(19) United States
(12) Patent Application Publication
(10) Pub. No.: US 2025/0185214 A1
(43) Pub. Date: Jun. 5, 2025

(54) VAPOR CHAMBER, ELECTRONIC APPARATUS, AND METHOD FOR MANUFACTURING VAPOR CHAMBER

(71) Applicant: DAI NIPPON PRINTING CO., LTD., Tokyo-to (JP)

(72) Inventors: Shinichiro TAKAHASHI, Tokyo-to (JP); Toshihiko TAKEDA, Tokyo-to (JP); Takayuki OTA, Tokyo-to (JP); Kazunori ODA, Tokyo-to (JP); Makoto YAMAKI, Tokyo-to (JP); Shinya KIURA, Tokyo-to (JP); Takayuki TERAUCHI, Tokyo-to (JP); Naohiro TAKAHASHI, Tokyo-to (JP); Youji KOZURU, Tokyo-to (JP)

(73) Assignee: DAI NIPPON PRINTING CO., LTD., Tokyo-to (JP)

(21) Appl. No.: 18/695,460

(22) PCT Filed: Sep. 30, 2022
(86) PCT No.: PCT/JP2022/036767

§ 371 Date: Mar. 26, 2024

(30) Foreign Application Priority Data
Sep. 30, 2021 (JP) 2021-161481
Sep. 30, 2021 (JP) 2021-161894
Nov. 12, 2021 (JP) 2021-185161
Dec. 6, 2021 (JP) 2021-198039
Dec. 16, 2021 (JP) 2021-204523
Dec. 22, 2021 (JP) 2021-208635
Feb. 25, 2022 (JP) 2022-028635

(51) Int. Cl. H05K 7/20; H01L 23/427

(52) U.S. Cl. CPC H05K 7/2039; H01L 23/427

(57) ABSTRACT

A body sheet of a vapor chamber includes a plurality of first land parts. A first-sheet outer face of the first sheet includes a first bond region, and a first space region. The first bond region overlaps each first land part. The first space region overlaps the space part. The vapor chamber includes a bend region where the vapor chamber is bent along a bend line that extends in a direction crossing the first direction in plan view. The maximum dimension defined between the first bond region and the first space region in the thickness direction of the first sheet is defined as a first maximum dimension. When viewed in a direction parallel to the bend line, the first maximum dimension in the bend region is greater than the first maximum dimension in a region other than the bend region.

### TECHNICAL FIELD

The present disclosure relates to a vapor chamber, an electronic apparatus, and a method for manufacturing a vapor chamber.

### BACKGROUND ART

Electronic apparatuses such as mobile terminals employ electronic devices that are prone to heat generation. Examples of the electronic devices include a central processing unit (CPU), a light-emitting diode (LED), and a power semiconductor. Examples of the mobile terminals include a portable terminal, and a tablet terminal.

Such an electronic device is cooled by a heat dissipation device such as a heat pipe (see, for example, PTLs 1 and 2). Recent years have seen increasing demand for thinner heat dissipation devices to achieve thinner electronic apparatuses. This had led to the ongoing development of vapor chambers, which are heat dissipation devices that can be made thinner than heat pipes. In such a vapor chamber, a working fluid sealed within the vapor chamber absorbs heat from the electronic device, and diffuses the absorbed heat inside the vapor chamber to thereby efficiently cool the electronic device.

More specifically, the working liquid within the vapor chamber receives heat at a location (evaporation part) proximate to the electronic device. Upon receiving the heat, the working liquid evaporates into a working vapor. Within a vapor channel part defined within the vapor chamber, the working vapor is diffused away from the evaporation part. The diffused working vapor is then cooled to condense into a working liquid. The vapor chamber includes a liquid channel part defined therein. The liquid channel part serves as a capillary structure (wick). The working liquid is transported through the liquid channel part toward the evaporation part. Once transported to the evaporation part, the working liquid receives heat and evaporates again in the evaporation part. As the working fluid undergoes refluxing within the vapor chamber while repeating phase changes, that is, evaporation and condensation as described above, the working fluid diffuses the heat from the electronic device. This results in improved heat dissipation efficiency of the vapor chamber.

A vapor chamber may undergo bending in some cases, depending on the internal structure of an electronic apparatus into which the vapor chamber is to be incorporated. In such cases, the vapor channel becomes bent, which may cause the working liquid to stagnate in the bent portion of the vapor channel part. This may impede the flow of the working vapor within the vapor channel part.

### CITATION LIST

### Patent Literature

PTL 1: International Publication No. 2018/221369
PTL 2: Japanese Unexamined Patent Application Publication No. 2018-204841

### SUMMARY OF INVENTION

### Technical Problem

An object of the present disclosure is to provide a vapor chamber capable of exhibiting improved performance even in its bent state, an electronic apparatus, and a method for manufacturing a vapor chamber.

### Solution to Problem

A first aspect of the present disclosure provides a vapor chamber in which a working fluid is sealed, the vapor chamber including:
a body sheet including a first body face and a second body face, the second body face being located opposite from the first body face;
a first sheet located on the first body face of the body sheet; and
a space part disposed in the body sheet and covered by the first sheet,
in which the body includes a plurality of first land parts located within the space part and extending in a first direction, the plurality of first land parts being spaced apart from each other in a second direction orthogonal to the first direction,
in which the first sheet includes a first-sheet outer face located opposite from the body sheet,
in which the first-sheet outer face includes a first bond region and a first space region, the first bond region overlapping each of the plurality of first land parts, the first space region overlapping the space part,
in which the vapor chamber includes a bend region where the vapor chamber is bent along a bend line, the bend line extending in a direction crossing the first direction in plan view,
in which a maximum dimension defined between the first bond region and the first space region in a thickness direction of the first sheet is defined as a first maximum dimension, and
in which when viewed in a direction parallel to the bend line, the first maximum dimension in the bend region is greater than the first maximum dimension in a region other than the bend region.

According to a second aspect of the present disclosure, the vapor chamber according to the first aspect may be configured such that the first space region has a recessed shape.

According to a third aspect of the present disclosure, the vapor chamber according to the first aspect may be configured such that:
the first space region has a recessed shape in the bend region; and
the first space region has, in the region other than the bend region, a flat shape in a direction aligned with the bend line.

According to a fourth aspect of the present disclosure, the vapor chamber according to the first aspect may be configured such that in the bend region, a portion of the first space region has a recessed shape, and an other portion of the first space region has a flat shape in a direction aligned with the bend line.

According to a fifth aspect of the present disclosure, the vapor chamber according to the first aspect may be configured such that the first sheet includes a plurality of first-sheet recesses, the plurality of first-sheet recesses overlapping the first space region in plan view and extending into the space part.

According to a sixth aspect of the present disclosure, the vapor chamber according to each of the first to fifth aspects may be configured such that in the bend region, the vapor chamber is bent along a bend line extending in the second direction.

According to a seventh aspect of the present disclosure, the vapor chamber according to each of the first to fifth aspects may be configured such that in the bend region, the vapor chamber is bent along a bend line inclined with respect to the first direction.

According to an eighth aspect of the present disclosure, the vapor chamber according to each of the first to seventh aspects may be configured such that in the bend region, the first sheet is located outward relative to the body sheet.

According to a ninth aspect of the present disclosure, the vapor chamber according to each of the first to seventh aspects may be configured such that in the bend region, the first sheet is located inward relative to the body sheet.

According to a tenth aspect of the present disclosure, the vapor chamber according to each of the first to ninth aspects may be configured such that:
the vapor chamber includes a second sheet located on the second body face of the body sheet;
the space part extends from the first body face to the second body face, and is covered at the second body face by the second sheet;
the second sheet includes a second-sheet outer face located opposite from the body sheet;
the second sheet includes a second bond region and a second space region, the second bond region overlapping each of the plurality of first land parts, the second space region overlapping the space part;
a maximum dimension defined between the second bond region and the second space region in a thickness direction of the second sheet is defined as a second maximum dimension; and
when viewed in the direction parallel to the bend line, the second maximum dimension in the bend region is greater than the second maximum dimension in the region other than the bend region.

According to an eleventh aspect of the present disclosure, the vapor chamber according to each of the first to tenth aspects may be configured such that:
the body sheet includes a plurality of second land parts extending in the second direction;
each of the plurality of second land parts is located in a region other than the bend region;
each of the plurality of first land parts is located in the bend region; and
each of the plurality of first land parts is connected to a corresponding one of the plurality of second land parts.

A twelfth aspect of the present disclosure provides an electronic apparatus, including:
a housing;
an electronic device contained in the housing; and
the vapor chamber according to any one of the first to eleventh aspects, the vapor chamber being in thermal contact with the electronic device.

A thirteenth aspect of the present disclosure provides a method for manufacturing a vapor chamber in which a working fluid is sealed, the method including:
a preparing step of preparing a body sheet and a first sheet, the body sheet including a first body face and a second body face located opposite from the first body face;
a bonding step of placing the first sheet on the first body face of the body sheet, and bonding the first sheet and the body sheet to each other, the bonding causing a space part to be formed in the body sheet, the space part being covered by the first sheet; and
a bending step of bending the body sheet and the first sheet to form a bend region where the body sheet and the first sheet are bent,
in which the body sheet includes a plurality of first land parts located within the space part and extending in a first direction, the plurality of first land parts being spaced apart from each other in a second direction orthogonal to the first direction;
in which the first sheet includes a first-sheet outer face located opposite from the body sheet;
in which the first-sheet outer face includes a first bond region and a first space region, the first bond region overlapping each of the plurality of first land parts, the first space region overlapping the space part,
in which in the bend region, the vapor chamber is bent along a bend line, the bend line extending in a direction crossing the first direction in plan view,
in which a maximum dimension defined between the first bond region and the first space region in a thickness direction of the first sheet is defined as a first maximum dimension, and
in which when viewed in a direction parallel to the bend line, the first maximum dimension in the bend region is greater than the first maximum dimension in a region other than the bend region.

A fourteenth aspect of the present disclosure provides a vapor chamber in which a working fluid is sealed, the vapor chamber including:
a plurality of vapor passages through which the working fluid in a gaseous state passes, the plurality of vapor passages extending in a first direction; and
a liquid channel part communicating with each of the plurality of vapor passages and through which the working fluid in a liquid state passes,
in which the vapor chamber is bent in a direction parallel to the first direction.

According to a fifteenth aspect of the present disclosure, the vapor chamber according to the fourteenth aspect may be configured such that the vapor chamber is bent at a position where at least one of the plurality of vapor passages is disposed.

According to a sixteenth aspect of the present disclosure, the vapor chamber according to the fourteenth aspect may be configured such that:
the liquid channel part is disposed between the plurality of vapor passages, and extends in the first direction; and
the vapor chamber is bent at a position where the liquid channel part is disposed.

According to a seventeenth aspect of the present disclosure, the vapor chamber according to the fourteenth aspect may be configured such that:
the vapor chamber includes a reinforcement part where the plurality of vapor passages and the liquid channel part are not disposed; and
the vapor chamber is bent at a position where the reinforcement part is disposed.

According to an eighteenth aspect of the present disclosure, the vapor chamber according to the fourteenth aspect may be configured such that:
the vapor chamber includes a space part where the plurality of vapor passages and the liquid channel part are not disposed; and
the vapor chamber is bent at a position where the space part is disposed.

A nineteenth aspect of the present disclosure provides a vapor chamber in which a working fluid is sealed, the vapor chamber including:
a body sheet including a first body face and a second body face, the second body face being located opposite from the first body face;
a first sheet located on the first body face of the body sheet;
a second sheet located on the second body face of the body sheet;
a plurality of vapor passages through which the working fluid in a gaseous state passes, the plurality of vapor passages extending in a first direction; and
a liquid channel part communicating with each of the plurality of vapor passages and through which the working fluid in a liquid state passes,
in which the vapor chamber includes a bend region, a first region, and a second region, the bend region being a region where the vapor chamber is bent along a bend line parallel to the first direction, the first region and the second region being separated from each other via the bend region, and
in which in the bend region, the first body face or the second body face is provided with a body-face recess.

According to a twentieth aspect of the present disclosure, the vapor chamber according to the nineteenth aspect may be configured such that a plurality of the body-face recesses are disposed along the bend line.

According to a twenty-first aspect of the present disclosure, the vapor chamber according to each of the nineteenth and twentieth aspects may be configured such that:
the body sheet includes a reinforcement part where the plurality of vapor passages and the liquid channel part are not disposed; and
the body-face recess is provided in the first body face or the second body face of the reinforcement part.

According to a twenty-second aspect of the present disclosure, the vapor chamber according to each of the nineteenth and twentieth aspects may be configured such that:
the body sheet includes a land part in which the liquid channel part is disposed, the land part being located between two vapor passages of the plurality of vapor passages and extending in the first direction; and
the body-face recess is located at a position in the first land part where the liquid channel part is not disposed.

A twenty-third aspect of the present disclosure provides an electronic apparatus including:
a housing;
a device contained in the housing; and
the vapor chamber according to any one of the fourteenth to twenty-second aspects, the vapor chamber being in thermal contact with the device.

According to a twenty-fourth aspect of the present disclosure, the electronic apparatus according to the twenty-third aspect may be configured such that:
the vapor chamber includes a plurality of the devices;
the plurality of devices include a first device, and a second device;
the vapor chamber is divided via a bend part into a first region and a second region;
the first device is in thermal contact with the first region of the vapor chamber; and
the second device is in thermal contact with the second region of the vapor chamber.

According to a twenty-fifth aspect of the present disclosure, the electronic apparatus according to the twenty-third aspect may be configured such that:
the vapor chamber is divided via a bend part into a first region and a second region; and
the device is in thermal contact with the first region of the vapor chamber.

A twenty-sixth aspect of the present disclosure provides a method for manufacturing a vapor chamber, the method including:
a first-sheet preparing step of preparing a first sheet;
a body-sheet preparing step of preparing a body sheet, the body sheet including
   a plurality of vapor passages through which a working fluid in a gaseous state passes, the plurality of vapor passages extending in a first direction, and
   a liquid channel part communicating with each of the plurality of vapor passages and through which the working fluid in a liquid state passes;
a bonding step of stacking and bonding the first sheet and the body sheet to each other; and
a bending step of, after the bonding step, bending the first sheet and the body sheet in a direction parallel to the first direction.

### Advantageous Effects of Invention

The present disclosure allows the vapor chamber to exhibit improved performance even in its bent state.

### BRIEF DESCRIPTION OF DRAWINGS

FIG. 1 is a schematic perspective view of an electronic apparatus according to a first embodiment.

FIG. 2 schematically illustrates an example of a vapor chamber according to the first embodiment that is incorporated in the electronic apparatus illustrated in FIG. 1.

FIG. 3 schematically illustrates another example of the vapor chamber according to the first embodiment that is incorporated in the electronic apparatus illustrated in FIG. 1.

FIG. 4 is an outline perspective view of the vapor chamber according to the first embodiment.

FIG. 5 is a plan view of the vapor chamber illustrated in FIG. 2 in its pre-bending state.

FIG. 6 is a cross-section taken along a line A-A of FIG. 5.

FIG. 7 is a plan view of an inner face of a first sheet illustrated in FIG. 6.

FIG. 8 is a plan view of an inner face of a second sheet illustrated in FIG. 6.

FIG. 9 is a plan view of a first body face of a wick sheet illustrated in FIG. 6.

FIG. 10 is a plan view of a second body face of the wick sheet illustrated in FIG. 6.

FIG. 11 is a partial enlarged cross-section of FIG. 6, which is taken along a line B-B of FIG. 13 (described later).

FIG. 12 is a partial enlarged view of a liquid channel part illustrated in FIG. 9.

FIG. 13 is a diagram illustrating a sheet outer face in a bend region of the vapor chamber illustrated in FIG. 4.

FIG. 14 is a cross-section taken along a line C-C of FIG. 13.

FIG. 15 is a cross-section of a modification of the vapor chamber according to the first embodiment, the cross-section being taken at an end portion of the vapor chamber in the width direction.

FIG. 16 is a cross-section of a modification of the vapor chamber illustrated in FIG. 14.

FIG. 17 is a cross-section of a modification of the vapor chamber illustrated in FIG. 14.

FIG. 18 is a cross-section of a modification of the vapor chamber illustrated in FIG. 14.

FIG. 19 is a cross-section of a modification of the vapor chamber illustrated in FIG. 14.

FIG. 20 is a cross-section of a modification of the vapor chamber illustrated in FIG. 14.

FIG. 21 is a cross-section of a modification of the vapor chamber illustrated in FIG. 14.

FIG. 22 is a cross-section of a modification of the vapor chamber illustrated in FIG. 14.

FIG. 23 is a cross-section of a modification of the vapor chamber illustrated in FIG. 14.

FIG. 24 is a plan view of a modification of the vapor chamber according to the first embodiment, illustrating a liquid channel part in enlarged scale.

FIG. 25 is a cross-section in each of a first region and a second region of the vapor chamber illustrated in FIG. 24.

FIG. 26 is a cross-section in a bend region of the vapor chamber illustrated in FIG. 24.

FIG. 27 is a plan view of a modification of the vapor chamber according to the first embodiment, illustrating a second body face of a land part in enlarged scale.

FIG. 28 illustrates, in plan view, another example of the configuration illustrated in FIG. 27.

FIG. 29 is a cross-section of a modification of the vapor chamber illustrated in FIG. 13.

FIG. 30 is an outline perspective view of a vapor chamber according to a second embodiment.

FIG. 31 is a plan view of a vapor passage, representing a planar development of a bend region of the vapor chamber illustrated in FIG. 30.

FIG. 32 illustrates diagrammatic cross-sections of a vapor passage taken along lines D-D, E-E, and F-F of FIG. 31.

FIG. 33 is a plan view of a modification, in a pre-bending state, of the vapor chamber illustrated in FIG. 30.

FIG. 34 is a plan view of the outline, in a pre-bending state, of a vapor chamber according to a third embodiment.

FIG. 35 is a plan view of a modification of the vapor chamber illustrated in FIG. 34.

FIG. 36 is a plan view of another modification of the vapor chamber illustrated in FIG. 34.

FIG. 37 is a plan view of another modification of the vapor chamber illustrated in FIG. 24.

FIG. 38 is a perspective view of a vapor chamber according to a fourth embodiment in its bent state.

FIG. 39 is a cross-section taken along a line AA-AA of FIG. 38.

FIG. 40 is an illustration for explaining the vapor chamber illustrated in FIG. 38, depicting in plan view the vapor chamber in its unbent state.

FIG. 41 is a cross-section taken along a line BB-BB of FIG. 40.

FIG. 42 is a plan view of an inner face of a first sheet illustrated in FIG. 41.

FIG. 43 is a plan view of an inner face of a second sheet illustrated in FIG. 41.

FIG. 44 is a plan view of a second body face of a body sheet illustrated in FIG. 41.

FIG. 45 is a partial enlarged cross-section of FIG. 41.

FIG. 46 is a partial enlarged view of a liquid channel part illustrated in FIG. 45.

FIG. 47 illustrates a material-sheet preparing step of a method for manufacturing the vapor chamber according to the fourth embodiment.

FIG. 48 illustrates an etching step of the method for manufacturing the vapor chamber according to the fourth embodiment.

FIG. 49 illustrates a bonding step of the method for manufacturing the vapor chamber according to the fourth embodiment.

FIG. 50 illustrates a bending step of the method for manufacturing the vapor chamber according to the fourth embodiment.

FIG. 51 is a cross-section of a modification of the vapor chamber illustrated in FIG. 45, illustrating a liquid channel part in enlarged scale.

FIG. 52 is a cross-section of a modification of the vapor chamber illustrated in FIG. 45, illustrating a liquid channel part in enlarged scale.

FIG. 53 is a cross-section of a modification of the vapor chamber illustrated in FIG. 45.

FIG. 54 is a cross-section of a modification of the vapor chamber illustrated in FIG. 45.

FIG. 55 is a cross-section of a modification of the vapor chamber illustrated in FIG. 45.

FIG. 56 is a cross-section of a modification of the vapor chamber illustrated in FIG. 45.

FIG. 57 is a plan view of a modification of the vapor chamber illustrated in FIG. 44.

FIG. 58 is a cross-section of a modification of the vapor chamber illustrated in FIG. 57, illustrating a liquid channel part in enlarged scale.

FIG. 59 is a cross-section of a modification of the vapor chamber illustrated in FIG. 57, illustrating a liquid channel part in enlarged scale.

FIG. 60 is a cross-section of a modification of the vapor chamber illustrated in FIG. 57, illustrating a liquid channel part in enlarged scale.

FIG. 61 is a plan view of a modification of the vapor chamber illustrated in FIG. 57, illustrating a liquid channel part in enlarged scale.

FIG. 62 is a cross-section of a modification of the vapor chamber illustrated in FIG. 57, illustrating a liquid channel part in enlarged scale.

FIG. 63 is a plan view of a modification of the vapor chamber illustrated in FIG. 44.

FIG. 64 is a plan view of a modification of the vapor chamber illustrated in FIG. 63.

FIG. 65 is a plan view of a modification of the vapor chamber illustrated in FIG. 63.

FIG. 66 is a plan view of a modification of the vapor chamber illustrated in FIG. 65.

FIG. 67 is a plan view of a modification of the vapor chamber illustrated in FIG. 65, illustrating a reinforcement part in enlarged scale.

FIG. 68 illustrates, in plan view, another example of the configuration illustrated in FIG. 67.

FIG. 69 is a plan view of a modification of the vapor chamber illustrated in FIG. 65.

FIG. 70 is a plan view of a modification of the vapor chamber illustrated in FIG. 65, illustrating in enlarged scale a first body face of a land part.

FIG. 71 is a plan view of a modification of the vapor chamber illustrated in FIG. 63.

FIG. 72 is a plan view of a modification of the vapor chamber illustrated in FIG. 44.

FIG. 73 is a plan view of a modification of the vapor chamber illustrated in FIG. 63.

FIG. 74 is a plan view of a modification of the vapor chamber illustrated in FIG. 73.

FIG. 75 is a plan view of a modification of the vapor chamber illustrated in FIG. 44.

FIG. 76 is a cross-section of a modification of the vapor chamber illustrated in FIG. 39.

FIG. 77 is a cross-section in a bend part of the vapor chamber illustrated in FIG. 76.

FIG. 78 is a cross-section of a modification of the vapor chamber illustrated in FIG. 76.

FIG. 79 is a cross-section of a modification of the vapor chamber illustrated in FIG. 41.

FIG. 80 illustrates, in cross-section, another example of the configuration illustrated in FIG. 79.

### DESCRIPTION OF EMBODIMENTS

Embodiments of the present disclosure are described below with reference to the drawings. In the accompanying drawings, for ease of illustration and understanding, the scales, the horizontal-to-vertical dimensional ratios, or other details in the drawings are changed and exaggerated from the actual ones. In some cases, components or other features illustrated in some figures are not illustrated in other figures.

As used herein, geometric conditions, physical characteristics, terms specifying the degree or extent of geometric conditions or physical characteristics, numerical values representing geometric conditions or physical characteristics, and other similar references may be interpreted without being bound by their strict meanings. Such geometric conditions, physical characteristics, terms, numerical values, and other similar references may be interpreted to include a range such that similar or equivalent functions may be expected. Examples of terms specifying geometric conditions include “length”, “angle”, “shape”, and “arrangement.” Examples of terms specifying geometric conditions include “parallel”, “orthogonal”, and “same.” Further, for the clarity of the drawings, a plurality of parts or portions that may be expected to have similar functions are depicted as being shaped regularly. However, the shapes of such portions or parts may, without being bound by their strict meanings, differ from each other, insofar as the above-mentioned functions may be expected. In the drawings, each boundary line representing the bonding face between components or other features is indicated by a simple straight line. However, such a boundary line may, without being bound to a strictly straight line, have any shape, insofar as desired bond performance can be expected.

### First Embodiment

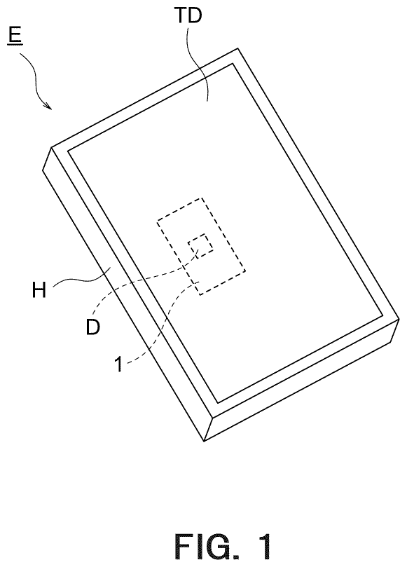

A vapor chamber, an electronic apparatus, and a method for manufacturing a vapor chamber according to a first embodiment of the present disclosure are described below with reference to FIGS. 1 to 29. A vapor chamber 1 according to the first embodiment is contained in a housing H of an electronic apparatus E together with an electronic device D that is prone to heat generation. The vapor chamber 1 serves to cool the electronic device D. Examples of the electronic apparatus E include a mobile terminal, such as a portable terminal or a tablet terminal. Examples of the electronic device D include a central processing unit (CPU), a light-emitting diode (LED), and a power semiconductor. The electronic device D will be sometimes also referred to as a device to be cooled.

Reference is first made to a tablet terminal, which is an example of the electronic apparatus E in which the vapor chamber 1 according to the first embodiment is incorporated. As illustrated in FIG. 1, the electronic apparatus E may include the housing H, the electronic device D contained in the housing H, and the vapor chamber 1. The electronic apparatus E illustrated in FIG. 1 includes a touchscreen display TD on the front of the housing H. The vapor chamber 1 is contained in the housing H, and disposed in thermal contact with the electronic device D. The vapor chamber 1 receives heat that the electronic device D generates when the electronic apparatus E is in use. The heat received by the vapor chamber 1 is released out of the vapor chamber 1 via working fluids 2a and 2b (described later). The electronic device D is thus effectively cooled. If the electronic apparatus E is a tablet terminal, the electronic device D corresponds to, for example, a central processing unit.

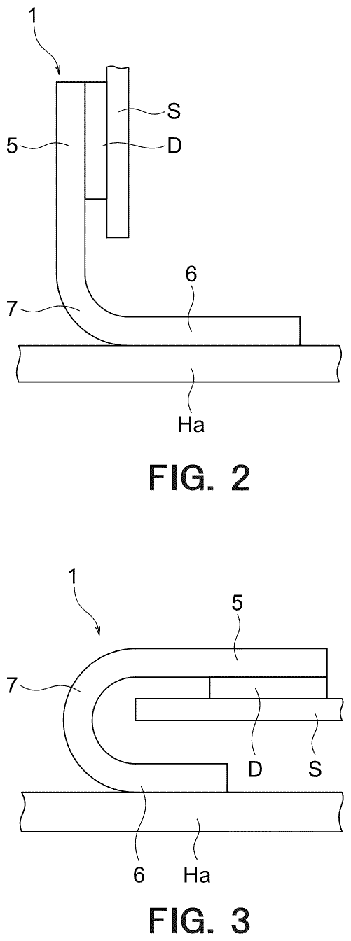

Reference is now made to the vapor chamber 1 according to the first embodiment. The vapor chamber 1 according to the first embodiment is bent as illustrated in FIGS. 2 and 3. The vapor chamber 1 is bent in accordance with the internal structure of the electronic apparatus E. Depending the positional relationship between the electronic apparatus E that is prone to heat generation, and a housing component Ha that releases heat, the vapor chamber 1 may undergo bending in some cases. The housing component Ha is a component constituting the housing H.

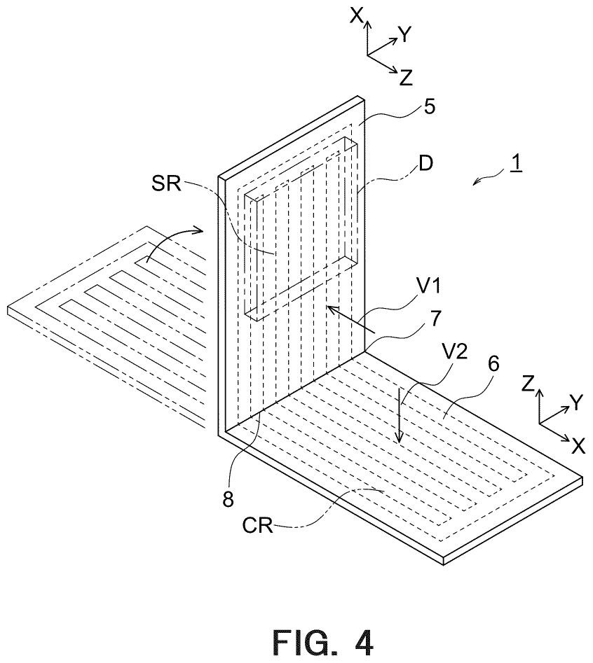

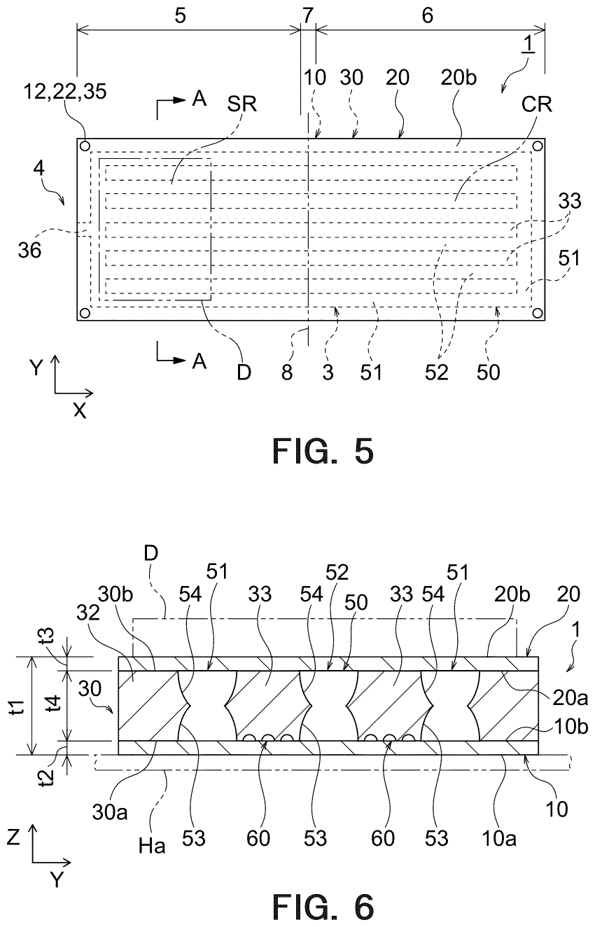

By way of one example, reference is made to a case where the electronic device D and the housing component Ha are disposed as illustrated in FIG. 2. In this case, the vapor chamber 1 is bent at substantially right angles such that the vapor chamber 1 is in contact with the electronic device D and the housing component Ha. The electronic device D is mounted to a substrate S. By way of another example, reference is made to a case where the electronic device D and the housing component Ha are disposed as illustrated in FIG. 3. In this case, the vapor chamber 1 is bent at 180 degrees such that the vapor chamber 1 is in contact with the electronic device D and the housing component Ha. Although FIGS. 2 and 3 depict an example in which the vapor chamber 1 is bent along a single bend line 8 (see FIGS. 4 and 5), this is not intended to be limiting. The vapor chamber 1 may be bent along two or more bend lines 8, that is, at different positions.

The following description of the first embodiment is directed to an example of the vapor chamber 1 that is bent at substantially right angles along a single bend line 8 as illustrated in FIG. 4. The vapor chamber 1 illustrated in FIG. 4 is divided into a first region 5, a second region 6, and a bend region 7. The bend region 7 is located between the first region 5 and the second region 6. In the bend region 7, the vapor chamber 1 is bent at substantially right angles. The first region 5 and the second region 6 each have a substantially flat shape. The electronic device D may be in contact with the first region 5, and the housing component Ha (see FIG. 2) may be in contact with the second region 6.

Now, the configuration of the vapor chamber 1 is first described with reference to FIGS. 5 to 11, which illustrate the vapor chamber 1 in its pre-bending state. The vapor chamber 1 in the form of a flat plate illustrated in FIG. 5 is bent to obtain the vapor chamber 1 illustrated in FIG. 4.

As illustrated in FIGS. 5 and 6, the vapor chamber 1 has a hermetically sealed space 3 with the working fluids 2a and 2b sealed therein. As the working fluids 2a and 2b within the hermetically sealed space 3 undergo repeated phase changes, the electronic device D mentioned above is cooled. Examples of the working fluids 2a and 2b include pure water, ethanol, methanol, acetone, and liquid mixtures thereof.

As illustrated in FIGS. 5 and 6, the vapor chamber 1 includes a first sheet 10, a second sheet 20, a wick sheet 30, a vapor channel part 50, and a first liquid channel part 60. The second sheet 20 is disposed on a side of the wick sheet 30 opposite from the first sheet 10. The wick sheet 30 is an example of a body sheet. The wick sheet 30 is interposed between the first sheet 10 and the second sheet 20. In the vapor chamber 1 according to the first embodiment, the first sheet 10, the wick sheet 30, and the second sheet 20 are stacked in this order. Although the following description is directed to an example in which a single wick sheet 30 is stacked, two or more wick sheets 30 may be stacked.

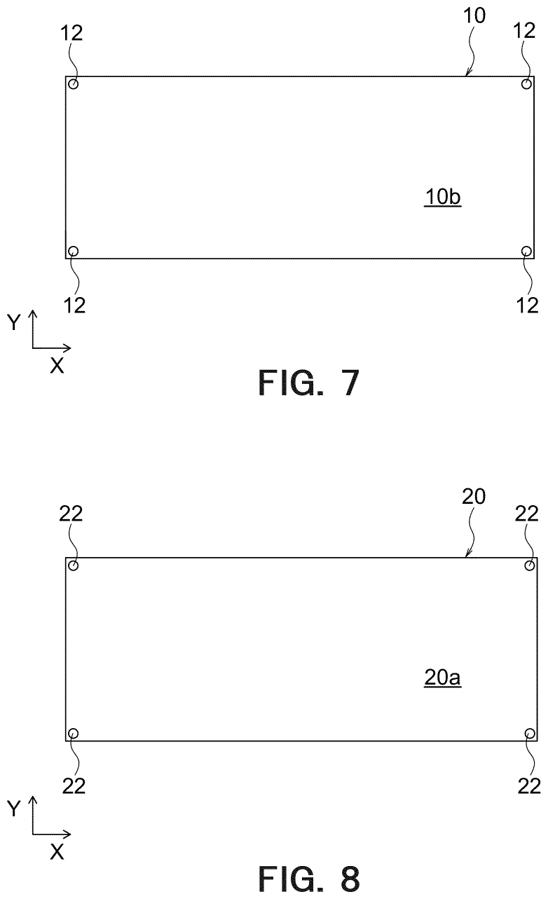

The vapor chamber 1 is illustrated in FIG. 5 as being generally in the form of a thin flat plate. Although the vapor chamber 1 in its pre-bending state may have any shape in plan view, the vapor chamber 1 in its pre-bending state may have a rectangular shape in plan view as illustrated in FIG. 5. The shape of the vapor chamber 1 in plan view may be, for example, a rectangle that is 1 cm on one side and 3 cm on the other side, or may be a square that is 15 cm on each side. The vapor chamber 1 in its pre-bending state may be of any dimensions in plan view. The following description of the first embodiment is directed to an example in which the vapor chamber 1 in its pre-bending state has a shape in plan view that is a rectangle with its longitudinal direction aligned with an X-direction described later. In this case, as illustrated in FIGS. 7 to 10, the first sheet 10, the second sheet 20, and the wick sheet 30 may each have a shape in plan view similar to that of the vapor chamber 1. The shape, in plan view, of the vapor chamber 1 in its pre-bending state is not necessarily a rectangle but may be any shape, such as a circle, an ellipse, an L-shape, or a T-shape.

As illustrated in FIGS. 4 and 5, the vapor chamber 1 includes an evaporation region SR where the working liquid 2b evaporates, and a condensation region CR where the working vapor 2a condenses. The working vapor 2a is a working fluid in a gaseous state, and the working liquid 2b is a working fluid in a liquid state.

The evaporation region SR is a region that overlaps the electronic device D in plan view, and that is in contact with the electronic device D. Although the evaporation region SR is located within the first region 5 in the present example, the evaporation region SR may be located at any position. According to the first embodiment, the evaporation region SR is located at one side (the left side in FIG. 5) of the vapor chamber 1 in the X-direction. Heat from the electronic device D is transferred to the evaporation region SR, and the transferred heat causes the working liquid 2b to evaporate. The working vapor 2a is thus generated. The heat from the electronic device D may be transferred not only to a region overlapping the electronic device D in plan view, but also to the vicinity of the region that overlaps the electronic device D. Accordingly, the evaporation region SR may, in plan view, include a region overlapping the electronic device D, and the vicinity of the region.

The condensation region CR is a region that does not overlap the electronic device D in plan view, and that serves as a region where mainly the working vapor 2a releases its heat and condenses. The condensation region CR may be located within the second region 6. The condensation region CR may be a region surrounding the evaporation region SR including the second region 6. In the condensation region CR, heat from the working vapor 2a is released. The working vapor 2a is thus cooled to condense, and the working liquid 2b is generated.

As used herein, the term “plan view” refers to viewing in a direction that is orthogonal to a face of the vapor chamber 1 that receives heat from the electronic device D, and to a face of the vapor chamber 1 that releases the received heat. A face that receives heat corresponds to a second-sheet outer face 20b (described later) of the second sheet 20. A face that releases heat corresponds to a first-sheet outer face 10a (described later) of the first sheet 10. For example, for the first region 5 of the vapor chamber 1 in its bent state, its plan view corresponds to a view seen in a direction represented by an arrow V1 as illustrated in FIG. 4. For the second region 6, its plan view corresponds to a view seen in a direction represented by an arrow V2. As illustrated in FIG. 5, for the vapor chamber 1 in its pre-bending state, its plan view corresponds to a view of the vapor chamber 1 as seen from above or a view of the vapor chamber 1 as seen from below.

As illustrated in FIG. 6, the first sheet 10 has the first-sheet outer face 10a located opposite from the wick sheet 30, and a first-sheet inner face 10b facing the wick sheet 30. In the second region 6 mentioned above, the housing component Ha mentioned above is in contact with the first-sheet outer face 10a. A first body face 30a (described later) of the wick sheet 30 is in contact with the first-sheet inner face 10b. As illustrated in FIGS. 6 and 7, the first sheet 10 may have a substantially flat shape. The first sheet 10 may have a substantially constant thickness.

As illustrated in FIG. 7, an alignment hole 12 may be disposed at each of the four corners of the first sheet 10. Although the alignment hole 12 is illustrated in FIG. 7 as having a circular shape in plan view, this is not intended to be limiting. The alignment hole 12 may extend through the first sheet 10.

As illustrated in FIG. 6, the second sheet 20 includes a second-sheet inner face 20a facing the wick sheet 30, and the second-sheet outer face 20b located opposite from the wick sheet 30. In the first region 5 mentioned above, the electronic device D is in contact with the second-sheet outer face 20b. A second body face 30b (described later) of the wick sheet 30 is in contact with the second-sheet inner face 20a. As illustrated in FIGS. 6 and 8, the second sheet 20 may have a substantially flat shape. The second sheet 20 may have a substantially constant thickness.

As illustrated in FIG. 8, an alignment hole 22 may be disposed at each of the four corners of the second sheet 20. Although the alignment hole 22 is illustrated in FIG. 8 as having a circular shape in plan view, this is not intended to be limiting. The alignment hole 22 may extend through the second sheet 20.

As illustrated in FIG. 5, the wick sheet 30 has the first body face 30a, and the second body face 30b located opposite from the first body face 30a. The first-sheet inner face 10b of the first sheet 10 is in contact with the first body face 30a. The second-sheet inner face 20a of the second sheet 20 is in contact with the second body face 30b.

The first-sheet inner face 10b of the first sheet 10, and the first body face 30a of the wick sheet 30 may be diffusion-bonded to each other. The first-sheet inner face 10b and the first body face 30a may be permanently bonded to each other.

Likewise, the second-sheet inner face 20a of the second sheet 20, and the second body face 30b of the wick sheet 30 may be diffusion-bonded to each other. The second-sheet inner face 20a and the second body face 30b may be permanently bonded to each other.

As described herein, the term “permanently bonded” is not bound by the strict meaning of the term. Rather, the term is used to mean being bonded to an extent that allows the sealing of the hermetically sealed space 3 to be maintained during operation of the vapor chamber 1.

As illustrated in FIGS. 5, 9, and 10, the wick sheet 30 according to the first embodiment includes a frame part 32, and a plurality of first land parts 33. The frame part 32 defines the vapor channel part 50. In plan view, the frame part 32 is in the form of a rectangular frame extending in the X-direction and the Y-direction. Each first land part 33 is located within the vapor channel part 50. In plan view, the first land part 33 is located inside the frame part 32. The frame part 32 and the first land part 33 are parts where the material of the wick sheet 30 remains without being etched away in an etching step (described later). A first vapor passage 51 (described later) is provided between the frame part 32, and the first land part 33 adjacent to the frame part 32. The working vapor 2a flows through the first vapor passage 51. A second vapor passage 52 (described later) is provided between the first land parts 33 that are adjacent to each other. The working vapor 2a flows through the second vapor passage 52.

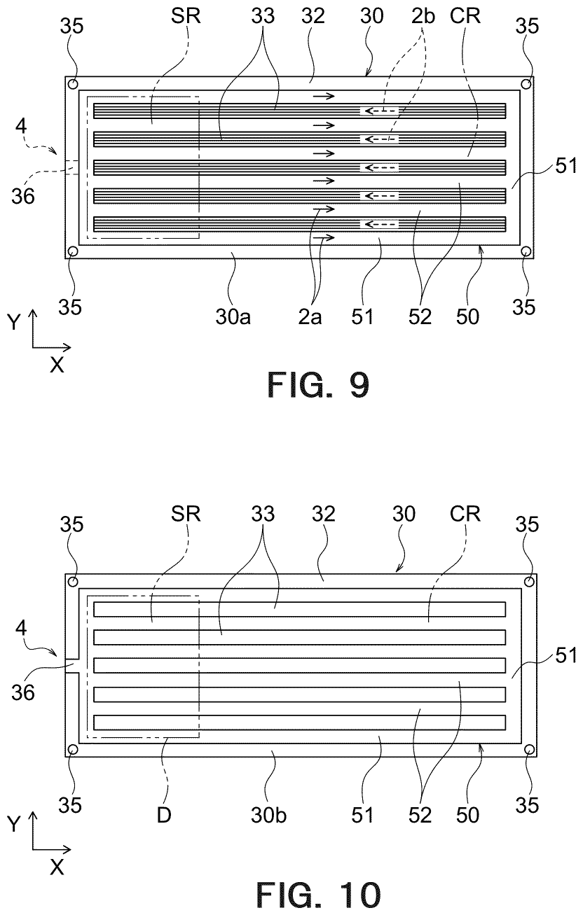

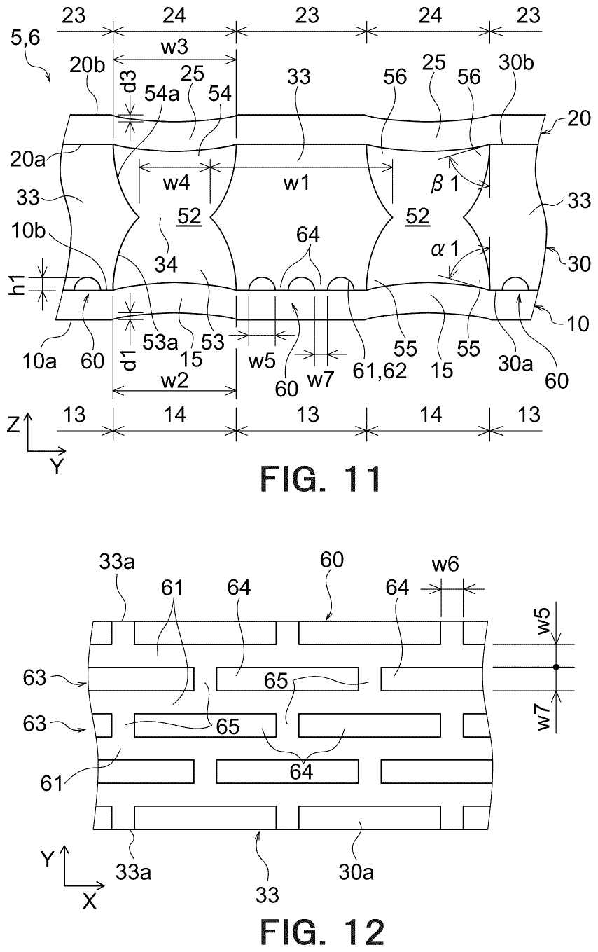

In plan view, the first land part 33 may extend in an elongated shape with its longitudinal direction aligned with the X-direction. The first land part 33 may have an elongated rectangular shape in plan view. The X-direction is an example of a first direction. The X-direction corresponds to the left-right direction in FIGS. 9 and 10. The first land parts 33 may be disposed at equal intervals in the Y-direction. The Y-direction is an example of a second direction. The Y-direction is a direction orthogonal to the X-direction in plan view. The Y-direction corresponds to the up-down direction in FIGS. 9 and 10. The first land parts 33 may be positioned in parallel to each other. A direction orthogonal to the X-direction and to the Y-direction is defined as a Z-direction. The Z-direction corresponds to the up-down direction in FIGS. 6 and 11. The Z-direction corresponds to the thickness direction.

As illustrated in FIG. 11, the first land part 33 may have a width w1 of, for example, 100 μm to 1500 μm. The width w1 of the first land part 33 in this case is a dimension of the first land part 33 in the Y-direction. The width w1 refers to a dimension of the wick sheet 30 at a location in the Z-direction of the wick sheet 30 where a through-part 34 (described later) exists.

In the first region 5 and the second region 6 of the vapor chamber 1 illustrated in FIG. 4, the X-direction corresponds to the direction along the length of the first land part 33. The X-direction in the first region 5 corresponds to the up-down direction in FIG. 4. In the first region 5 and the second region 6 of the vapor chamber 1 illustrated in FIG. 4, the Y-direction corresponds to a direction in which the first land parts 33 are arranged side by side. In the first region 5 and the second region 6 of the vapor chamber 1 illustrated in FIG. 4, the Z-direction corresponds to a direction orthogonal to the vapor chamber 1. The Z-direction in the second region 6 corresponds to the up-down direction in FIG. 4.

The frame part 32 and each first land part 33 are diffusion-bonded to the first sheet 10, and diffusion-bonded to the second sheet 20. This allows for improved mechanical strength of the vapor chamber 1. A wall face 53a of a first vapor channel recess 53 (described later), and a wall face 54a of a second vapor channel recess 54 (described later) constitute a side wall of the first land part 33. The first body face 30a and the second body face 30b of the wick sheet 30 may each extend in a flat shape across the frame part 32 and the first land parts 33.

As illustrated in FIGS. 9 and 10, an alignment hole 35 may be disposed at each of the four corners of the wick sheet 30. Although the alignment hole 35 is illustrated in FIG. 10 as having a circular shape in plan view, this is not intended to be limiting. The alignment hole 35 may extend through the wick sheet 30.

As illustrated in FIG. 6, the vapor channel part 50 may be disposed in the first body face 30a of the wick sheet 30. The vapor channel part 50 is an example of a space part. The vapor channel part 50 may be a channel through which mainly the working vapor 2a passes. The working liquid 2b may also pass through the vapor channel part 50. According to the first embodiment, the vapor channel part 50 may extend from the first body face 30a to the second body face 30b, that is, may extend through the wick sheet 30. The vapor channel part 50 may be covered at the first body face 30a by the first sheet 10. The vapor channel part 50 may be covered at the second body face 30b by the second sheet 20.

As illustrated in FIGS. 9 and 10, the vapor channel part 50 according to the first embodiment may include the first vapor passage 51, and a plurality of second vapor passages 52. The first vapor passage 51 is provided between the frame part 32 and the first land part 33. The first vapor passage 51 is an example of a space periphery portion. The first vapor passage 51 is provided contiguously inside the frame part 32 and outside the first land part 33. In plan view, the first vapor passage 51 may be in the form of a rectangular frame extending in the X-direction and the Y-direction. The second vapor passage 52 is disposed between the first land parts 33 that are adjacent to each other. The second vapor passage 52 may have an elongated rectangular shape in plan view. The vapor channel part 50 is divided by the first land parts 33 into the first vapor passage 51 and the second vapor passages 52.

As illustrated in FIG. 6, the first vapor passage 51 and the second vapor passage 52 may extend from the first body face 30a of the wick sheet 30 to the second body face 30b. The first vapor passage 51 and the second vapor passage 52 each include the first vapor channel recess 53, and the second vapor channel recess 54. The first vapor channel recess 53 is disposed in the first body face 30a. The second vapor channel recess 54 is disposed in the second body face 30b. The first vapor channel recess 53 and the second vapor channel recess 54 may communicate with each other.

The first vapor channel recess 53 may be formed in an etching step (described later) through etching performed from the first body face 30a of the wick sheet 30. The first vapor channel recess 53 is in the form of a recess provided in the first body face 30a. As illustrated in FIG. 11, the first vapor channel recess 53 may have the wall face 53a having a curved shape. FIG. 11 is a cross-section orthogonal to the X-direction. The wall face 53a defines the first vapor channel recess 53. The wall face 53a may have a curved shape such that the distance between the wall face 53a on one side and the wall face 53a on the other, opposite side decreases with increasing proximity to the second body face 30b. The first vapor channel recess 53 constitutes a portion of the first vapor passage 51 located relatively close to the first sheet 10, and a portion of the second vapor passage 52 located relatively close to the first sheet 10.

The first vapor channel recess 53 may have a width w2 of, for example, 100 μm to 5000 μm. The width w2 of the first vapor channel recess 53 is a dimension in the Y-direction. The width w2 is a dimension of the first vapor channel recess 53 at the location of the first body face 30a. The width w2 corresponds to a dimension in the Y-direction of a portion of the first vapor passage 51 that extends in the X-direction, and to a dimension in the Y-direction of the second vapor passage 52. The width w2 also corresponds to a dimension in the X-direction of a portion of the first vapor passage 51 that extends in the Y-direction.

The second vapor channel recess 54 may be formed in an etching step (described later) through etching performed from the second body face 30b of the wick sheet 30. The second vapor channel recess 54 is in the form of a recess provided in the second body face 30b. As illustrated in FIG. 11, the second vapor channel recess 54 may have the wall face 54a having a curved shape. The wall face 54a defines the second vapor channel recess 54. The wall face 54a may have a curved shape such that the distance between the wall face 54a on one side and the wall face 54a on the other, opposite side decreases with increasing proximity to the first body face 30a. The second vapor channel recess 54 constitutes a portion of the first vapor passage 51 located relatively close to the second sheet 20, and a portion of the second vapor passage 52 located relatively close to the second sheet 20.

As with the width w2 of the first vapor channel recess 53 mentioned above, a width w3 of the second vapor channel recess 54 may be, for example, 100 μm to 5000 μm. The width w3 of the second vapor channel recess 54 is a dimension in the Y-direction. The width w3 is a dimension of the second vapor channel recess 54 at the location of the second body face 30b. The width w3 corresponds to a dimension in the Y-direction of a portion of the first vapor passage 51 that extends in the X-direction, and to a dimension in the Y-direction of the second vapor passage 52. The width w3 also corresponds to a dimension in the X-direction of a portion of the first vapor passage 51 that extends in the Y-direction. The width w3 of the second vapor channel recess 54 may be equal to or different from the width w2 of the first vapor channel recess 53.

As illustrated in FIG. 11, the wall face 53a of the first vapor channel recess 53, and the wall face 54a of the second vapor channel recess 54 may be connected to define the through-part 34. According to the first embodiment, the through-part 34 in the first vapor passage 51 may have the shape of a rectangular frame in plan view. The through-part 34 in the second vapor passage 52 may have an elongated rectangular shape in plan view. The through-part 34 may be defined by an edge where the wall face 53a of the first vapor channel recess 53, and the wall face 54a of the second vapor channel recess 54 meet. As illustrated in FIG. 11, the edge may project toward the inner portion of each of the first vapor passages 51 and 52. The area of the first vapor passage 51 in plan view may be at its minimum at the through-part 34, and the area of the second vapor passage 52 in plan view may be at its minimum at the through-part 34. The through-part 34 in each of the vapor passages 51 and 52 may have a width w4 of, for example, 400 μm to 5000 μm. The width w4 of the through-part 34 in this case corresponds to the gap between the first land parts 33 that are adjacent to each other in the Y-direction.

The position of the through-part 34 in the Z-direction may be the midway position between the first body face 30a and the second body face 30b. Alternatively, the position of the through-part 34 may be closer to the first sheet 10 than is the midway position, or may be closer to the second sheet 20 than is the midway position. The through-part 34 may be located at any position in the Z-direction.

According to the first embodiment, as mentioned above, the first vapor passage 51 and the second vapor passage 52 are each shaped to have a cross-section that includes the through-part 34 defined by the inwardly projecting edge. This, however, is not intended to be limiting. For example, the first vapor passage 51 and the second vapor passage 52 may each have a cross-section that is a trapezoid or a parallelogram, or a cross-section that is barrel-shaped.

The vapor channel part 50 including the first vapor passage 51 and the second vapor passage 52 configured as described above constitutes a portion of the hermetically sealed space 3 mentioned above. The vapor passages 51 and 52 each have a relatively large channel cross-sectional area to allow passage of the working vapor 2a therethrough.

It is to be noted that for clarity of illustration, FIG. 11 depicts the first vapor passage 51 and the second vapor passage 52 in enlarged scale. The numbers, locations, or other details of features such as the vapor passages 51 and 52 in FIG. 11 differ from those illustrated in FIGS. 5, 9, and 10.

Although not illustrated, a plurality of supports for supporting the first land part 33 to the frame part 32 may be disposed in each of the vapor passages 51 and 52. A support for supporting the first land parts 33 that are adjacent to each other may be also provided. These supports may be disposed on both sides of the first land part 33 in the X-direction, or may be disposed on both sides of the first land part 33 in the Y-direction. Each support is preferably provided in a manner that does not obstruct the flow of the working vapor 2a that diffuses in the vapor channel part 50. For example, the support may be located near one of the first body face 30a and the second body face 30b of the wick sheet 30, and a space defining the vapor channel part 50 may be provided near the other one of the first body face 30a and the second body face 30b. The support can be thus made thinner than the wick sheet 30. This can prevent the first vapor passage 51 and the second vapor passage 52 from being divided into separate parts in the X-direction and the Y-direction.

As illustrated in FIG. 5, the vapor chamber 1 may include an injection part 4 for injecting the working liquid 2b into the hermetically sealed space 3. The injection part 4 includes an injection channel 36 communicating with the first vapor passage 51. The injection part 4 may be located at any position. As illustrated in FIGS. 9 and 10, the injection channel 36 may be in the form of a recess provided in the second body face 30b. Alternatively, the injection channel 36 may be in the form of a recess provided in the first body face 30a. Depending on the configuration of the first liquid channel part 60, the injection channel 36 may communicate with the first liquid channel part 60.

As illustrated in FIGS. 6, 10, and 11, the first liquid channel part 60 may be provided between the first sheet 10 and the wick sheet 30. According to the first embodiment, the first liquid channel part 60 is provided in the first body face 30a of the first land part 33. The first liquid channel part 60 may be a channel through which mainly the working liquid 2b passes. The working vapor 2a mentioned above may pass through the first liquid channel part 60. The first liquid channel part 60 constitutes a portion of the hermetically sealed space 3 mentioned above. The first liquid channel part 60 communicates with the vapor channel part 50. The first liquid channel part 60 is implemented as a capillary structure for transporting the working liquid 2b to the evaporation region SR. The first liquid channel part 60 is referred to also as wick in some cases. The first liquid channel part 60 may be provided across the entire first body face 30a of each first land part 33. Although not illustrated in FIG. 9 or other figures, the first liquid channel part 60 may be provided inside an area defined by the first body face 30a of the frame part 32. According to the first embodiment, the first liquid channel part 60 is provided neither in the second body face 30b of the first land part 33 nor in the second body face 30b of the frame part 32.

As illustrated in FIG. 12, the first liquid channel part 60 is an example of a first collection of grooves including a plurality of grooves. More specifically, the first liquid channel part 60 includes a plurality of main flow grooves 61, and a plurality of communication grooves 65. The main flow groove 61 and the communication groove 65 are grooves through which the working liquid 2b passes. The communication groove 65 communicates with the main flow groove 61.

As illustrated in FIG. 12, each main flow groove 61 extends in the X-direction. The main flow groove 61 has a small channel cross-sectional area that allows mainly the working liquid 2b to flow therethrough under capillary action. The main flow groove 61 is smaller in channel cross-sectional area than the vapor passages 51 and 52. The main flow groove 61 is configured to transport the working liquid 2b condensed from the working vapor 2a to the evaporation region SR. The main flow grooves 61 may be spaced apart from each other at equal intervals in the Y-direction orthogonal to the X-direction. The main flow grooves 61 may be positioned in parallel to each other.

The main flow groove 61 is formed in an etching step (described later) through etching performed from the first body face 30a of the wick sheet 30. The main flow groove 61 may thus have a curved wall face 62 as illustrated in FIG. 11. The wall face 62 defines the main flow groove 61. The wall face 62 may have such a curved shape that bulges toward the second body face 30b.

As illustrated in FIGS. 11 and 12, the main flow groove 61 may have a width w5 less than the width w2 of the first vapor channel recess 53. The width w5 of the main flow groove 61 may be less than the width w1 of the first land part 33. The width w5 of the main flow groove 61 may be, for example, 5 μm to 400 μm. The width w5 means a dimension of the main flow groove 61 at the location of the first body face 30a. In FIGS. 11 and 12, the width w5 corresponds to a dimension of the main flow groove 61 in the Y-direction. The main flow groove 61 may have a depth h1 of, for example, 3 μm to 300 μm. The depth h1 corresponds to a dimension of the main flow groove 61 in the Z-direction.

As illustrated in FIG. 12, each communication groove 65 extends in a direction different from the X-direction. According to the first embodiment, each communication groove 65 extends in the Y-direction, and is perpendicular to the main flow groove 61. Some communication grooves 65 provide communication between the main flow grooves 61 that are adjacent to each other. Other communication grooves 65 provide communication between the first vapor passage 51 or the second vapor passage 52, and the main flow groove 61. That is, each of the other communication groove 65 extends from a side edge 33a of the first land part 33 in the Y-direction to the main flow groove 61 adjacent to the side edge 33a. In this way, the first vapor passage 51 communicates with the main flow groove 61, and the second vapor passage 52 communicates with the main flow groove 61.

The communication groove 65 has a small channel cross-sectional area that allows mainly the working liquid 2b to flow therethrough under capillary action. The communication groove 65 has a channel cross-sectional area less than the channel cross-sectional area of each of the vapor passages 51 and 52. The communication grooves 65 are spaced apart from each other at equal intervals in the X-direction. The communication grooves 65 may be positioned in parallel to each other.

As with the main flow groove 61, the communication groove 65 is also formed through etching (described later). The communication groove 65 may thus have a curved wall face (not illustrated) similar to that of the main flow groove 61. The communication groove 65 may have a width w6 less than the width w2 of the first vapor channel recess 53. The width w6 of the communication groove 65 may be less than the width w1 of the first land part 33. As illustrated in FIG. 12, the width w6 of the communication groove 65 may be equal to the width w5 of the main flow groove 61. Alternatively, however, the width w6 may be greater than the width w5, or may be less than the width w5. The width w6 means a dimension of the communication groove 65 at the location of the first body face 30a. In FIG. 12, the width w6 corresponds to a dimension of the communication groove 65 in the X-direction. The communication groove 65 may have a depth equal to the depth h1 of the main flow groove 61. Alternatively, however, the depth of the communication groove 65 may be greater than the depth h1, or may be less than the depth h1.

As illustrated in FIG. 12, the first liquid channel part 60 includes projection rows 63. Each projection row 63 is disposed on the first body face 30a of the wick sheet 30. Each projection row 63 is disposed between the main flow grooves 61 that are adjacent to each other. Each projection row 63 includes a plurality of projections 64 arranged in the X-direction. The projections 64 abut on the first sheet 10. As illustrated in FIG. 12, each projection 64 has a rectangular shape in plan view with its longitudinal direction aligned with the X-direction. The main flow groove 61 is interposed between the projections 64 that are adjacent to each other in the Y-direction. The communication groove 65 is interposed between the projections 64 that are adjacent to each other in the X-direction.

The projection 64 is a part where the material of the wick sheet 30 remains without being etched away in an etching step (described later). According to the first embodiment, the projection 64 has a rectangular shape in plan view as illustrated in FIG. 12. More specifically, a shape of the projection 64 in plan view corresponds to a shape in plan view of the projection 64 at the location of the first body face 30a.

According to the first embodiment, the projections 64 are positioned in a staggered arrangement. More specifically, the projections 64 of the projection rows 63 that are adjacent to each other in the Y-direction are displaced relative to each other in the X-direction. The amount of displacement may be half the arrangement pitch of the projections 64 in the X-direction. The projection 64 may have a width w7 of, for example, 5 μm to 500 μm. The width w7 means a dimension of the projection 64 at the location of the first body face 30a. In FIG. 12, the width w7 corresponds to a dimension of the projection 64 in the Y-direction. The projections 64 are not necessarily positioned in a staggered arrangement. Alternatively, the projections 64 may be positioned in a parallel arrangement. In this case, the projections 64 of the projection rows 63 that are adjacent to each other in the Y-direction are located at the same position in the X-direction.

The first sheet 10, the second sheet 20, and the wick sheet 30 may be made of any material without particular limitation, as long as the material has favorable thermal conductivity sufficient to ensure adequate heat dissipation efficiency of the vapor chamber 1. For example, each of the sheets 10, 20, and 30 may be made of a metallic material. For example, each of the sheets 10, 20, and 30 may contain copper or a copper alloy. Copper and a copper alloy have favorable thermal conductivity, and exhibit corrosion resistance for cases where pure water is to be used as the working fluid. Examples of copper include pure copper and oxygen-free copper (C1020). Examples of copper alloys include: copper alloys containing tin; copper alloys containing titanium (e.g., C1990); and Corson copper alloys (e.g., C7025), which are copper alloys containing nickel, silicon, and magnesium. An example of copper alloys containing tin is phosphor bronze (e.g., C5210).

The first sheet 10, the second sheet 20, and the wick sheet 30 may be made of any material without particular limitation, as long as the material has favorable thermal conductivity. Each of the sheets 10, 20, and 30 may contain, for example, copper or a copper alloy. This can improve the thermal conductivity of the sheets 10, 20, and 30, and consequently improve the heat dissipation efficiency of the vapor chamber 1. This can also prevent corrosion for cases where pure water is used as the working fluids 2a and 2b. The sheets 10, 20, and 30 may be made of other metals such as aluminum or titanium, or other metallic alloys such as stainless steel, as long as use of such metallic materials allows a desired heat dissipation efficiency to be attained and also enables corrosion prevention.

The vapor chamber 1 illustrated in FIG. 5 may have a thickness t1 of, for example, 100 μm to 500 μm. Making the thickness t1 of the vapor chamber 1 greater than or equal to 100 μm can ensure adequate space for the vapor channel part 50. This allows for proper functioning of the vapor chamber 1. By contrast, making the thickness t1 less than or equal to 500 μm can mitigate an increase in the thickness t1 of the vapor chamber 1. This allows for reduced thickness of the vapor chamber 1.

The thickness of the wick sheet 30 may be greater than the thickness of the first sheet 10. Likewise, the thickness of the wick sheet 30 may be greater than the thickness of the second sheet 20. The first embodiment is directed to an exemplary case where the thickness of the first sheet 10 and the thickness of the second sheet 20 are equal. This, however, is not intended to be limiting. Alternatively, the thickness of the first sheet 10 and the thickness of the second sheet 20 may be different.

The first sheet 10 may have a thickness t2 of, for example, 6 μm to 100 μm. Making the thickness t2 of the first sheet 10 greater than or equal to 6 μm can ensure mechanical strength and long-term reliability of the first sheet 10. By contrast, making the thickness t2 of the first sheet 10 less than or equal to 100 μm can mitigate an increase in the thickness t1 of the vapor chamber 1. The thickness t3 of the second sheet 20 may be set similarly to the thickness t2 of the first sheet 10.

The wick sheet 30 may have a thickness t4 of, for example, 50 μm to 400 μm. Making the thickness t4 of the wick sheet 30 greater than or equal to 50 μm can ensure adequate space for the vapor channel part 50. This allows for proper functioning of the vapor chamber 1. By contrast, making the thickness t4 less than or equal to 400 μm can mitigate an increase in the thickness t1 of the vapor chamber 1. This allows for reduced thickness of the vapor chamber 1. The thickness t4 of the wick sheet 30 may be the distance between the first body face 30a and the second body face 30b.

As described above, the vapor chamber 1 according to the first embodiment is divided into the first region 5, the second region 6, and the bend region 7. In the bend region 7, the vapor chamber 1 is bent along the bend line 8 extending in a direction crossing the X-direction in plan view. As illustrated in FIGS. 4 and 5, the bend line 8 according to the first embodiment extends in the Y-direction in plan view. The Y-direction is a direction orthogonal to the X-direction in plan view. The bend line 8 crosses the frame part 32, the first land part 33, the first vapor passage 51, and the second vapor passage 52. This can reduce deformation that causes the first sheet 10 to enter the vapor passages 51 and 52, and can also reduce deformation that causes the second sheet 20 to enter the vapor passages 51 and 52. This can ensure that the first vapor passage 51 and the second vapor passage 52 have adequate channel cross-sectional area.

The first region 5, the second region 6, and the bend region 7 may be divided from each other by a boundary line lying along the bend line 8. As illustrated in FIGS. 4 and 5, the regions 5, 6, and 7 may be divided from each other by a boundary line extending in the Y-direction in plan view. The bend region 7 is a region including the bend line 8 and having a predetermined width. The bend region 7 is defined by a portion of the vapor chamber 1 where deformation occurs in the vapor chamber 1 due to bending. The first region 5 and the second region 6 each correspond to a region other than the bend region 7. That is, the first region 5 and the second region 6 are unbent regions. As illustrated in FIGS. 4 and 5, the first region 5 and the second region 6 may be regions extending in the XY-plane without undergoing bending. The first region 5 and the second region 6 may be each defined by a portion of the vapor chamber 1 in its bent state where no deformation has occurred.

The first region 5 and the second region 6 may be two regions separated by the bend region 7. The first region 5 may be a region located on one side (the left side in FIG. 5) of the bend region 7 in a direction (the X-direction in the illustrated example) orthogonal to the bend line 8. The first region 5 may be a region located on one side of the bend region 7 and adjacent to the bend region 7. The second region 6 may be a region located on the other side (the right side in FIG. 5) of the bend region 7 in the direction orthogonal to the bend line 8. The second region 6 may be a region located on the other side of the bend region 7 and adjacent to the bend region 7.

In the illustrated example, the first region 5 extends all the way from a boundary line bordering the bend region 7 to an end portion at one side (the left side in FIG. 5) of the vapor chamber 1 in the X-direction, and the second region 6 extends all the way from a boundary line bordering the bend region 7 to an end portion at the other side (the right side in FIG. 5) of the vapor chamber 1 in the X-direction. This, however, is not intended to be limiting. For example, the first region 5 does not necessarily have to extend all the way to the end portion at one side of the vapor chamber 1 in the X-direction, and likewise, the second region 6 does not necessarily have to extend all the way to the end portion at the other side of the vapor chamber 1 in the X-direction.

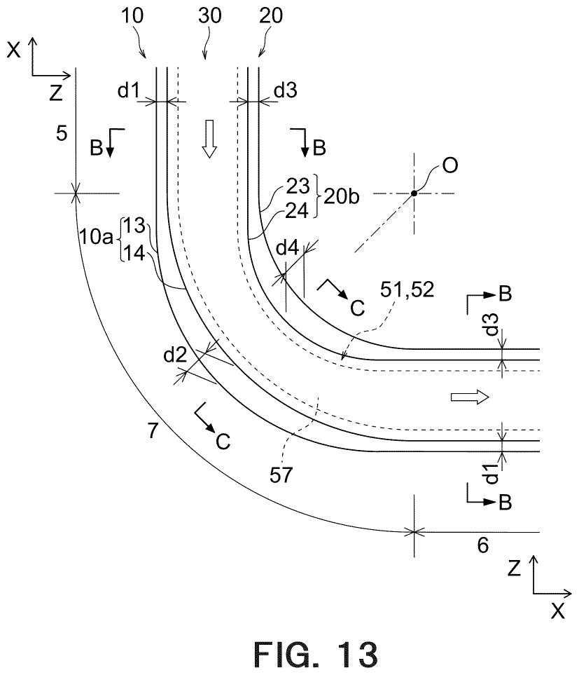

The vapor chamber 1 is bent as illustrated in FIG. 13. In the bend region 7, the first sheet 10 is located outward relative to the wick sheet 30 with respect to a center O of the bend. The second sheet 20 is located inward relative to the wick sheet 30 with respect to the center O of the bend.

As illustrated in FIG. 13, the vapor passages 51 and 52 may each include a passage bend part 57 located in the bend region 7. FIG. 13 illustrates an example of the passage bend part 57. Although the passage bend part 57 is illustrated in FIG. 13 as having the shape of a quarter-circular arc when viewed in the Y-direction, this is not intended to be limiting. The passage bend part 57 may include the first vapor channel recess 53 and the second vapor channel recess 54 mentioned above.

As illustrated in FIGS. 11, 13, and 14, the first-sheet outer face 10a of the first sheet 10 mentioned above may include a plurality of first bond regions 13, and a first vapor channel region 14. Each of the first bond regions 13 is a region overlapping the corresponding first land part 33 in plan view. The first bond region 13 is a region bonded to the first land part 33 of the wick sheet 30. The first vapor channel region 14 is an example of a first space region. The first vapor channel region 14 is a region overlapping the vapor channel part 50 in plan view. The first vapor channel region 14 is a region not bonded to the wick sheet 30. The first vapor channel region 14 may have a recessed channel cross-section that is recessed inward toward the vapor channel part 50. The first vapor channel region 14 may have a curved shape.

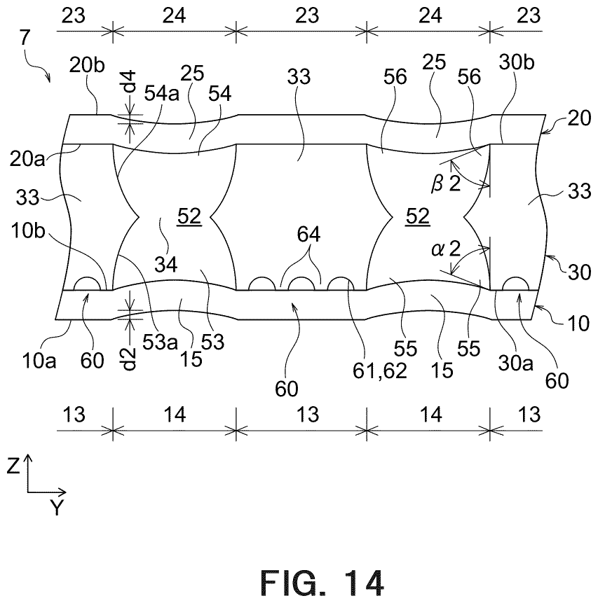

The first vapor channel region 14 of the first-sheet outer face 10a may have a recessed shape in each of the first region 5, the second region 6, and the bend region 7. More specifically, in each of the first region 5 and the second region 6, the first vapor channel region 14 may have a recessed shape as illustrated in FIG. 11. FIG. 11 is a cross-section taken along a line B-B of FIG. 13. In the bend region 7, the first vapor channel region 14 may have a recessed shape as illustrated in FIG. 14. FIG. 14 is a cross-section taken along a line C-C of FIG. 13. The first vapor channel region 14 may have a recessed shape across the entire first-sheet outer face 10a.

As illustrated in FIGS. 11 and 14, the first sheet 10 may have a first-sheet recess 15 overlapping the first vapor channel region 14 in plan view. The first-sheet recess 15 extends into the first vapor channel recess 53.

The first bond region 13 of the first sheet 10 is bonded to the first land part 33. Accordingly, upon bending of the vapor chamber 1, the first bond region 13 deforms along the first land part 33. By contrast, the first vapor channel region 14 of the first sheet 10 covers each of the vapor passages 51 and 52 of the vapor channel part 50. Accordingly, the first vapor channel region 14 is less susceptible to stretching than is the first bond region 13. As a result, the first vapor channel region 14 undergoes comparatively less stretching. As illustrated in FIG. 14, the first-sheet recess 15 is displaced inward into the first vapor channel recess 53.

The recessed portion of the first vapor channel region 14 in the bend region 7 is dimensioned to be larger than the recessed portion of the first vapor channel region 14 in each of the first region 5 and the second region 6. As illustrated in FIG. 13, when viewed in a direction parallel to the bend line 8, a maximum dimension d2 in the bend region 7 is greater than a maximum dimension d1 in each of the first region 5 and the second region 6. The maximum dimension d1 is a dimension defined between the first bond region 13 and the first vapor channel region 14 in each of the first region 5 and the second region 6. The maximum dimension d1 is a dimension in the thickness direction of the first sheet 10. The thickness direction of the first sheet 10 corresponds to the Z-direction. The maximum dimension d2 is a dimension defined between the first bond region 13 and the first vapor channel region 14 in the bend region 7. The maximum dimension d2 is a dimension in the thickness direction of the first sheet 10. FIG. 13 is an illustration viewed in a direction parallel to the bend line 8, in other words, in the Y-direction. The maximum dimensions d1 and d2 that are defined between the first bond region 13 and the first vapor channel region 14, and that are the maximum dimensions d1 and d2 in the thickness direction of the first sheet 10 are also respectively referred to as first maximum dimensions d3 and d4. In this regard, when it is stated herein that the maximum dimension d2 in the bend region 7 is greater than the maximum dimension d1 in each of the first region 5 and the second region 6, it may suffice that the maximum dimension d2 at a given position in the bend region 7 be greater than the maximum dimension d1 at a given position in each of the first region 5 and the second region 6, and it is not required that the maximum dimension d2 at every position in the bend region 7 be greater than the maximum dimension d1 at every position in each of the first region 5 and the second region 6.

FIG. 11 is a cross-section, orthogonal to the X-direction, of the vapor chamber 1 in each of the first region 5 and the second region 6. According to the first embodiment, the first vapor channel region 14 is recessed in each of the first region 5 and the second region 6. The first bond region 13 has a flat shape in each of the X-direction and the Y-direction. The dimension d1 mentioned above may be the depth of the corresponding recess. The dimension d1 may be the distance between the position of the most recessed portion of the first vapor channel region 14, and a straight line on the first bond region 13 that overlaps the above-mentioned position when viewed in a direction normal to the above-mentioned position, and that extends in the Y-direction. That is, the dimension d1 may be the distance in the Z-direction between the position of the most recessed portion of the first vapor channel region 14, and the position of the flat portion of the first bond region 13. The dimension d1 may be obtained from each of the first region 5 and the second region 6. The dimension d1 in the first region 5, and the dimension d1 in the second region 6 may be equal or may be different.

FIG. 14 is a cross-section, orthogonal to the X-direction, of the vapor chamber 1 in the bend region 7. According to the first embodiment, the first vapor channel region 14 in the bend region 7 is recessed. The first bond region 13 in the bend region 7 has a flat shape in the Y-direction. The dimension d2 mentioned above may be the depth of the corresponding recess. The dimension d2 may be the distance between the position of the most recessed portion of the first vapor channel region 14, and a straight line on the first bond region 13 that overlaps the above-mentioned position when viewed in a direction normal to the above-mentioned position, and that extends in the Y-direction. That is, the dimension d2 may be the distance in the Z-direction between the position of the most recessed portion of the first vapor channel region 14, and the position of the flat portion of the first bond region 13. FIG. 14 is a cross-section taken along a line C-C of FIG. 13. FIG. 14 is a cross-section at the position where the first vapor channel region 14 is most recessed. FIG. 14 depicts a cross-section at a position displaced rotationally with respect to the center O of the bend by 45 degrees from the boundary between the first region 5 and the bend region 7. However, the position where the first vapor channel region 14 is most recessed is not limited to the above-mentioned position.

The first vapor channel region 14 illustrated in FIG. 14 is recessed more greatly than is the first vapor channel region 14 illustrated in FIG. 11. The dimension d2 is thus greater than the dimension d1. The first-sheet recess 15 in the bend region 7 extends more deeply into the first vapor channel recess 53 than does the first-sheet recess 15 in each of the first region 5 and the second region 6.

As illustrated in FIGS. 11 and 14, the first-sheet inner face 10b at the location of the first-sheet recess 15, and the wall face 53a of the first vapor channel recess 53 define a channel corner 55, which constitutes a portion of the vapor channel cross-section. The channel corner 55 may be wedge-shaped.

As illustrated in FIG. 11, in each of the first region 5 and the second region 6, the first-sheet inner face 10b and the wall face 53a may form an angle α1. The angle α1 may be an acute angle. The angle α1 may be defined, at the intersection of the first-sheet inner face 10b and the wall face 53a, by a tangent to the first-sheet inner face 10b and a tangent to the wall face 53a.

As illustrated in FIG. 14, in the bend region 7, the first-sheet inner face 10b and the wall face 53a may form an angle α2. The angle α2 may be defined similarly to the angle α1.

The angle α2 illustrated in FIG. 14 may be less than the angle α1 illustrated in FIG. 11. This is because the first vapor channel region 14 illustrated in FIG. 14 is recessed more greatly than is the first vapor channel region 14 illustrated in FIG. 11. In this case, the capillary action at the channel corner 55 illustrated in FIG. 14 may be stronger than the capillary action at the channel corner 55 illustrated in FIG. 11.

As with the first land part 33, the first vapor channel region 14 may extend in the X-direction in each of the first region 5, the second region 6, and the bend region 7. Likewise, the first-sheet recess 15 and the channel corner 55 may extend similarly in the X-direction.

As illustrated in FIGS. 11, 13, and 14, the second-sheet outer face 20b of the second sheet 20 mentioned above may include a plurality of second bond regions 23, and a second vapor channel region 24. Each of the second bond regions 23 is a region overlapping the corresponding first land part 33 in plan view. The second bond region 23 is a region bonded to the first land part 33 of the wick sheet 30. The second vapor channel region 24 is an example of a second space region. The second vapor channel region 24 is a region overlapping the vapor channel part 50 in plan view. The second vapor channel region 24 is a region not bonded to the wick sheet 30. The second vapor channel region 24 may have a recessed channel cross-section that is recessed inward toward the vapor channel part 50. The second vapor channel region 24 may have a curved shape.

The second vapor channel region 24 of the second-sheet outer face 20b may have a recessed shape in each of the first region 5, the second region 6, and the bend region 7. More specifically, in each of the first region 5 and the second region 6, the second vapor channel region 24 may have a recessed shape as illustrated in FIG. 11. In the bend region 7, the second vapor channel region 24 may have a recessed shape as illustrated in FIG. 14. The second vapor channel region 24 may have a recessed shape across the entire second-sheet outer face 20b.

As illustrated in FIGS. 11 and 14, the second sheet 20 may have a second-sheet recess 25 overlapping the second vapor channel region 24 in plan view. The second-sheet recess 25 extends into the second vapor channel recess 54.

The second bond region 23 of the second sheet 20 is bonded to the first land part 33. Accordingly, upon bending of the vapor chamber 1, the second bond region 23 deforms along the first land part 33. By contrast, the second vapor channel region 24 covers each of the vapor passages 51 and 52 of the vapor channel part 50. Accordingly, the second vapor channel region 24 is susceptible to contraction. Since the second sheet 20 is located at the inner side, a jig (not illustrated) abuts on the second-sheet outer face 20b of the second sheet 20. This restricts inward displacement of the second vapor channel region 24. As illustrated in FIG. 13, the second-sheet recess 25 is displaced outward into the second vapor channel recess 54.

The recessed portion of the second vapor channel region 24 in the bend region 7 is dimensioned to be larger than the recessed portion of the second vapor channel region 24 in each of the first region 5 and the second region 6. As illustrated in FIG. 13, when viewed in a direction parallel to the bend line 8, the maximum dimension d4 in the bend region 7 is greater than the maximum dimension d3 in each of the first region 5 and the second region 6. The maximum dimension d3 is a dimension defined between the second bond region 23 and the second vapor channel region 24 in each of the first region 5 and the second region 6. The maximum dimension d3 is a dimension in the thickness direction of the second sheet 20. The thickness direction of the second sheet 20 corresponds to the Z-direction. The maximum dimension d4 is a dimension defined between the second bond region 23 and the second vapor channel region 24 in the bend region 7. The maximum dimension d4 is a dimension in the thickness direction of the second sheet 20. The maximum dimensions d3 and d4 that are defined between the second bond region 23 and the second vapor channel region 24, and that are the maximum dimensions d3 and d4 in the thickness direction of the second sheet 20 are also respectively referred to as second maximum dimensions d3 and d4. In this regard, when it is stated herein that the maximum dimension d4 in the bend region 7 is greater than the maximum dimension d3 in each of the first region 5 and the second region 6, it may suffice that the maximum dimension d4 at a given position in the bend region 7 be greater than the maximum dimension d3 at a given position in each of the first region 5 and the second region 6, and it is not required that the maximum dimension d4 at every position in the bend region 7 be greater than the maximum dimension d3 at every position in each of the first region 5 and the second region 6.

According to the first embodiment, the second vapor channel region 24 is recessed in each of the first region 5 and the second region 6. The second bond region 23 has a flat shape in each of the X-direction and the Y-direction. The dimension d3 mentioned above may be the depth of the corresponding recess. The dimension d3 may be the distance between the position of the most recessed portion of the second vapor channel region 24, and a straight line on the second bond region 23 that overlaps the above-mentioned position when viewed in a direction normal to the above-mentioned position, and that extends in the Y-direction. That is, the dimension d3 may be the distance in the Z-direction between the position of the most recessed portion of the second vapor channel region 24, and the position of the flat portion of the second bond region 23. The dimension d3 may be obtained from each of the first region 5 and the second region 6. The dimension d3 in the first region 5, and the dimension d3 in the second region 6 may be equal or may be different.

According to the first embodiment, the second vapor channel region 24 in the bend region 7 is recessed. The second bond region 23 in the bend region 7 has a flat shape in the Y-direction. The dimension d4 mentioned above may be the depth of the corresponding recess. The dimension d4 may be the distance between the position of the most recessed portion of the second vapor channel region 24, and a straight line on the second bond region 23 that overlaps the above-mentioned position when viewed in a direction normal to the above-mentioned position, and that extends in the Y-direction. That is, the dimension d4 may be the distance in the Z-direction between the position of the most recessed portion of the second vapor channel region 24, and the position of the flat portion of the second bond region 23. Although FIG. 14 is a cross-section at the position where the second vapor channel region 24 is most recessed, the position where the second vapor channel region 24 is most recessed is not limited to the above-mentioned position.

The second vapor channel region 24 in FIG. 14 is recessed more greatly than is the second vapor channel region 24 illustrated in FIG. 11. The dimension d4 is thus greater than the dimension d3. The second-sheet recess 25 in the bend region 7 extends more deeply into the second vapor channel recess 54 than does the second-sheet recess 25 in each of the first region 5 and the second region 6.

As illustrated in FIGS. 11 and 14, the second-sheet inner face 20a at the location of the second-sheet recess 25, and the wall face 54a of the second vapor channel recess 54 define a channel corner 56, which constitutes a portion of the vapor channel cross-section. The channel corner 56 may be wedge-shaped.

As illustrated in FIG. 11, in each of the first region 5 and the second region 6, the second-sheet inner face 20a and the wall face 54a may form an angle β1. The angle β1 may be an acute angle. The angle β1 may be defined, at the intersection of the second-sheet inner face 20a and the wall face 54a, by a tangent to the second-sheet inner face 20a and a tangent to the wall face 54a.

As illustrated in FIG. 14, in the bend region 7, the second-sheet inner face 20a and the wall face 53a may form an angle β2. The angle β2 may be defined similarly to the angle β1.

The angle β2 illustrated in FIG. 14 may be less than the angle β1 illustrated in FIG. 11. This is because the second vapor channel region 24 illustrated in FIG. 14 is recessed more greatly than is the second vapor channel region 24 illustrated in FIG. 11. In this case, the capillary action at the channel corner 56 illustrated in FIG. 14 may be stronger than the capillary action at the channel corner 56 illustrated in FIG. 11.

As with the first land part 33, the second vapor channel region 24 may extend in the X-direction in each of the first region 5, the second region 6, and the bend region 7. Likewise, the second-sheet recess 25 and the channel corner 56 may extend similarly in the X-direction.

As described above, the first sheet 10 and the second sheet 20 may be thinner than the wick sheet 30. In this case, applying stress on a portion of the first sheet 10 that overlaps the vapor channel part 50 allows distortion to remain in the portion. Likewise, applying stress on a portion of the second sheet 20 that overlaps the vapor channel part 50 allows distortion to remain in the portion. Due to the presence of such residual distortion, even in a pre-bending state, the first vapor channel region 14 and the second vapor channel region 24 can be formed into a recessed shape in each of the first region 5, the second region 6, and the bend region 7. For example, the first sheet 10 and the second sheet 20 are more likely to exhibit residual distortion when subjected to stress applied while being softened by heating, or more likely to exhibit residual distortion when subjected to stress applied after being softened by heating. The first vapor channel region 14 and the second vapor channel region 24 can be thus formed into a recessed shape. However, as will be described later, the first vapor channel region 14 in a pre-bending state may have a flat shape in each of the first region 5, the second region 6, and the bend region 7. Likewise, the second vapor channel region 24 in a pre-bending state may have a flat shape in each of the first region 5, the second region 6, and the bend region 7.

Reference is now made to a method for manufacturing the vapor chamber 1 according to the first embodiment configured as described above.

First, as a preparing step, the first sheet 10, the second sheet 20, and the wick sheet 30 are prepared. The preparing step may include an etching step of forming the wick sheet 30 through etching. In the etching step, the wick sheet 30 may be formed through etching by use of a patterned resist film (not illustrated) based on the photolithography technique.

As a temporary fastening step, the first sheet 10, the wick sheet 30, and the second sheet 20 are temporarily fastened together. For example, the sheets 10, 20, and 30 may be temporarily fastened together by spot welding or laser welding. At this time, the sheets 10, 20, and 30 may be aligned with each other by use of the alignment holes 12, 22, and 35.

Subsequently, as a bonding step, the first sheet 10, the wick sheet 30, and the second sheet 20 are permanently bonded to each other. The sheets 10, 20, and 30 may be bonded to each other by diffusion bonding.

The bonding step is followed by an injection step. In the injection step, the hermetically sealed space 3 is evacuated to a vacuum, and the working liquid 2b is injected into the hermetically sealed space 3 from the injection part 4 (see FIG. 5).

The injection step is followed by a sealing step, in which the injection channel 36 mentioned above is sealed off. This cuts off communication between the hermetically sealed space 3 and the external environment, resulting in hermetic sealing of the hermetically sealed space 3. As a result, the hermetically sealed space 3 with the working liquid 2b sealed therein is obtained, and external leakage of the working liquid 2b sealed in the hermetically sealed space 3 is prevented.

The sealing step may be followed by a bending step, in which the first sheet 10, the second sheet 20, and the wick sheet 30 are bent. For example, the sheets 10, 20, and 30 are bent along the bend line 8 extending in the Y-direction as illustrated in FIG. 5. At this time, a jig (not illustrated) abuts on the second-sheet outer face 20b of the second sheet 20, which is located at the inner side of the bend. With the sheets 10, 20, and 30 held at their opposite ends in the X-direction, the sheets 10, 20, and 30 are each bent at a desired angle. Consequently, the vapor chamber 1 in its bent state illustrated in FIG. 4 is obtained, and the vapor chamber 1 is divided into the first region 5, the second region 6, and the bend region 7. The bending step may be performed between the bonding step and the injection step.

The vapor chamber 1 according to the first embodiment is obtained through the above-mentioned process.

Reference is now made to how the vapor chamber 1 operates, that is, how the electronic device D is cooled.

The vapor chamber 1 obtained as described above is installed inside the housing H of, for example, a mobile terminal. In the first region 5, the first-sheet outer face 10a of the first sheet 10 is in contact with the housing component Ha. In the second region 6, the second-sheet outer face 20b of the second sheet 20 is in contact with the electronic device D. The working liquid 2b within the hermetically sealed space 3 adheres, due to its surface tension, to the wall face of the hermetically sealed space 3. More specifically, the working liquid 2b adheres to the following wall faces: the wall face 53a of the first vapor channel recess 53; the wall face 54a of the second vapor channel recess 54; the wall face 62 of the main flow groove 61 of the first liquid channel part 60; and the wall face of the communication groove 65 of the first liquid channel part 60. The working liquid 2b may also adhere to a portion of the first-sheet inner face 10b of the first sheet 10 that is exposed to the first vapor channel recess 53. Further, the working liquid 2b may also adhere to portions of the second-sheet inner face 20a of the second sheet 20 that are exposed to the following areas: the second vapor channel recess 54, the main flow groove 61, and the communication groove 65.

When the electronic device D generates heat in this state, the working liquid 2b in the evaporation region SR receives heat from the electronic device D. As the received heat is absorbed as latent heat, the working liquid 2b evaporates, and the working vapor 2a is generated. The generated working vapor 2a diffuses within the first vapor passage 51 and the second vapor passage 52, which constitute the hermetically sealed space 3 (see solid arrows in FIG. 9). More specifically, in a portion of the first vapor passage 51 of the vapor channel part 50 that extends in the X-direction, and in the second vapor passage 52, the working vapor 2a diffuses mainly in the X-direction. In this case, a portion of the working vapor 2a diffuses by passing through the passage bend part 57. Meanwhile, in a portion of the first vapor passage 51 that extends in the Y-direction, the working vapor 2a diffuses mainly in the Y-direction.

The working vapor 2a within each of the vapor passages 51 and 52 is then transported away from the evaporation region SR to the condensation region CR, which is at a relatively low temperature. In the condensation region CR, the working vapor 2a is cooled by rejecting heat mainly to the first sheet 10. The heat received by the first sheet 10 from the working vapor 2a is transferred to the outside air via the housing component Ha (see FIG. 6).

As the working vapor 2a rejects heat to the first sheet 10 in the condensation region CR, the working vapor 2a gives off the latent heat absorbed in the evaporation region SR. The working vapor 2a thus condenses, and the working liquid 2b is generated. The generated working liquid 2b adheres to the respective wall faces 53a and 54a of the vapor channel recesses 53 and 54, the first-sheet inner face 10b of the first sheet 10, and the second-sheet inner face 20a of the second sheet 20. At this time, the working liquid 2b keeps evaporating in the evaporation region SR. The working liquid 2b in the condensation region CR of the first liquid channel part 60 is thus transported by the capillary action of each main flow groove 61 toward the evaporation region SR (see dashed arrows in FIG. 9). Consequently, the working liquid 2b adhering on the wall faces 53a and 54a, the first-sheet inner face 10b, and the second-sheet inner face 20a moves to the first liquid channel part 60, where the working liquid 2b passes through the communication groove 65 into the main flow groove 61. In this way, each main flow groove 61 and each communication groove 65 are filled with the working liquid 2b. The working liquid 2b now filling these grooves gains, due to the capillary action of each main flow groove 61, a propulsion force that causes the working liquid 2b to move toward the evaporation region SR. The working liquid 2b is thus smoothly transported toward the evaporation region SR. As illustrated in FIG. 4, the working liquid 2b is transported under capillary action even when the evaporation region SR is located in an upper part of the vapor chamber 1.

In the first liquid channel part 60, each main flow groove 61 communicates with another adjacent main flow groove 61 via the corresponding communication groove 65. The working liquid 2b thus moves back and forth between the main flow grooves 61 that are adjacent to each other. This reduces the risk of dry-out in the main flow grooves 61. As a result, capillary action is imparted to the working liquid 2b within each main flow groove 61, and the working liquid 2b is thus smoothly transported toward the evaporation region SR.

Upon reaching the evaporation region SR, the working liquid 2b evaporates by receiving heat from the electronic device D again. The working vapor 2a evaporated from the working liquid 2b passes through the communication groove 65 within the evaporation region SR to the first vapor channel recess 53 and the second vapor channel recess 54, each of which has a large channel cross-sectional area. Then, the working vapor 2a diffuses within each of the vapor channel recesses 53 and 54, and a portion of the working vapor 2a is allowed to diffuse by passing through the passage bend part 57. In this way, the working fluids 2a and 2b undergo refluxing within the hermetically sealed space 3 while repeating phase changes, that is, evaporation and condensation. Heat from the electronic device D is thus diffused and released. As a result, the electronic device D is cooled.

As illustrated in FIGS. 11 and 14, in the first region 5, the second region 6, and the bend region 7, the first vapor channel region 14 of the first-sheet outer face 10a has a recessed shape. The channel corner 55 mentioned above, which is capable of exerting capillary action, is defined within the first vapor channel recess 53. As a result, due to the presence of the channel corner 55, the working liquid 2b condensed within the vapor channel part 50 is transported toward the evaporation region SR.

More specifically, as illustrated in FIG. 13, when viewed in the direction parallel to the bend line 8, the maximum dimension d2 in the bend region 7 (the first maximum dimension d2) is greater than the maximum dimension d1 in each of the first region 5 and the second region 6 (the first maximum dimension d1). Consequently, the capillary action occurring at the channel corner 55 in the bend region 7 is stronger than the capillary action occurring at the channel corner 55 in each of the first region 5 and the second region 6.

Likewise, in the first region 5, the second region 6, and the bend region 7, the second vapor channel region 24 of the second-sheet outer face 20b has a recessed shape. The channel corner 56 mentioned above, which is capable of exerting capillary action, is defined within the second vapor channel recess 54. As a result, due to the presence of the channel corner 56, the working liquid 2b condensed within the vapor channel part 50 is transported toward the evaporation region SR.

More specifically, when viewed in the direction parallel to the bend line 8, the maximum dimension d4 in the bend region 7 (the second maximum dimension d4) is greater than the maximum dimension d3 in each of the first region 5 and the second region 6 (the second maximum dimension d3). Consequently, the capillary action occurring at the channel corner 56 in the bend region 7 is stronger than the capillary action occurring at the channel corner 55 in each of the first region 5 and the second region 6.

At the outer side of the passage bend part 57, the working vapor 2a is susceptible to collision with the first-sheet inner face 10b. Upon such collision, the working vapor 2a condenses into the working liquid 2b, which adheres to the first-sheet inner face 10b. Due to the capillary action of the channel corner 55 mentioned above, a portion of the adhering working liquid 2b is transported through the channel corner 55 toward the evaporation region SR. Another portion of the working liquid 2b adhering on the first-sheet inner face 10b passes through the communication groove 65 of the first liquid channel part 60 into the main flow groove 61. The working liquid 2b is then transported toward the evaporation region SR due to the capillary action of each main flow groove 61. This reduces stagnation of the working liquid 2b that has adhered to the first-sheet inner face 10b in the bend region 7.

At the inner side of the passage bend part 57, the flow of the working vapor 2a may be allowed to separate from the second-sheet inner face 20a. This is explained below in more detail. In an area near the exit of the passage bend part 57, eddies are formed, and the working vapor 2a condenses and adheres onto the second-sheet inner face 20a. The area near the exit of the passage bend part 57 corresponds to a portion of the passage bend part 57 that is located relatively close to the second region 6. Due to the capillary action of the channel corner 56 mentioned above, a portion of the adhering working liquid 2b is transported through the channel corner 55 toward the evaporation region SR. This reduces stagnation of the working liquid 2b that has adhered to the second-sheet inner face 20a in the bend region 7.

As described above, according to the first embodiment, the first land parts 33 of the wick sheet 30 are spaced apart from each other in the Y-direction orthogonal to the X-direction, and in the bend region 7, the vapor chamber 1 is bent along the bend line 8, which extends in a direction crossing the X-direction in plan view. When viewed in the direction parallel to the bend line 8, the maximum dimension d2 in the bend region 7 (the first maximum dimension d2) is greater than the maximum dimension d1 (the first maximum dimension d1) in a region (each of the first region 5 and the second region 6) other than the bend region 7. Consequently, in the bend region 7, the first sheet 10 is allowed to extend into the first vapor passage 51 and the second vapor passage 52, and the channel corner 55 with enhanced capillary action can be thus formed in each of the vapor passages 51 and 52. As a result, in the bend region 7, the working liquid 2b condensed from the working vapor 2a can be transported to the evaporation region SR by the capillary action of the channel corner 55. Further, the condensed working liquid 2b can be efficiently moved to the first liquid channel part 60 communicating with the vapor passages 51 and 52. This can reduce the risk that the working liquid 2b stagnates in the vapor passages 51 and 52 in the bend region 7, and consequently reduce the risk that the flow of the working vapor 2a is inhibited by the working liquid 2b. This allows the vapor chamber 1 to exhibit improved heat dissipation efficiency even in its bent state.

The large maximum dimension d2 in the bend region 7 allows the first sheet 10 to have an increased surface area in the bend region 7. This can lead to improved efficiency of external dissipation of heat via the housing component Ha, and consequently to improved cooling capacity of the vapor chamber 1. Further, in the bend region 7, an increase in the vapor pressure of the working vapor 2a can be mitigated. This can reduce the difference between the vapor pressure of the working vapor 2a in the bend region 7, and the vapor pressure of the working vapor 2a in each of the first region 5 and the second region 6. As a result, the working vapor 2a can be transported smoothly. Further, the increased surface area of the first sheet 10 can increase the force with which the first sheet 10 adheres to the housing component Ha in the bend region 7 by means of, for example, an adhesive tape. This can lead to improved reliability of the vapor chamber 1.

According to the first embodiment, the first vapor channel region 14 of the first-sheet outer face 10a has a recessed shape. Consequently, in each of the first region 5, the second region 6, and the bend region 7, the channel corner 55 with enhanced capillary action can be formed in the first vapor passage 51 and the second vapor passage 52. As a result, the working liquid 2b condensed from the working vapor 2a can be transported to the evaporation region SR by the capillary action of the channel corner 55.

The recessed shape of the first vapor channel region 14 allows for increased surface area of the first sheet 10. This can lead to improved efficiency of external dissipation of heat via the housing component Ha, and consequently to improved cooling capacity of the vapor chamber 1. Further, in the bend region 7, an increase in the vapor pressure of the working vapor 2a can be mitigated. This can reduce the difference between the vapor pressure of the working vapor 2a in the bend region 7, and the vapor pressure of the working vapor 2a in each of the first region 5 and the second region 6. As a result, the working vapor 2a can be transported smoothly. Further, the increased surface area of the first sheet 10 can increase the force with which the first sheet 10 adheres to the housing component Ha by means of, for example, an adhesive tape. This can lead to improved reliability of the vapor chamber 1.

According to the first embodiment, in the bend region 7, the vapor chamber 1 is bent along the bend line 8 extending in the Y-direction. This allows the vapor chamber 1 to be bent in a direction orthogonal to the X-direction in which the first land part 33 extends. As a result, in the first region 5, the second region 6, and the bend region 7, an excessive increase in the maximum dimension between the first bond region 13 and the first vapor channel region 14 can be mitigated. This can ensure that the first vapor passage 51 and the second vapor passage 52 each have adequate cross-sectional area in the bend region 7. This can, in turn, reduce the risk that the flow of the working vapor 2a is inhibited in the bend region 7.

According to the first embodiment, the first body face 30a of the first land part 33 is provided with the first liquid channel part 60. In the bend region 7, the first sheet 10 is located outward relative to the wick sheet 30. The configuration mentioned above can ensure that, as the working vapor 2a flowing in the passage bend part 57 condenses upon collision with the first-sheet inner face 10b, the resulting working liquid 2b can be readily guided to the first liquid channel part 60. The working liquid 2b can be thus transported smoothly toward the evaporation region SR. This can reduce the risk that the working liquid 2b stagnates in the vapor passages 51 and 52 in the bend region 7, and consequently reduce the risk that the flow of the working vapor 2a is inhibited.

According to the first embodiment, when viewed in the direction parallel to the bend line 8, the maximum dimension d4 in the bend region 7 (the second maximum dimension d4) is greater than the maximum dimension d3 (the second maximum dimension d3) in a region (each of the first region 5 and the second region 6) other than the bend region 7. Consequently, in the bend region 7, the second sheet 20 is allowed to extend into the first vapor passage 51 and the second vapor passage 52, and the channel corner 56 with enhanced capillary action can be thus formed in each of the vapor passages 51 and 52. As a result, in the bend region 7, the working liquid 2b condensed from the working vapor 2a can be transported to the evaporation region SR by the capillary action of the channel corner 56. Further, the condensed working liquid 2b can be efficiently moved to the first liquid channel part 60 communicating with the vapor passages 51 and 52. This can reduce the risk that the working liquid 2b stagnates in the vapor passages 51 and 52 in the bend region 7, and consequently reduce the risk that the flow of the working vapor 2a is inhibited.

In the bend region 7, the working liquid 2b tends to stagnate at the inner side of the bend where the working vapor 2a has a low vapor pressure. This means that allowing the working liquid 2b to move efficiently at the inner side of the bend to the first liquid channel part 60 makes it possible to effectively mitigate an increase in the channel resistance to the flow of the working vapor 2a in the bend region 7. Further, the large maximum dimension d4 allows the flow of the working vapor 2a along the inner wall of the second sheet 20 to be easily deflected along the shape of the bend. As a result, the working vapor 2a can be transported smoothly.

The foregoing description of the first embodiment is directed to the example in which the first vapor channel region 14 of the first-sheet outer face 10a has a recessed shape in each of the first region 5, the second region 6, and the bend region 7. This, however, is not intended to be limiting. Rather, it may simply suffice that the first vapor channel region 14 in the bend region 7 has a recessed shape, and that the maximum dimension d2 mentioned above is greater than the dimension d1 mentioned above.

For example, the first vapor channel region 14 of the first-sheet outer face 10a in one of the first region 5 and the second region 6 may have a flat shape in the Y-direction. The first vapor channel region 14 of the first-sheet outer face 10a in both of the first region 5 and the second region 6 may have a flat shape in the Y-direction. In this case, the maximum dimension d1 mentioned above may be zero. For example, if the first vapor channel region 14 illustrated in FIG. 11 has a flat shape, the difference between the capillary force exerted at the channel corner 55 illustrated in FIG. 11, and the capillary force exerted at the channel corner 55 illustrated in FIG. 14 can be increased. This allows for relatively increased capillary action at the channel corner 55 in the bend region 7. This also allows for relatively increased surface area of the first sheet 10 in the bend region 7. As a result, heat can be dissipated externally via the housing component Ha with improved efficiency. This can lead to improved cooling capacity of the vapor chamber 1. Further, in the bend region 7, an increase in the vapor pressure of the working vapor 2a can be mitigated. This can lead to a reduced difference between the vapor pressure of the working vapor 2a in the bend region 7, and the vapor pressure of the working vapor 2a in each of the first region 5 and the second region 6. As a result, the working vapor 2a can be transported smoothly. Further, the flat shape of the first vapor channel region 14 can reduce the risk of a gap being created between the first vapor channel region 14 and the housing component Ha. This can ensure sufficiently close contact with the housing component Ha. As a result, heat can be dissipated externally via the housing component Ha with improved efficiency.

Likewise, the second vapor channel region 24 of the second-sheet outer face 20b in one of the first region 5 and the second region 6 may have a flat shape in the Y-direction. The second vapor channel region 24 of the second-sheet outer face 20b in both of the first region 5 and the second region 6 may have a flat shape in the Y-direction. In this case, the maximum dimension d3 mentioned above may be zero. For example, if the second vapor channel region 24 illustrated in FIG. 11 has a flat shape, the difference between the capillary force exerted at the channel corner 56 illustrated in FIG. 11 and the capillary force exerted at the channel corner 56 illustrated in FIG. 14 can be increased. This allows for relatively increased capillary action at the channel corner 56 in the bend region 7. This also allows for relatively increased surface area of the second sheet 20 in the bend region 7. As a result, heat can be dissipated externally via the housing component Ha with improved efficiency. This can lead to improved cooling capacity of the vapor chamber 1. Further, in the bend region 7, an increase in the vapor pressure of the working vapor 2a can be mitigated. This can lead to a reduced difference between the vapor pressure of the working vapor 2a in the bend region 7, and the vapor pressure of the working vapor 2a in each of the first region 5 and the second region 6. As a result, the working vapor 2a can be transported smoothly. Further, the flat shape of the second vapor channel region 24 can reduce the risk of a gap being created between the second vapor channel region 24 and the electronic device D. This can ensure sufficiently close contact with the electronic device D. As a result, the electronic device D can be cooled efficiently.

According to the first embodiment mentioned above, in the bend region 7, the amount of recessing of the second vapor channel region 24 of the second sheet 20, which is located at the inner side of the bend, may be less than the amount of recessing of the first vapor channel region 14 of the first sheet 10, which is located at the outer side of the bend. That is, the maximum dimension d4 mentioned above may be less than the maximum dimension d2 mentioned above. This configuration can mitigate a decrease in the channel cross-sectional area of the second vapor channel recess 54, and consequently mitigate an increase in the channel resistance to the working vapor 2a. As a result, the working vapor 2a can be transported smoothly.

According to the first embodiment mentioned above, in the bend region 7, the amount of recessing of the first vapor channel region 14 of the first sheet 10, which is located at the outer side of the bend, may be less than the amount of recessing of the second vapor channel region 24 of the second sheet 20, which is located at the inner side of the bend. That is, the maximum dimension d2 mentioned above may be less than the maximum dimension d4 mentioned above. The maximum dimension d2 mentioned above may be zero. This configuration can mitigate a decrease in the channel cross-sectional area of the first vapor channel recess 53, and consequently mitigate an increase in the channel resistance to the working vapor 2a. As a result, the working vapor 2a can be transported smoothly.

According to the first embodiment mentioned above, in the bend region 7, the amount of recessing of the first vapor channel region 14 of the first sheet 10, which is a sheet at which the first liquid channel part 60 is located, may be greater than the amount of recessing of the second vapor channel region 24 of the second sheet 20, which is a sheet at which the first liquid channel part 60 is not located. In this case, the channel corner 55 with enhanced capillary action can be formed between each of the vapor passages 51 and 52, and the first liquid channel part 60. As a result, in the bend region 7, the working liquid 2b condensed from the working vapor 2a can be efficiently transported to the first liquid channel part 60.

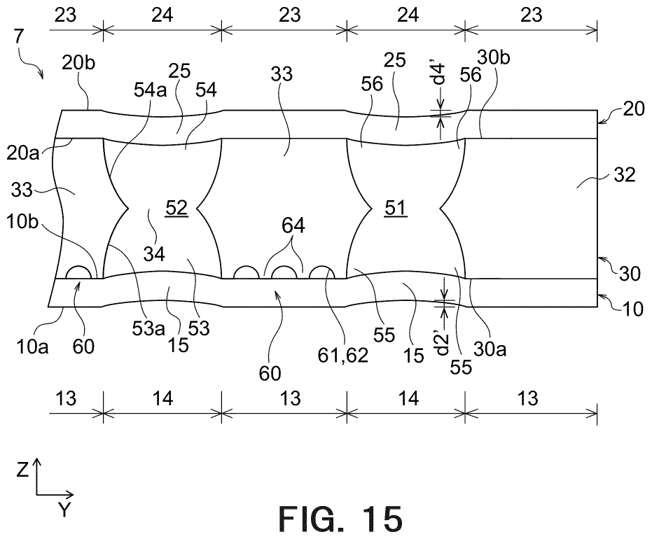

According to the first embodiment mentioned above, in the bend region 7, the respective vapor channel regions 14 and 24 of the sheets 10 and 20 may be recessed by an amount that is less in an end portion of the vapor channel part 50 in the width direction than in the middle portion of the vapor channel part 50 in the width direction. For example, in the second vapor passage 52 located in the middle portion, in the width direction, of the vapor chamber 1 illustrated in FIG. 5, as illustrated in FIG. 14, the first sheet 10 may have the maximum dimension d2 in the bend region 7, and the second sheet 20 may have the maximum dimension d4 in the bend region 7. Further, in the first vapor passage 51 located in an end portion, in the Y-direction, of the vapor chamber 1 illustrated in FIG. 5, as illustrated in FIG. 15, the first sheet 10 may have a maximum dimension d2′ in the bend region 7, and the second sheet 20 may have a maximum dimension d4′ in the bend region 7. The maximum dimension d2′ may be less than the maximum dimension d2. The maximum dimension d4′ may be less than the maximum dimension d4. In this case, in the end portion of the vapor channel part 50 in the width direction, an increase in the channel resistance to the working vapor 2a can be mitigated, and the working vapor 2a can be thus transported smoothly. The resulting ability to facilitate movement of heat in the end portion of the vapor channel part 50 in the width direction can lead to a reduced temperature difference between the end portion of the vapor channel part 50 in the width direction and the middle portion of the vapor channel part 50 in the width direction. This allows for temperature equalization of the vapor chamber 1.

According to the first embodiment mentioned above, in the bend region 7, the respective vapor channel regions 14 and 24 of the sheets 10 and 20 may be recessed by an amount that is greater in an end portion of the vapor channel part 50 in the width direction than in the middle portion of the vapor channel part 50 in the width direction. For example, the maximum dimension d2′ mentioned above may be greater than the maximum dimension d2. The maximum dimension d4′ mentioned above may be greater than the maximum dimension d4. In this case, in the end portion of the vapor channel part 50 in the width direction, the working liquid 2b that has condensed can be efficiently moved to the first liquid channel part 60. This can reduce the risk of the vapor passages 51 and 52 being blocked by the condensed working liquid 2b. The working vapor 2a can be thus transported smoothly. The resulting ability to facilitate movement of heat in the end portion of the vapor channel part 50 in the width direction can lead to a reduced temperature difference between the end portion of the vapor channel part 50 in the width direction and the middle portion of the vapor channel part 50 in the width direction. This allows for temperature equalization of the vapor chamber 1.

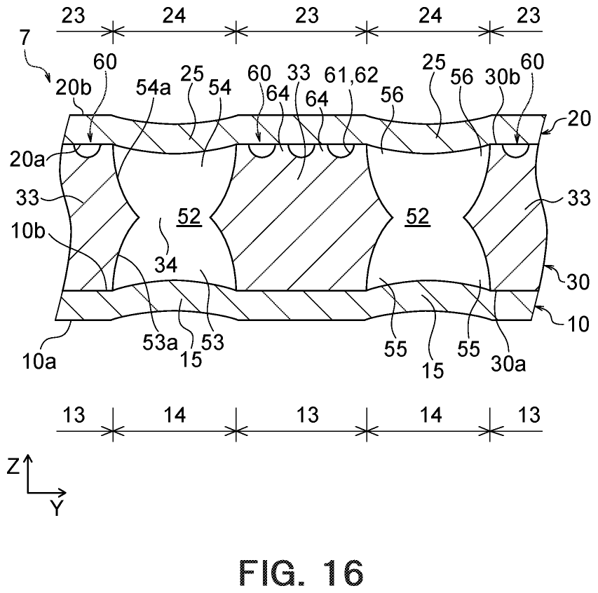

The foregoing description of the first embodiment is directed to the example in which the first body face 30a of the first land part 33 is provided with the first liquid channel part 60, and the second body face 30b of the first land part 33 is provided with no liquid channel part. This, however, is not intended to be limiting. In another example, as illustrated in FIG. 16, the first body face 30a of the first land part 33 may be provided with no liquid channel part, and the second body face 30b of the first land part 33 may be provided with the first liquid channel part 60.

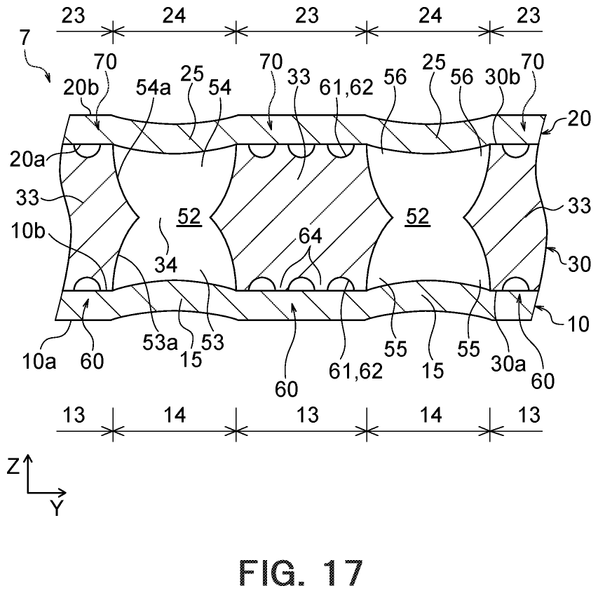

The foregoing description of the first embodiment is directed to the example in which the first body face 30a of the first land part 33 is provided with the first liquid channel part 60, and the second body face 30b of the first land part 33 is provided with no liquid channel part. This, however, is not intended to be limiting. For example, as illustrated in FIG. 17, the second body face 30b of the first land part 33 may be provided with a second liquid channel part 70. The second liquid channel part 70 provided in the second body face 30b is an example of a second group of grooves. As with the first liquid channel part 60, the second liquid channel part 70 may include a plurality of main flow grooves 61, and a plurality of communication grooves 65.

In the bend region 7, the second sheet 20 is located inward relative to the wick sheet 30. At the inner side of the passage bend part 57, the flow of the working vapor 2a may separate from the second-sheet inner face 20a. This is explained below in more detail. In an area near the exit of the passage bend part 57, eddies are formed, and the working vapor 2a condenses. The condensed working liquid 2b can be guided to the second liquid channel part 70. The working liquid 2b can be thus transported toward the evaporation region SR. This can reduce the risk that the working liquid 2b stagnates in the vapor passages 51 and 52 in the bend region 7, and consequently reduce the risk that the flow of the working vapor 2a is inhibited.

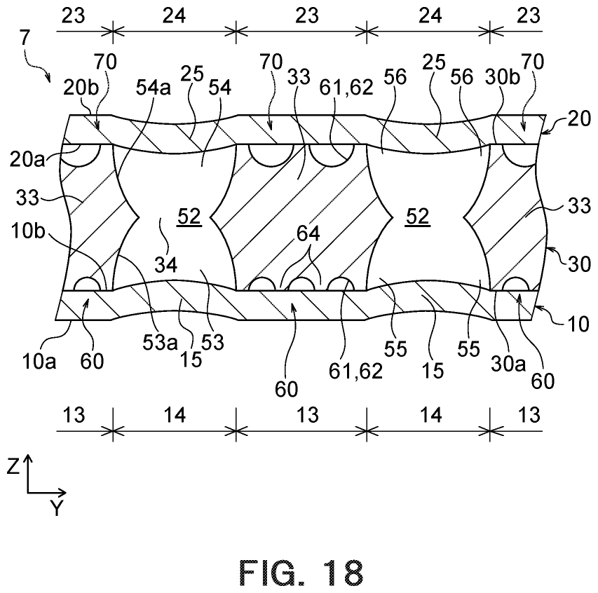

In the example illustrated in FIG. 17, the second liquid channel part 70 is similar in configuration to the first liquid channel part 60. This, however, is not intended to be limiting. For example, as illustrated in FIG. 18, the main flow groove 61 of the second liquid channel part 70 may have a channel cross-sectional area greater than the channel cross-sectional area of the main flow groove 61 of the first liquid channel part 60. The communication groove 65 of the second liquid channel part 70 may have a channel cross-sectional area greater than the channel cross-sectional area of the communication groove 65 of the first liquid channel part 60. The second liquid channel part 70 illustrated in FIG. 18 is referred to also as liquid reservoir.

According to the modification illustrated in FIG. 18, during a period when the electronic device D is not generating heat, the working liquid 2b can be stored in a distributed manner, that is, not only in the first liquid channel part 60 but also in the second liquid channel part 70. The modification thus makes it possible to reduce the expansion force that is exerted on the first sheet 10 when the working liquid 2b within the first liquid channel part 60 freezes and expands under low-temperature conditions below the freezing point of the working liquid 2b. In this case, deformation of the first sheet 10 can be reduced. The modification also makes it possible to reduce the expansion force that is exerted on the second sheet 20 when the working liquid 2b within the second liquid channel part 70 freezes and expands. In this case, deformation of the second sheet 20 can be reduced. This can result in reduced deformation of the vapor chamber 1, and consequently reduced performance deterioration of the vapor chamber 1. During a period when the electronic device D is generating heat, the working liquid 2b within the second liquid channel part 70 can evaporate by receiving the heat from the electronic device D.

The modification illustrated in FIG. 18 can ensure that the capillary force exerted on the working liquid 2b within the main flow groove 61 of the second liquid channel part 70 is less than the capillary force exerted on the working liquid 2b within the main flow groove 61 of the first liquid channel part 60. This allows for reduced movement of the working liquid 2b to the second liquid channel part 70 during a period when the electronic device D is generating heat. This in turn makes it possible to reduce deterioration of the capability to transport the working liquid 2b to the evaporation region SR, and consequently reduce deterioration of heat transport efficiency. As mentioned above, the main flow groove 61 of the second liquid channel part 70 has a channel cross-sectional area greater than the channel cross-sectional area of the main flow groove 61 of the first liquid channel part 60. This makes it possible to increase the total volume of the spaces defined by individual main flow grooves 61 of the second liquid channel part 70. This can in turn ensure that, during a period when the electronic device D is generating heat, an increased amount of the working liquid 2b can be stored in the second liquid channel part 70.

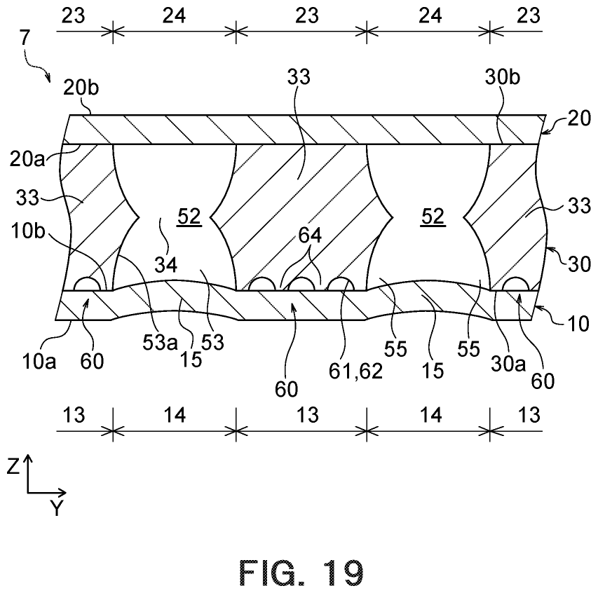

The foregoing description of the first embodiment is directed to the example in which the second vapor channel region 24 has a recessed shape in the first region 5, the second region 6, and the bend region 7. This, however, is not intended to be limiting. For example, the second vapor channel region 24 may have a flat shape in the Y-direction in the first region 5, the second region 6, and the bend region 7 as illustrated in FIG. 19. In this case as well, the capillary action at the channel corner 55 can be increased to allow transport of the working liquid 2b that has adhered on the first-sheet inner face 10b. Further, in the bend region 7, the surface area of the first sheet 10 can be increased. As a result, heat can be dissipated externally via the housing component Ha with improved efficiency. This can lead to improved cooling capacity of the vapor chamber 1. Further, in the bend region 7, an increase in the vapor pressure of the working vapor 2a can be mitigated. This can lead to a reduced difference between the vapor pressure of the working vapor 2a in the bend region 7, and the vapor pressure of the working vapor 2a in each of the first region 5 and the second region 6. As a result, the working vapor 2a can be transported smoothly. Further, the flat shape of the second vapor channel region 24 can reduce the risk of a gap being created between the second vapor channel region 24 and the electronic device D. This can ensure sufficiently close contact with the electronic device D. As a result, the electronic device D can be cooled efficiently.

The foregoing description of the first embodiment is directed to the example in which, in the bend region 7, the first sheet 10 is located outward relative to the wick sheet 30. This, however, is not intended to be limiting. For example, the first sheet 10 may be located inward relative to the wick sheet 30. In this case as well, the capillary action at the channel corner 55 can be increased to allow transport of the working liquid 2b that has adhered on the first-sheet inner face 10b. In this case, the second vapor channel region 24 of the second sheet 20, which is located outward relative to the wick sheet 30, may have a flat shape in the Y-direction in the first region 5, the second region 6, and the bend region 7.

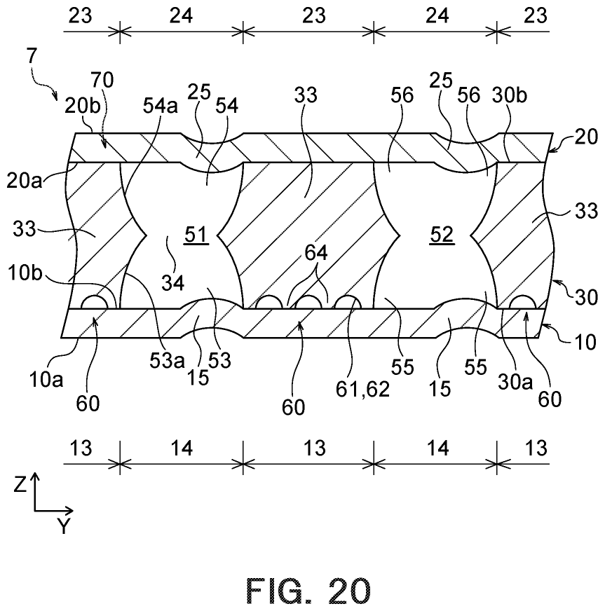

The foregoing description of the first embodiment is directed to the example in which a single first-sheet recess 15 is provided across the entire first vapor channel region 14 in the width direction. This, however, is not intended to be limiting. For example, as illustrated in FIG. 20, in the bend region 7, a portion of the first vapor channel region 14 may have a recessed shape, and another portion of the first vapor channel region 14 may have a flat shape in the Y-direction. Consequently, the capillary action in the recessed portion of the first vapor channel region 14 can be increased relative to the capillary action in the flat portion. This allows for control of the flow of the working liquid 2b, which provides the ability to intentionally increase the capillary action at any desired location. For example, a single first-sheet recess 15 may be provided in a portion of the first vapor channel region 14 in the width direction. In this case, another portion of the first vapor channel region 14 may have a flat shape in the Y-direction. For example, in the bend region 7, a portion of the first vapor channel region 14 in the direction of vapor flow may have a recessed shape, and another portion may have a flat shape in the Y-direction. Likewise, a portion of the second vapor channel region 24 may have a recessed shape, and another portion may have a flat shape in the Y-direction.

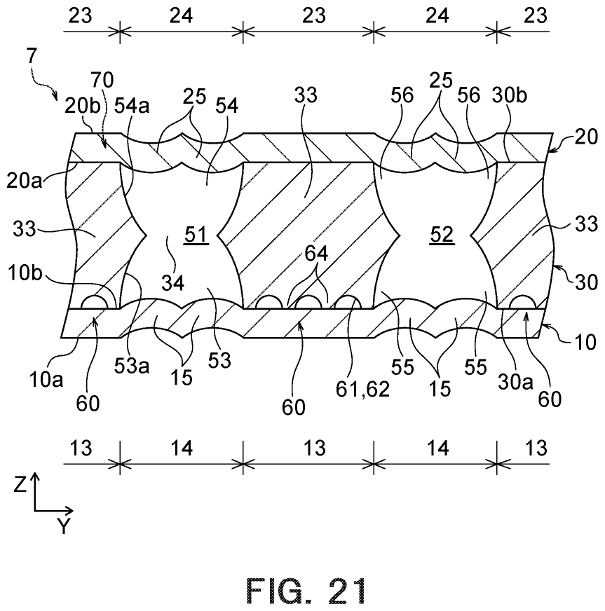

The foregoing description of the first embodiment is directed to the example in which the first sheet 10 includes a single first-sheet recess 15 overlapping the first vapor channel region 14 in plan view. This, however, is not intended to be limiting. For example, as illustrated in FIG. 21, the first sheet 10 may include a plurality of first-sheet recesses 15 overlapping the first vapor channel region 14 in plan view. For example, a plurality of first-sheet recesses 15 may be provided in the first vapor channel region 14. The first-sheet recesses 15 may be located at different positions in the Y-direction. The first-sheet recesses 15 may be located at different positions in the X-direction. FIG. 21 depicts an example in which the first vapor channel region 14 is provided with two first-sheet recesses 15 arranged side by side in the Y-direction. Likewise, the second sheet 20 may include a plurality of second-sheet recesses 25.

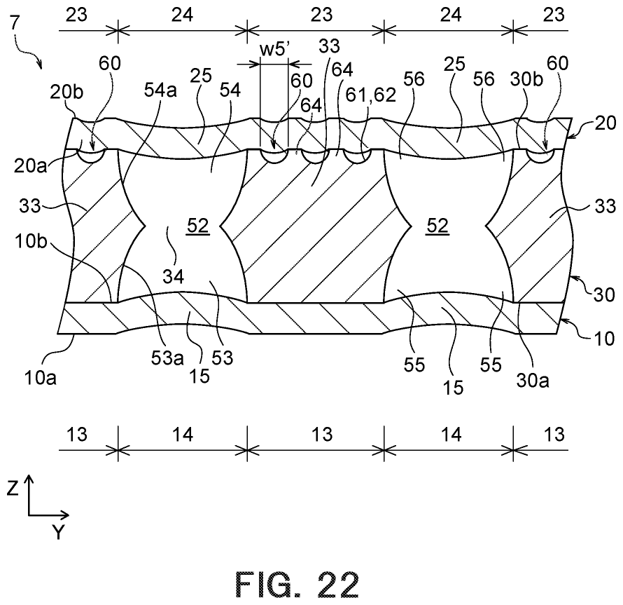

According to the first embodiment mentioned above, if the second body face 30b of the first land part 33 is provided with the first liquid channel part 60 as illustrated in FIG. 22, the main flow groove 61 of the first liquid channel part 60 in the bend region 7 illustrated in FIG. 22 may have a width w5′, which is less than the width w5 of the main flow groove 61 of the first liquid channel part 60 in each of the first region 5 and the second region 6. The same applies to the width w6 of the communication groove 65. In the example illustrated in FIG. 22, the second sheet 20 may be located at the inner side of the bend. In this case, the capillary action of the first liquid channel part 60 can be increased in the bend region 7. This can ensure that the working liquid 2b that has condensed is allowed to efficiently move from the vapor passages 51 and 52 to the first liquid channel part 60. This can also reduce the risk that the main flow groove 61 and the communication groove 65 of the first liquid channel part 60 are crushed when the second sheet 20 is subjected to an external pressing force.

As illustrated in FIG. 22, in the bend region 7, the second sheet 20 may be recessed toward the first liquid channel part 60. The amount of recessing of the second sheet 20 in the bend region 7 may be greater than the amount of recessing of the second sheet 20 in each of the first region 5 and the second region 6. The amount of recessing of the second sheet 20 in each of the first region 5 and the second region 6 may be zero. In other words, in each of the first region 5 and the second region 6, the second sheet 20 does not have to be recessed toward the first liquid channel part 60. The configuration mentioned above makes it possible to reduce, in the bend region 7, the angle formed between the second-sheet inner face 20a, and the wall face 62 of the main flow groove 61. The configuration mentioned above also makes it possible to reduce the angle formed between the second-sheet inner face 20a, and the wall face of the communication groove 65. Consequently, the capillary action of the first liquid channel part 60 can be enhanced. As a result, the working liquid 2b that has condensed can be transported smoothly toward the evaporation region SR.

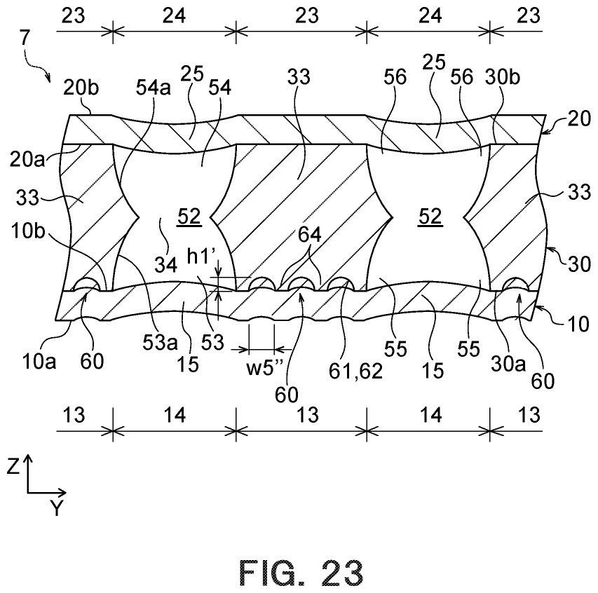

According to the first embodiment mentioned above, if the first body face 30a of the first land part 33 is provided with the first liquid channel part 60 as illustrated in FIG. 23, the main flow groove 61 of the first liquid channel part 60 in the bend region 7 illustrated in FIG. 23 may have a width w5″, which is less than the width w5 of the main flow groove 61 of the first liquid channel part 60 in each of the first region 5 and the second region 6. The same applies to the width w6 of the communication groove 65. Further, the main flow groove 61 of the first liquid channel part 60 in the bend region 7 illustrated in FIG. 23 may have a depth h1′ less than the depth h1 of the main flow groove 61 of the first liquid channel part 60 in each of the first region 5 and the second region 6. The same applies to the depth of the communication groove 65. In the example illustrated in FIG. 23, the second sheet 20 may be located at the inner side of the bend. The configuration mentioned above makes it possible to reduce, in the bend region 7, the angle formed between the first-sheet inner face 10b, and the wall face 62 of the main flow groove 61. The configuration mentioned above also makes it possible to reduce the angle formed between the first-sheet inner face 10b, and the wall face of the communication groove 65. Consequently, the capillary action of the first liquid channel part 60 can be enhanced. As a result, the working liquid 2b that has condensed can be transported smoothly toward the evaporation region SR.

As illustrated in FIG. 23, in the bend region 7, the first sheet 10 may be recessed toward the first liquid channel part 60. The amount of recessing of the first sheet 10 in the bend region 7 may be greater than the amount of recessing of the first sheet 10 in each of the first region 5 and the second region 6. The amount of recessing of the first sheet 10 in each of the first region 5 and the second region 6 may be zero. In other words, in each of the first region 5 and the second region 6, the first sheet 10 does not have to be recessed toward the first liquid channel part 60. The configuration mentioned above makes it possible to further reduce, in the bend region 7, the angle that the first-sheet inner face 10b, and the wall face 62 of the main flow groove 61. The configuration mentioned above also makes it possible to further reduce the angle formed between the first-sheet inner face 10b, and the wall face of the communication groove 65. Consequently, the capillary action of the first liquid channel part 60 can be enhanced. As a result, the working liquid 2b that has condensed can be transported further smoothly toward the evaporation region SR.

In the examples illustrated in FIGS. 22 and 23, the channel cross-sectional area of the main flow groove 61 in the bend region 7 may be less than the channel cross-sectional area of the main flow groove 61 in each of the first region 5 and the second region 6. The channel cross-sectional area of the communication groove 65 in the bend region 7 may be less than the channel cross-sectional area of the communication groove 65 in each of the first region 5 and the second region 6. In this case, the capillary action of the first liquid channel part 60 can be increased in the bend region 7. As a result, the working liquid 2b that has condensed can be transported smoothly toward the evaporation region SR.

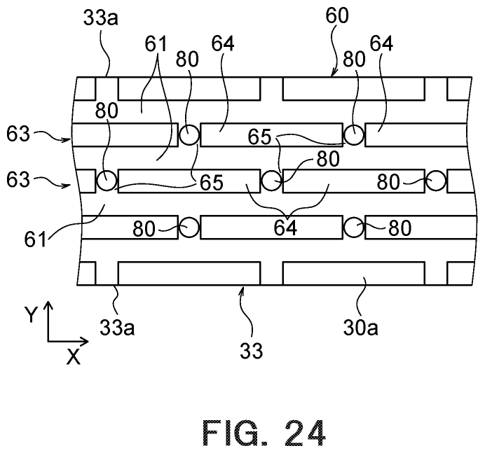

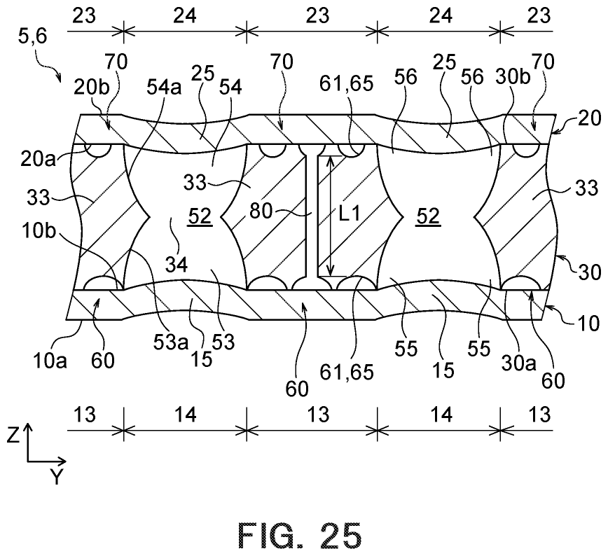

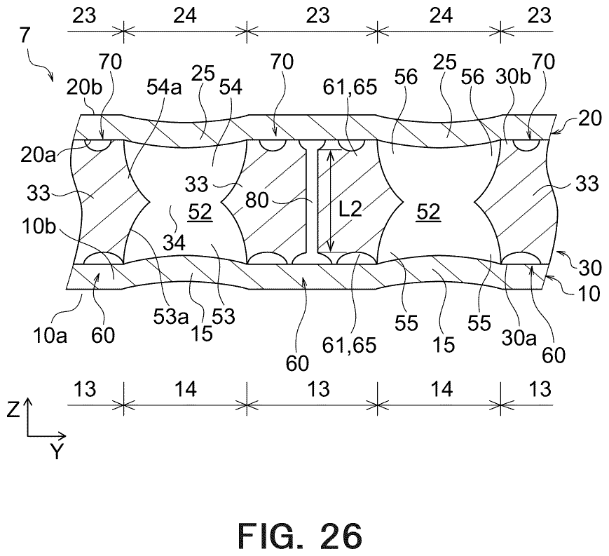

According to the first embodiment mentioned above, if the first body face 30a of the first land part 33 is provided with the first liquid channel part 60, and the second body face 30b of the first land part 33 is provided with the second liquid channel part 70 as illustrated in FIGS. 24 to 26, a communicating path 80 may be provided to communicate the first liquid channel part 60 and the second liquid channel part 70 with each other. As illustrated in FIGS. 25 and 26, the communicating path 80 may extend straight in the Z-direction, and penetrate the first land part 33. The communicating path 80 may be positioned at any location in the first land part 33. In plan view, the communicating path 80 may be positioned to overlap the main flow groove 61 of the first liquid channel part 60, and the main flow groove 61 of the second liquid channel part 70. In this case, the communicating path 80 may connect the main flow groove 61 of the first liquid channel part 60, and the main flow groove 61 of the second liquid channel part 70 to each other. As illustrated in FIG. 24, in plan view, the communicating path 80 may be positioned to overlap the communication groove 65 of the first liquid channel part 60, and the communication groove 65 of the second liquid channel part 70. In this case, the communicating path 80 may connect the communication groove 65 of the first liquid channel part 60, and the communication groove 65 of the second liquid channel part 70 to each other. The presence of the communicating path 80 communicating the first liquid channel part 60 and the second liquid channel part 70 with each other can for instance ensure that, even when the working liquid 2b ceases to flow smoothly in one of the first liquid channel part 60 and the second liquid channel part 70 due to bending, the working liquid 2b is allowed to pass through the communicating path 80 to the other liquid channel part. As a result, the working liquid 2b can be transported smoothly toward the evaporation region SR. This can lead to improved cooling capacity of the vapor chamber 1.

The communicating path 80 in the bend region 7 illustrated in FIG. 26 may have a length L2 less than a length L1 of the communicating path 80 in each of the first region 5 and the second region 6 illustrated in FIG. 25. Each of the lengths L1 and L2 of the communicating path 80 means the distance along the communicating path 80. If the communicating path 80 extends straight in the Z-direction as illustrated in FIGS. 25 and 26, each of the lengths L1 and L2 is the length in the Z-direction. In this case, the liquid channel resistance of the communicating path 80 in the bend region 7 can be decreased. As a result, the working liquid 2b that has condensed can be efficiently moved from a liquid channel part with high capillary action at the channel corner to a liquid channel part with low capillary action at the channel corner. This can lead to improved cooling capacity of the vapor chamber 1.

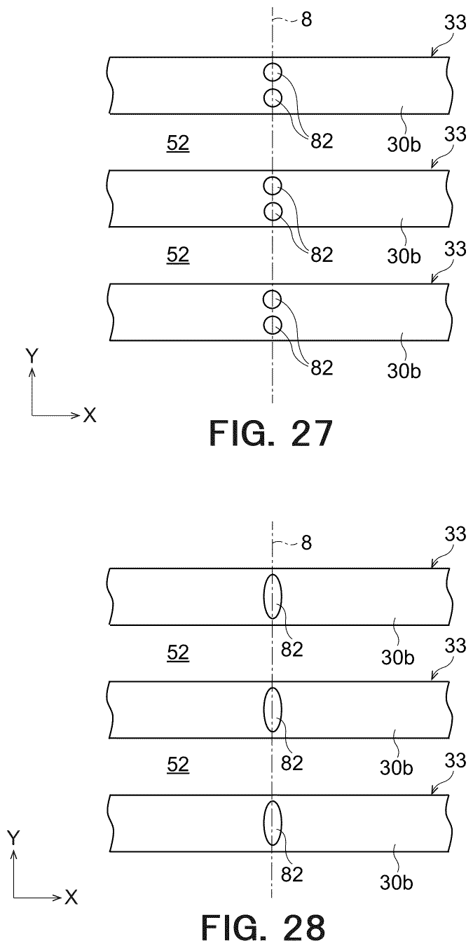

According to the first embodiment mentioned above, a body-face recess 82 may be disposed at a position in the first land part 33 where the first liquid channel part 60 is not disposed. In one example, if the first body face 30a of the first land part 33 is provided with the first liquid channel part 60, the second body face 30b of the first land part 33 may be provided with the body-face recess 82. In another example, if the second body face 30b of the first land part 33 is provided with the first liquid channel part 60, the first body face 30a of the first land part 33 may be provided with the body-face recess 82. In another example, if the first body face 30a of the first land part 33 is provided with the first liquid channel part 60, and the second body face 30b of the first land part 33 is provided with the second liquid channel part 70, the first body face 30a or the second body face 30b of the first land part 33 may be provided with the body-face recess 82 located at any position in the first body face 30a or the second body face 30b where the liquid channel part 60 or 70 is not provided. In the examples illustrated in FIGS. 27 and 28, the second body face 30b of the first land part 33 is provided with the body-face recess 82.

The body-face recess 82 may be in the form of a recess provided in the second body face 30b of the first land part 33. The body-face recess 82 may have any shape in plan view. For example, as illustrated in FIG. 27, the body-face recess 82 may be in the form of a minute hole having the shape of a circle (e.g., a perfect circle or an ellipse) in plan view. For example, as illustrated in FIG. 28, the body-face recess 82 may be in the form of a groove extending in the Y-direction. As illustrated in FIGS. 27 and 28, a plurality of body-face recesses 82 may be arranged side by side in the Y-direction. As illustrated in FIGS. 27 and 28, the body-face recesses 82 overlap the bend line 8 in plan view. That is, the body-face recesses 82 are disposed along a bend line BL. In other words, each body-face recess 82 is positioned to overlap the bend line 8 in plan view.

The body-face recess 82 may be formed through etching of the wick sheet 30 in the above-mentioned etching step of the method for manufacturing the vapor chamber 1. With the vapor chamber 1 seen in plan view, the body-face recess 82 is visible also from outside the vapor chamber 1 through the first sheet 10 or the second sheet 20. The body-face recess 82 thus serves as a visual indication of where to bend the vapor chamber 1 in the above-mentioned bending step of the method for manufacturing the vapor chamber 1. That is, in the bending step, bending the vapor chamber 1 along the body-face recess 82 makes it possible to obtain the vapor chamber 1 that has been bent along the bend line 8. The presence of the body-face recess 82 can thus improve the ease of bending operation. Further, the presence of the body-face recess 82 in the form of a minute hole or a groove can facilitate bending of the vapor chamber 1. This can in turn facilitate manufacture of a bent vapor chamber 1.

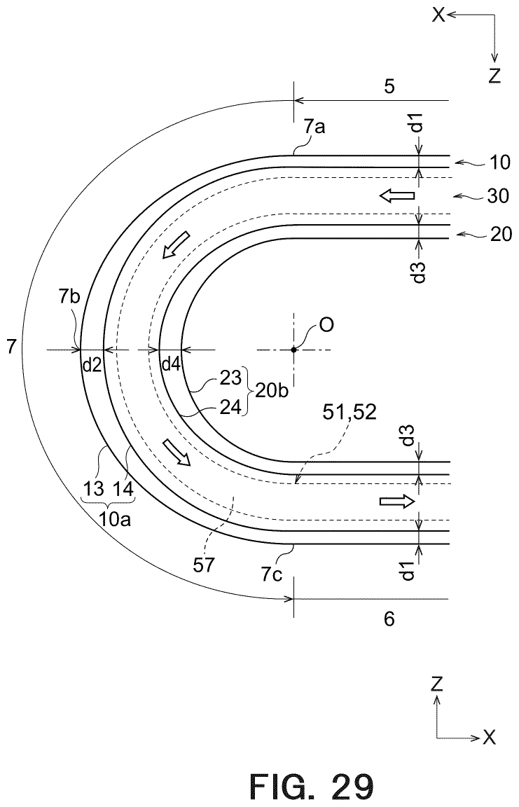

The foregoing description of the first embodiment is directed to the example in which the vapor chamber 1 is bent at substantially right angles such that the first region 5 and the second region 6 are orthogonal to each other. This, however, is not intended to be limiting. For example, as illustrated in FIG. 29, the vapor chamber 1 may be bent in a U-shape such that the first region 5 and the second region 6 face each other. In the example illustrated in FIG. 29, the bend region 7 of the vapor chamber 1 has the shape of a semi-circular arc. This allows for increased flexibility in where the vapor chamber 1 can be placed within the housing H. As a result, for instance, even if the electronic apparatus E prone to heat generation is located far from the housing component Ha that releases heat, the heat from the electronic apparatus E can be transferred to the housing component Ha via the vapor chamber 1.

In this case, as illustrated in FIG. 29, when viewed in the direction parallel to the bend line 8, a dimension in the thickness direction of the first sheet 10 that is defined between the first bond region 13 and the first vapor channel region 14 in the bend region 7 may vary within the bend region 7. Now, an end portion of the bend region 7 near the first region 5 is referred to as first bend end portion 7a, an end portion of the bend region 7 near the second region 6 is referred to as second bend end portion 7c, and a portion of the bend region 7 midway between the first bend end portion 7a and the second bend end portion 7c is referred to as bend middle portion 7b. In this case, for example, the above-mentioned dimension may increase with increasing distance from the first bend end portion 7a toward the bend middle portion 7b. The above-mentioned dimension may become the maximum dimension d2 in the bend middle portion 7b. The above-mentioned dimension may decrease with increasing distance from the bend middle portion 7b toward the second bend end portion 7c. Likewise, when viewed in the direction parallel to the bend line 8, a dimension in the thickness direction of the second sheet 20 that is defined between the second bond region 23 and the second vapor channel region 24 in the bend region 7 may vary within the bend region 7. For example, the above-mentioned dimension may increase with increasing distance from the first bend end portion 7a toward the bend middle portion 7b. The above-mentioned dimension may become the maximum dimension d4 in the bend middle portion 7b. The above-mentioned dimension may decrease with increasing distance from the bend middle portion 7b toward the second bend end portion 7c.

According to the modification illustrated in FIG. 29, the capillary action at the channel corner 55 can be increased in the bend middle portion 7b, which is a portion of the bend region 7 where bending is particularly large. The working liquid 2b that has condensed can be thus transported smoothly toward the evaporation region SR. Further, the first sheet 10 and the second sheet 20 can be increased in surface area, which can lead to improved heat dissipation efficiency of the vapor chamber 1. Further, in the bend region 7, an increase in the vapor pressure of the working vapor 2a can be mitigated. This can lead to a reduced difference between the vapor pressure of the working vapor 2a in the bend region 7, and the vapor pressure of the working vapor 2a in each of the first region 5 and the second region 6. As a result, the working vapor 2a can be transported smoothly even in the bend middle portion 7b where bending is particularly large.

The configuration mentioned above with reference to the example illustrated in FIG. 29 may similarly apply to the case where, as illustrated in FIG. 13, the vapor chamber 1 is bent at substantially right angles such that the first region 5 and the second region 6 are orthogonal to each other. In this case as well, when viewed in the direction parallel to the bend line 8, a dimension in the thickness direction of the first sheet 10 that is defined between the first bond region 13 and the first vapor channel region 14 in the bend region 7 may vary within the bend region 7. For example, the above-mentioned dimension may increase with increasing distance from the first bend end portion 7a toward the bend middle portion 7b. The above-mentioned dimension may become the maximum dimension d2 in the bend middle portion. The above-mentioned dimension may decrease with increasing distance from the bend middle portion 7b toward the second bend end portion 7c. Likewise, when viewed in the direction parallel to the bend line 8, a dimension in the thickness direction of the second sheet 20 that is defined between the second bond region 23 and the second vapor channel region 24 in the bend region 7 may vary within the bend region 7. For example, the above-mentioned dimension may increase with increasing distance from the first bend end portion 7a toward the bend middle portion 7b. The above-mentioned dimension may become the maximum dimension d4 in the bend middle portion 7b. The above-mentioned dimension may decrease with increasing distance from the bend middle portion 7b toward the second bend end portion 7c. In this case as well, an effect similar to that of the modification illustrated in FIG. 29 can be provided.

### Second Embodiment

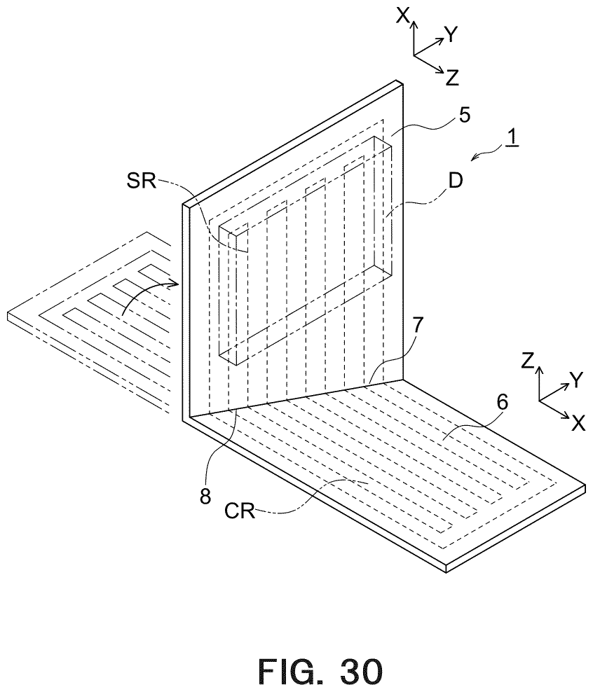

Now, reference is made to FIGS. 30 to 33 to describe a vapor chamber, an electronic apparatus, and a method for manufacturing a vapor chamber according to a second embodiment of the present disclosure.

The second embodiment illustrated in FIGS. 30 to 33 differs from the first embodiment mainly in that the vapor chamber is bent along a bend line inclined with respect to the first direction. The second embodiment is otherwise substantially identical in configuration to the first embodiment illustrated in FIGS. 1 to 29. Features in FIGS. 30 to 33 that are identical to those according to the first embodiment illustrated in FIGS. 1 to 29 are designated by the same reference signs and not described in further detail.

As illustrated in FIG. 30, the vapor chamber 1 according to the second embodiment is bent along the bend line 8 that is inclined with respect to the X-direction in plan view. The bend line 8 illustrated in FIG. 30 is inclined with respect to the X-direction, and also inclined with respect to the Y-direction. The bend line 8 illustrated in FIG. 30 as well extends in a direction crossing the X-direction in plan view. According to the second embodiment, the first region 5, the second region 6, and the bend region 7 may be divided from each other by a boundary line that is inclined with respect to the X-direction in plan view, and that extends along the bend line 8.

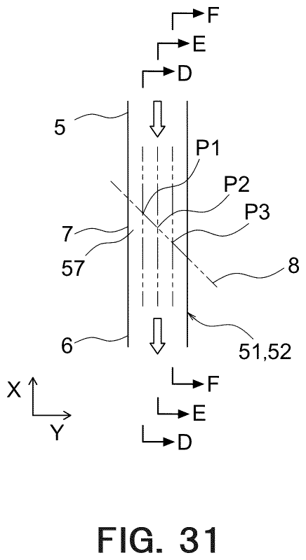

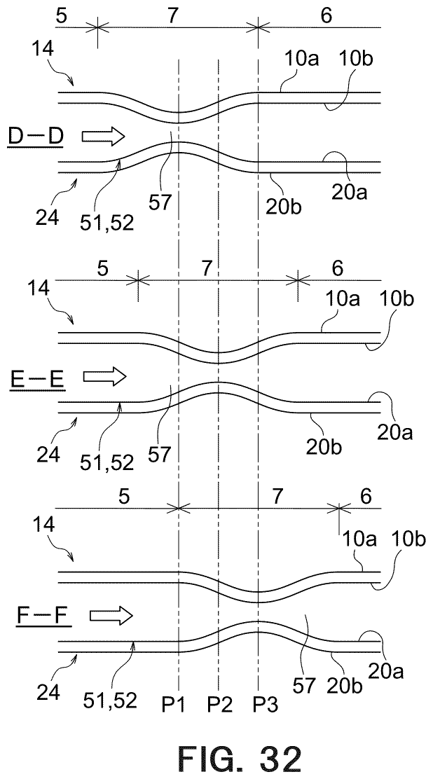

With reference to FIGS. 31 and 32, the flow of vapor in one vapor passage 51 or 52 in the bend region 7 is described below. FIG. 31 is a plan view of the vapor passage 51 or 52, representing a planar development of the bend region 7. FIG. 32 illustrates diagrammatic cross-sections of the vapor passage 51 or 52 taken along a line D-D, a line E-E, and a line F-F of FIG. 31. The line D-D, the line E-E, and the line F-F are defined as lines located at different positions in the Y-direction.

As illustrated in FIG. 32, the first vapor channel region 14 and the second vapor channel region 24 are most recessed at a position P1 on the line D-D. The first vapor channel region 14 and the second vapor channel region 24 are most recessed at a position P2 on the line E-E. The first vapor channel region 14 and the second vapor channel region 24 are most recessed at a position P3 on the line F-F.

As illustrated in FIG. 31, the positions P1, P2, and P3 are positions that overlap the bend line 8 in plan view, and that are different from each other in the X-direction in which the vapor passage 51 or 52 extends. Consequently, the positions P1, P2, and P3 where the vapor passage 51 or 52 has the smallest channel cross-sectional area in the above-mentioned cross-sections can be displaced relative to each other in the X-direction. As a result, positions where the working vapor 2a encounters an increased channel resistance can be distributed in the direction of flow of the working vapor 2a. This can reduce the risk that the flow of the working vapor 2a is inhibited in the passage bend part 57.

As described above, according to the second embodiment, the vapor chamber 1 is bent along the bend line 8 inclined with respect to the X-direction. This can reduce the risk that the flow of the working vapor 2a is inhibited in the bend region 7. This allows the vapor chamber 1 to exhibit improved heat dissipation efficiency even in its bent state.

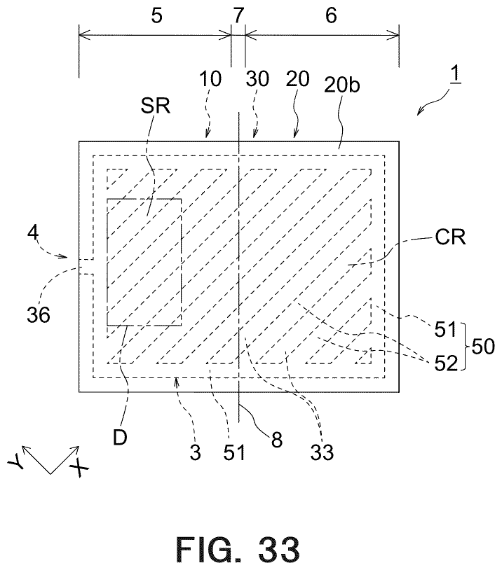

The foregoing description of the first embodiment is directed to the example in which the frame part 32 is in the form of a rectangular frame extending in the X-direction and the Y-direction. This, however, is not intended to be limiting. For example, as illustrated in FIG. 33, the frame part 32 may be inclined with respect to the first land part 33 extending in the X-direction. The frame part 32 is in the form of a rectangular frame that is inclined with respect to the X-direction and that is inclined with respect to the Y-direction. The bend line 8 lies along the frame part 32. The bend line 8 extends in the up-down direction in FIG. 33. In this case as well, the bend line 8 extends in a direction crossing the X-direction in plan view. As with the example illustrated in FIGS. 30 to 32, in the example illustrated in FIG. 33, positions where the working vapor 2a encounters an increased channel resistance in the vapor passage 51 or 52 can likewise be distributed in the direction of flow of the working vapor 2a. This can reduce the risk that the flow of the working vapor 2a is inhibited in the bend region 7.

### Third Embodiment

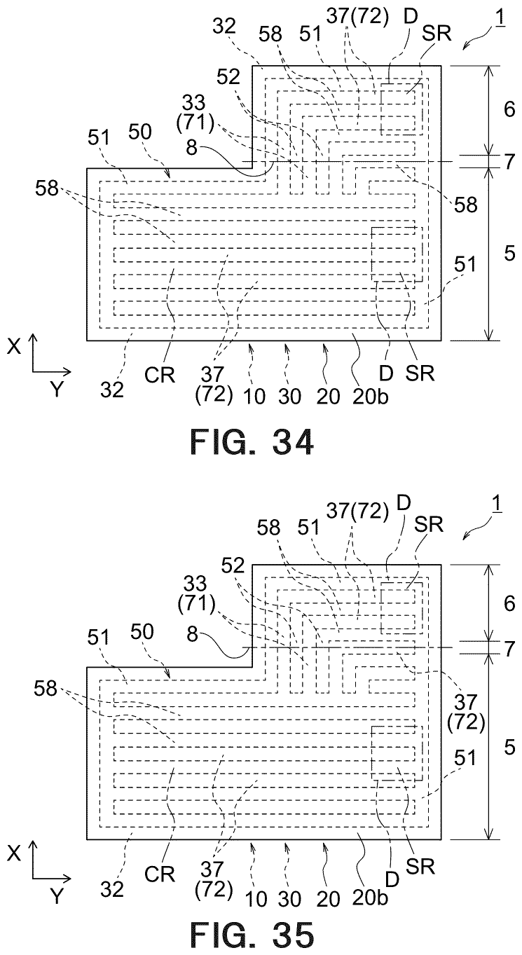

Now, reference is made to FIGS. 34 to 37 to describe a vapor chamber, an electronic apparatus, and a method for manufacturing a vapor chamber according to a third embodiment of the present disclosure.

The third embodiment illustrated in FIGS. 34 to 37 differs from the first embodiment mainly in the following respects: the body sheet includes a plurality of second land parts extending in the second direction; and the second land parts are located in a region other than the bend region. The third embodiment is otherwise substantially identical in configuration to the first embodiment illustrated in FIGS. 1 to 29. Features in FIGS. 34 to 37 that are identical to those according to the first embodiment illustrated in FIGS. 1 to 29 are designated by the same reference signs and not described in further detail.

According to the third embodiment, as illustrated in FIG. 34, the wick sheet 30 includes a plurality of second land parts 37 extending in the Y-direction. The second land part 37 is located in each of the first region 5 and the second region 6. A plurality of second land parts 37 may be located in each of the first region 5 and the second region 6. The second land part 37 can be configured similarly to the first land part 33.

The first land parts 33 are located in the bend region 7. The first land parts 33 may be provided over an area extending from the first region 5 to the second region 6 via the bend region 7. Each first land part 33 is connected to the second land part 37 located in the first region 5. In the example illustrated in FIG. 34, a plurality of first land parts 33 are connected to a single second land part 37 located in the first region 5. Each first land part 33 is connected to the second land part 37 located in the second region 6. In the example illustrated in FIG. 34, each first land part 33 is connected to the corresponding second land part 37. In other words, each one first land part 33 is connected with the corresponding one second land part 37 located in the second region 6.

According to the third embodiment, as illustrated in FIG. 34, the vapor channel part 50 may include a third vapor passage 58. The third vapor passage 58 is provided between the second land parts 37 located in the first region 5. The third vapor passage 58 extends in the Y-direction. The third vapor passage 58 extending in the Y-direction is likewise provided between the second land parts 37 located in the second region 6. The third vapor passage 58 located in the second region 6 communicates with the second vapor passage 52 located between the first land parts 33. In the example illustrated in FIG. 34, the third vapor passage 58 extending in the Y-direction is provided also in the bend region 7. The third vapor passage 58 can be configured similarly to the second vapor passage 52.

The first vapor passage 51 is provided contiguously inside the frame part 32 and outside the first land part 33 and the second land part 37.

According to the third embodiment, the first liquid channel part 60 includes a first-land liquid channel part 71, and a second-land liquid channel part 72. The first-land liquid channel part 71 is provided in the first body face 30a of the first land part 33. The second-land liquid channel part 72 is provided in the first body face 30a of the second land part 37. The first-land liquid channel part 71 and the second-land liquid channel part 72 each include a plurality of main flow grooves 61, and a plurality of communication grooves 65. The main flow groove 61 of the first-land liquid channel part 71 extends in the X-direction. The communication groove 65 of the first-land liquid channel part 71 may extend in the Y-direction. The main flow groove 61 of the second-land liquid channel part 72 extends in the Y-direction. The communication groove 65 of the second-land liquid channel part 72 may extend in the X-direction. The first-land liquid channel part 71 and the second-land liquid channel part 72 communicate with each other in a manner that allows the working liquid 2b to move back and forth therebetween. In this way, the working liquid 2b is allowed to move back and forth between the first region 5 and the second region 6.

According to the third embodiment, the evaporation region SR that overlaps the electronic device D is located in each of the first region 5 and the second region 6. The condensation region CR is located in the first region 5. The bend region 7 is provided between the first region 5 and the second region 6. The bend line 8 extends in a direction crossing the X-direction in plan view. In FIG. 34, the bend line 8 extends in the Y-direction. In the bend region 7, the working vapor 2a can pass through the first vapor passage 51, the second vapor passage 52, and the third vapor passage 58. This allows the working vapor 2a to move back and forth between the first region 5 and the second region 6. In the example illustrated in FIG. 34, the bend line 8 overlaps also the third vapor passage 58 located in the bend region 7 and extending in the Y-direction in plan view.

The working vapor 2a is transported from the evaporation region SR located in the first region 5 to the condensation region CR, and also transported from the evaporation region SR located in the second region 6 to the condensation region CR by way of the bend region 7. A portion of the working liquid 2b that has condensed in the condensation region CR is transported toward the evaporation region SR by the capillary action of the second-land liquid channel part 72 located in the first region 5. Another portion of the working liquid 2b is transported from the second-land liquid channel part 72 located in the first region 5 to the evaporation region SR located in the second region 6, via the first-land liquid channel part 71 and via the second-land liquid channel part 72 located in the second region 6.

As illustrated in FIG. 34, the electronic device D is disposed on the first region 5, and the electronic device D is disposed on the second region 6. This can reduce the risk that heat is transferred between the electronic device D disposed on the first region 5 and the electronic device D disposed on the second region 6. This can in turn reduce the risk that heat generated by one electronic device D causes thermal damage to the other electronic device D.

As described above, according to the third embodiment, each of the first land parts 33 is connected to the second land part 37. More specifically, each of the first land parts 33 is connected to the second land part 37 in the first region 5, and connected to the second land part 37 in the second region 6. The working liquid 2b is thus allowed to move back and forth between the first region 5 and the second region 6. Further, the evaporation region SR with which the electronic device D overlaps can be positioned in each of the first region 5 and the second region 6. Consequently, heat generated by a plurality of electronic devices D can be dissipated by means of a single vapor chamber 1.

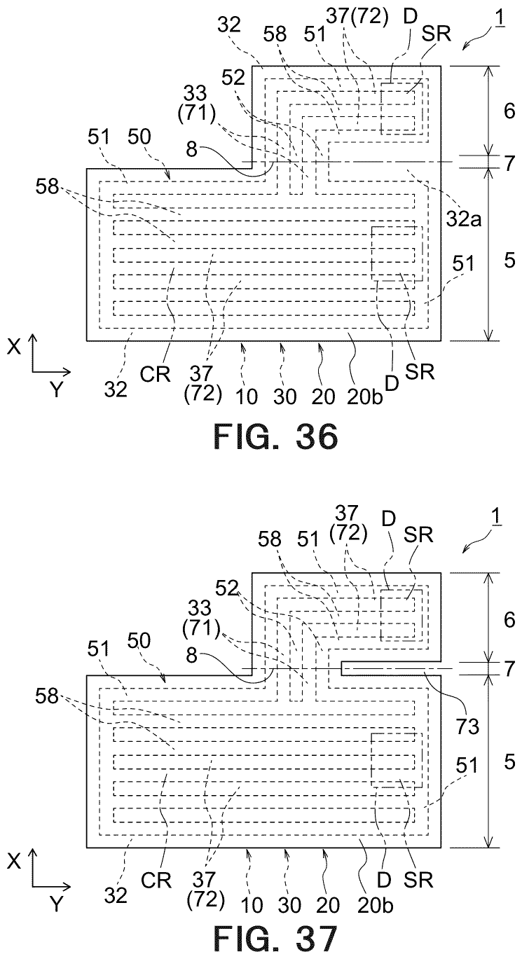

The foregoing description of the third embodiment is directed to the example in which the bend line 8 overlaps the third vapor passage 58 located in the bend region 7 and extending in the Y-direction in plan view. This, however, is not intended to be limiting. For example, in plan view, the bend line 8 may overlap the second land part 37 located in the bend region 7 as illustrated in FIG. 35. Alternatively, the bend line 8 may overlap the frame part 32 as illustrated in FIG. 36. In the example illustrated in FIG. 36, the frame part 32 includes an inwardly projecting part 32a extending in the Y-direction. The bend line 8 may overlap the inwardly projecting part 32a. Alternatively, as illustrated in FIG. 37, the bend line 8 may overlap a slit 73, which is provided between the first region 5 and the second region 6. The slit 73 may be a space located between the first region 5 and the second region 6 and where the first sheet 10, the second sheet 20, and the wick sheet 30 are not present.

### Fourth Embodiment

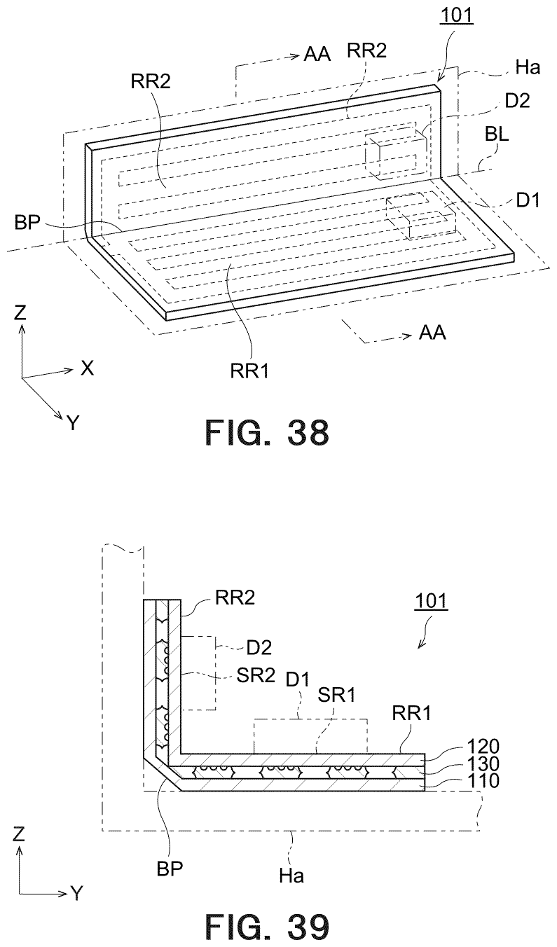

Now, reference is made to FIGS. 38 to 46 to describe a vapor chamber, an electronic apparatus, and a method for manufacturing a vapor chamber according to a fourth embodiment of the present disclosure.

According to the fourth embodiment, the electronic apparatus E may include a plurality of devices D. For example, the devices D may include a first device D1, and a second device D2. The first device D1 may be in thermal contact with a first region RR1 of a vapor chamber 101 (described later), and may be in thermal contact with a second region RR2 of the vapor chamber 101 (described later) (see FIGS. 38 to 40).

The vapor chamber 101 according to the fourth embodiment is described below. The vapor chamber 101 includes a hermetically sealed space 103 with working fluids 102a and 102b sealed therein. The vapor chamber 101 is configured to effectively cool the device D of the electronic apparatus E mentioned above as the working fluids 102a and 102b within the hermetically sealed space 103 undergo repeated phase changes. Examples of the working fluids 102a and 102b include pure water, ethanol, methanol, acetone, and liquid mixtures thereof.

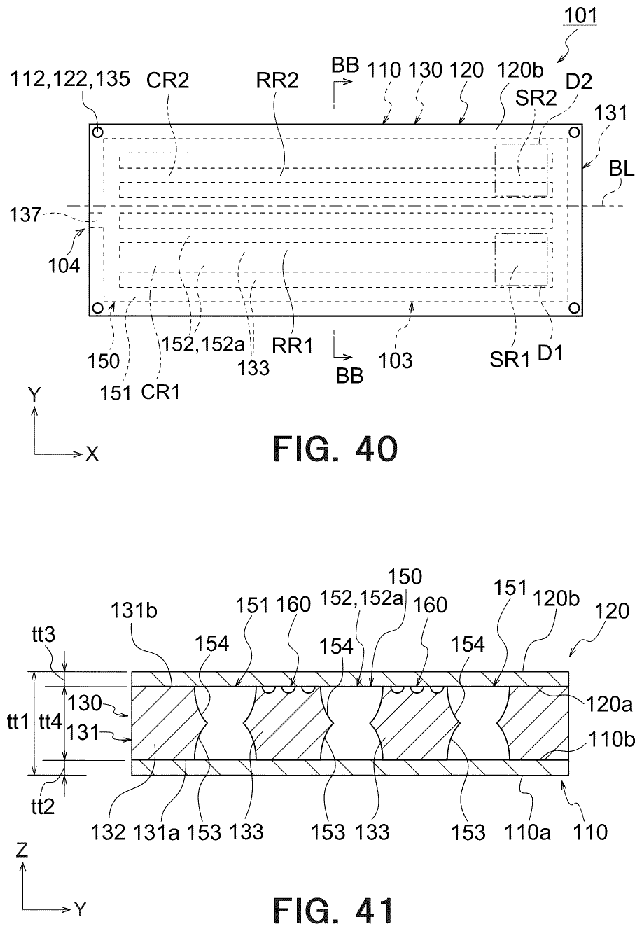

As illustrated in FIGS. 38 and 39, the vapor chamber 101 according to the fourth embodiment is a bent vapor chamber 101. Such a bent vapor chamber 101 can, for instance, be fabricated by bending, along the bend line BL, the vapor chamber 101 having the shape of a thin flat plate as illustrated in FIG. 40. The bent vapor chamber 101 includes a bend part BP, the first region RR1, and the second region RR2. The term “bend” is used herein as a synonym for “fold.” For example, bending the vapor chamber 101 means folding the vapor chamber 101.

The bend part BP is a portion of the vapor chamber 101 where a first sheet 110, a second sheet 120, and a body sheet 130, which constitute the vapor chamber 101, are bent. The bend part BP is formed by bending the vapor chamber 101 along the bend line BL. The bend part BP is a region including the bend line BL and having a predetermined width. The bend angle at the bend part BP may be any angle. In the illustrated example, the bend angle is 90 degrees (a right angle). The vapor chamber 101 thus has a substantially L-shaped cross-section as illustrated in FIG. 39. This, however, is not intended to be limiting. In one alternative example, the vapor chamber 101 may be bent into a curve such that the vapor chamber 101 has a U-shaped cross-section. In another alternative example, the vapor chamber 101 may be bent a plurality of times such that the vapor chamber 101 has, for example, a rectangular U-shaped cross-section.

The first region RR1 and the second region RR2 are regions separated via the bend part BP. In the example illustrated in FIG. 38, the first region RR1 is a region on the vapor chamber 101 that is located on the positive side in the Y-direction (the near side in FIG. 38) relative to the bend part BP, and the second region RR2 is a region on the vapor chamber 101 that is located on the positive side in the Z-direction (the upper side in FIG. 38) relative to the bend part BP. In the illustrated example, the first region RR1 extends in the XY-plane, and the second region RR2 extends in the XZ-plane. A plane defined by the first region RR1, and a plane defined by the second region RR2 are orthogonal to each other.

In this case, the X-direction represents a direction aligned with the longitudinal direction of the vapor chamber 101 in its unbent state as illustrated in FIG. 40. The Y-direction represents a direction aligned with the transverse direction of the unbent vapor chamber 101. The Z-direction represents a direction aligned with the direction of thickness of the unbent vapor chamber 101. The X-direction, the Y-direction, and the Z-direction are orthogonal to each other.

In the following description of the vapor chamber 101 according to the fourth embodiment, reference is made to FIGS. 40 to 46, which illustrate the vapor chamber 101 in its unbent state. For FIGS. 40 to 46 as well, a region on the vapor chamber 101 that will become the first region RR1 upon bending of the vapor chamber 101 is likewise referred to as first region RR1, and a region on the vapor chamber 101 that will become the second region RR2 upon bending of the vapor chamber 101 is likewise referred to as second region RR2.

As illustrated in FIGS. 39 to 41, the vapor chamber 101 includes the first sheet 110, the second sheet 120, and the body sheet 130 (wick sheet) interposed between the first sheet 110 and the second sheet 120. In the vapor chamber 101 according to the fourth embodiment, the first sheet 110, the body sheet 130, and the second sheet 120 are stacked in this order.

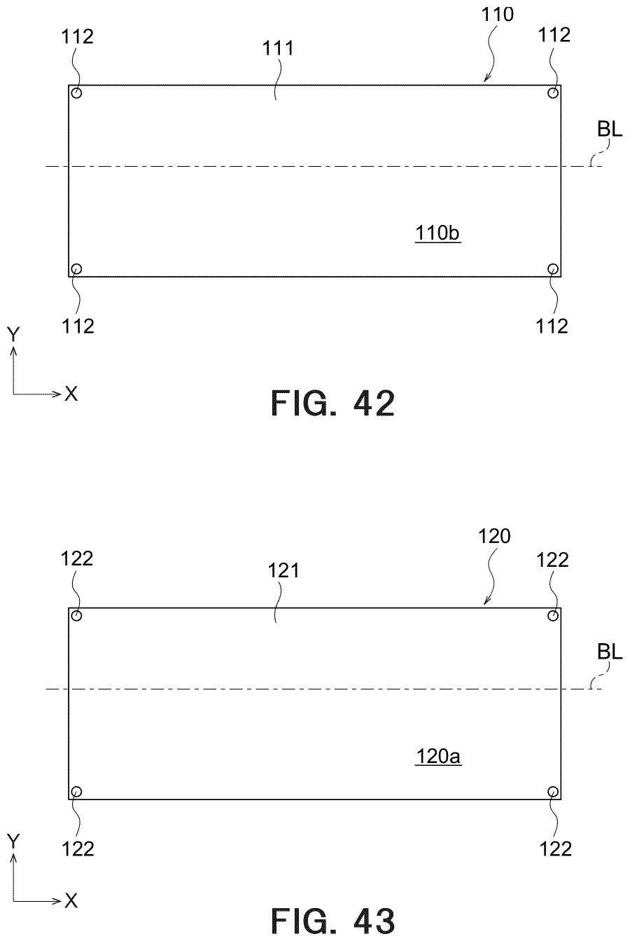

The vapor chamber 101 illustrated in FIG. 40 is in the form of a thin flat plate. Although the vapor chamber 101 may have any shape in plan view, the vapor chamber 101 may have a rectangular shape in plan view as illustrated in FIG. 40. The shape of the vapor chamber 101 in plan view may be, for example, a rectangle whose one side measures 10 mm or more and 200 mm or less and whose other side measures 50 mm or more and 600 mm or less, or may be a square whose one side measures 40 mm or more and 300 mm or less. The vapor chamber 101 may be of any dimensions in plan view. The following description of the fourth embodiment is directed by way of example to a case in which the shape of the vapor chamber 101 in plan view is a rectangle having a longitudinal direction and a transverse direction. In this case, as illustrated in FIGS. 42 to 44, the first sheet 110, the second sheet 120, and the body sheet 130 in their unbent state may likewise have a shape in plan view similar to that of the vapor chamber 101 illustrated in FIG. 40. The shape of the vapor chamber 101 in plan view is not limited to a rectangle but may be any shape, such as a circle, an ellipse, an L-shape, a T-shape, or a U-shape.

As illustrated in FIGS. 39 and 40, the vapor chamber 101 includes evaporation regions SR1 and SR2 where the working fluids 102a and 102b evaporate, and condensation regions CR1 and CR2 where the working fluids 102a and 102b condense. According to the fourth embodiment, the first region RR1 of the vapor chamber 101 is provided with the first evaporation region SR1 and the first condensation region CR1, and the second region RR2 of the vapor chamber 101 is provided with the second evaporation region SR2 and the second condensation region CR2.

The first evaporation region SR1 is a region that overlaps the first device D1 when viewed in the thickness direction (the Z-direction in FIG. 39) of the vapor chamber 101 (i.e., in plan view), and is a region to which the first device D1 is mounted. The first evaporation region SR1 may be located at any position in the first region RR1 of the vapor chamber 101. In the illustrated example, the first evaporation region SR1 is provided at the positive side in the X-direction of the first region RR1 of the vapor chamber 101 (the right side in FIG. 40). Heat from the first device D1 is transferred to the first evaporation region SR1, and the transferred heat causes the working fluid in a liquid state (to be referred to as working liquid 102b as appropriate) to evaporate in the first evaporation region SR1. The heat from the first device D1 may be transferred not only to a region overlapping the first device D1, but also to the vicinity of the region. Accordingly, the first evaporation region SR1 can include a region overlapping the first device D1, and the vicinity of the region.

The first condensation region CR1 is a region that does not overlap the first device D1 when viewed in the thickness direction (the Z-direction in FIG. 39) of the vapor chamber 101 (i.e., in plan view), and is a region where mainly the working fluid in a gaseous state (to be referred to as working vapor 102a as appropriate) releases its heat and condenses. The first condensation region CR1 can be also said to be a region located around the first evaporation region SR1 in the first region RR1. In the illustrated example, the first condensation region CR1 is provided at the negative side in the X-direction of the first region RR1 of the vapor chamber 101 (the left side in FIG. 40). In the first condensation region CR1, the heat of the working vapor 102a from the first evaporation region SR1 is rejected to the first sheet 110. The working vapor 102a is thus cooled and condenses in the first condensation region CR1.

The second evaporation region SR2 is a region that overlaps the second device D2 when viewed in the thickness direction (the Y-direction in FIG. 39) of the vapor chamber 101 (i.e., in plan view), and is a region to which the second device D2 is mounted. The second evaporation region SR2 may be located at any position in the second region RR2 of the vapor chamber 101. In the illustrated example, the second evaporation region SR2 is provided at the positive side in the X-direction of the second region RR2 of the vapor chamber 101 (the right side in FIG. 40). Heat from the second device D2 is transferred to the second evaporation region SR2, and the transferred heat causes the working liquid 102b to evaporate in the second evaporation region SR2. The heat from the second device D2 may be transferred not only to a region overlapping the second device D2, but also to the vicinity of the region. Accordingly, the second evaporation region SR2 can include a region overlapping the second device D2, and the vicinity of the region.

The second condensation region CR2 is a region that does not overlap the second device D2 when viewed in the thickness direction (the Y-direction in FIG. 39) of the vapor chamber 101 (i.e., in plan view), and is a region where mainly the working vapor 102a releases its heat and condenses. The second condensation region CR2 can be also said to be a region located around the second evaporation region SR2 in the second region RR2. In the illustrated example, the second condensation region CR2 is located at the negative side in the X-direction of the second region RR2 of the vapor chamber 101 (the left side in FIG. 40). In the second condensation region CR2, the heat of the working vapor 102a from the second evaporation region SR2 is rejected to the first sheet 110. The working vapor 2a is thus cooled and condenses in the second condensation region CR1.

As used herein, the term “plan view” refers to viewing in a direction that is orthogonal to a face of the vapor chamber 101 that receives heat from the electronic device D, and to a face of the vapor chamber 101 that releases the received heat. That is, the term refers to viewing in a direction that is orthogonal to a first-sheet outer face 110a (described later) of the first sheet 110 of the vapor chamber 101, and to a second-sheet outer face 120b (described later) of the second sheet 120. For example, for the first region RR1 of the vapor chamber 101 in its bent state, its plan view corresponds to a view seen in the Z-direction as illustrated in FIGS. 38 and 39. For the second region RR2, its plan view corresponds to a view seen in the Y-direction.

As illustrated in FIG. 41, the first sheet 110 has the first-sheet outer face 110a located opposite from the body sheet 130, and a first-sheet inner face 110b located opposite from the first-sheet outer face 110a (i.e., located near the body sheet 130). The first sheet 110 may have a generally flat shape. The first sheet 110 may have a generally constant thickness. The housing component Ha constituting a portion of the housing H of, for example, a mobile terminal is mounted to the first-sheet outer face 110a (se FIGS. 38 and 39). The entire first-sheet outer face 110a may be covered by the housing component Ha. As illustrated in FIG. 42, an alignment hole 112 may be disposed at each of the four corners of the first sheet 110.

As illustrated in FIG. 41, the second sheet 120 has a second-sheet inner face 120a located near the body sheet 130, and the second-sheet outer face 120b located opposite from the second-sheet inner face 120a. The second sheet 120 may have a generally flat shape. The second sheet 120 may have a generally constant thickness. The devices D1 and D2 are mounted to the second-sheet outer face 120b. As illustrated in FIG. 43, an alignment hole 122 may be disposed at each of the four corners of the second sheet 120.

In the example mentioned above, the housing component Ha is mounted to the first-sheet outer face 110a of the first sheet 110, and the devices D1 and D2 are mounted to the second-sheet outer face 120b of the second sheet 120. This, however, is not intended to be limiting. In one alternative example, the devices D1 and D2 may be mounted to the first-sheet outer face 110a of the first sheet 110, and the housing component Ha may be mounted to the second-sheet outer face 120b of the second sheet 120. In another alternative example, the housing component Ha and the devices D1 and D2 may be mounted to the first-sheet outer face 110a of the first sheet 110, or the housing component Ha and the devices D1 and D2 may be mounted to the second-sheet outer face 120b of the second sheet 120.

As illustrated in FIG. 41, the body sheet 130 includes a sheet body 131, and a vapor channel part 150 disposed in the sheet body 131. The sheet body 131 has a first body face 131a, and a second body face 131b located opposite from the first body face 131a. The first body face 131a is located near the first sheet 110, and the second body face 131b is located near the second sheet 120.

The first-sheet inner face 110b of the first sheet 110, and the first body face 131a of the sheet body 131 may be permanently bonded to each other through thermocompression bonding. Likewise, the second-sheet inner face 120a of the second sheet 120, and the second body face 131b of the sheet body 131 may be permanently bonded to each other through thermocompression bonding. An example of thermocompression bonding is diffusion bonding. However, the method for bonding the first sheet 110, the second sheet 120, and the body sheet 130 to each other does not necessarily have to be diffusion bonding but may be any bonding method that allows these sheets to be permanently bonded to each other, such as brazing. As used herein, the term “permanently bonded” is not bound by the strict meaning of the term. Rather, the term is used to mean being bonded to an extent such that bonding between the first sheet 110 and the body sheet 130, and bonding between the second sheet 120 and the second sheet 120 can be maintained to an extent that allows the hermetic sealing of the hermetically sealed space 103 to be maintained during operation of the vapor chamber 101.

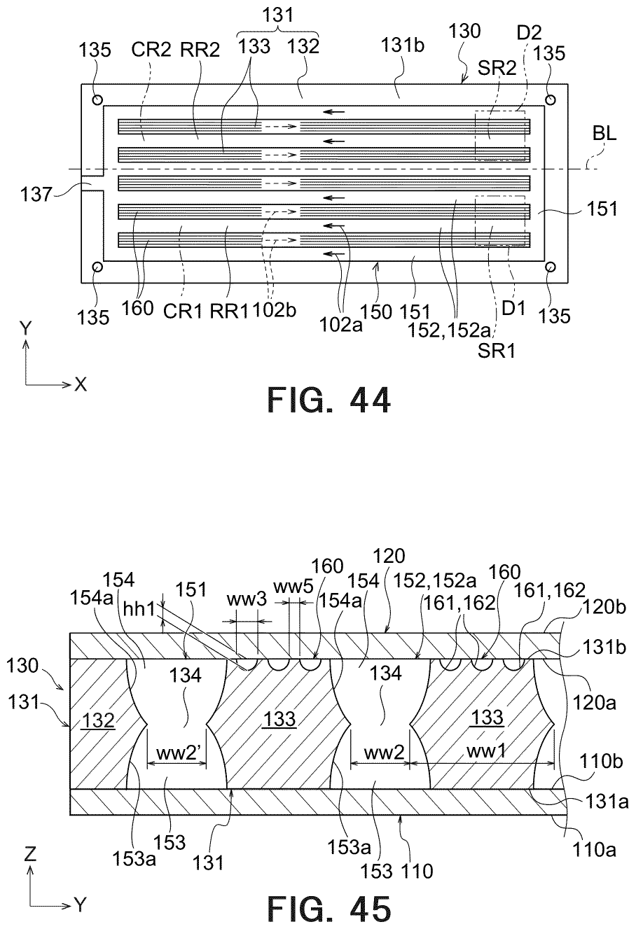

As illustrated in FIGS. 40 and 44, the sheet body 131 includes a frame part 132, and a plurality of land parts 133 disposed inside the frame part 132. The frame part 132 and the land part 133 are parts where the material of the body sheet 130 remains without being etched away in an etching step (described later).

In the illustrated example, the frame part 132 is in the form of a rectangular frame when viewed in the thickness direction of the body sheet 130 (the Z-direction in FIG. 44). The vapor channel part 150 is disposed inside the frame part 132. The vapor channel part 150 contains the working fluids 102a and 102b. The land parts 133 are disposed in the vapor channel part 150. The working vapor 102a flows around the land parts 133. That is, the vapor channel part 150 includes the land parts 133 mentioned above, and vapor passages 151 and 152 (described later), which are passages disposed around the land parts 133 and through which the working vapor 102a flows.

In the illustrated example, the land part 133 extends in the X-direction (the left-right direction in FIG. 44), and the land part 133 has an elongated rectangular shape in plan view. The land parts 133 are disposed in spaced parallel relation to each other in the Y-direction (the up-down direction in FIG. 44). The land part 133 may have a width ww1 (see FIG. 45) of, for example, 100 μm to 3000 μm. The width ww1 of the land part 133 is a dimension of the land part 133 in the Y-direction, and is a dimension at a position in the Z-direction where a through-part 134 (described later) exists.

The frame part 132 and the land parts 133 are bonded to the first sheet 110, and bonded to the second sheet 120. A wall face 153a of a first vapor channel recess 153 (described later), and a wall face 154a of a second vapor channel recess 154 (described later) constitute a side wall of the land part 133. The first body face 131a and the second body face 131b of the sheet body 131 may have a flat shape extending across the frame part 132 and the land parts 133.

The vapor channel part 150 defines a channel through which mainly the working vapor 102a passes. The working liquid 102b may also pass through the vapor channel part 150. As illustrated in FIGS. 41 and 45, the vapor channel part 150 may extend all the way from the first body face 131a to the second body face 131b. That is, the vapor channel part 150 may extend through the sheet body 131 of the body sheet 130. The vapor channel part 150 may be covered at the first body face 131a by the first sheet 110. The vapor channel part 150 may be covered at the second body face 131b by the second sheet 120.

As illustrated in FIG. 44, the vapor channel part 150 includes the first vapor passage 151, and a plurality of second vapor passages 152. The vapor channel part 150 is divided by the land parts 133 into the first vapor passage 151 and the second vapor passages 152. The first vapor passage 151 is provided between the frame part 132 and the land part 133. The first vapor passage 151 is provided contiguously inside the frame part 132 and outside the land parts 133. The first vapor passage 151 is in the form of a rectangular frame in plan view. The second vapor passage 152 is disposed between the land parts 133 that are adjacent to each other. The second vapor passage 152 includes a plurality of vapor passages 152a extending in the first direction. In the illustrated example, the first direction is the X-direction. That is, the vapor passages 152a each extend in the X-direction. The vapor passages 152a each have an elongated rectangular shape in plan view. The vapor passages 152a are disposed in a parallel arrangement.

According to the fourth embodiment, the vapor channel part 150 includes the first vapor passage 151. Alternatively, however, the vapor channel part 150 may include no first vapor passage 151. That is, the frame part 132 and the land part 133 may be disposed adjacent to each other, with no vapor passage provided between the frame part 132 and the land parts 133.

As illustrated in FIG. 41, the first vapor passage 151 and the second vapor passage 152 may extend all the way from the first body face 131a of the sheet body 131 to the second body face 131b. That is, the first vapor passage 151 and the second vapor passage 152 may extend through the sheet body 131 of the body sheet 130. The first vapor passage 151 and the second vapor passage 152 are each defined by the first vapor channel recess 153, and the second vapor channel recess 154. The first vapor channel recess 153 is disposed in the first body face 131a. The second vapor channel recess 154 is disposed in the second body face 131b. The first vapor channel recess 153 and the second vapor channel recess 154 communicate with each other in such a way that the first vapor passage 151 and the second vapor passage 152 of the vapor channel part 150 extend all the way from the first body face 131a to the second body face 131b.

The first vapor channel recess 153 is a recess formed in the first body face 131a through etching performed from the first body face 131a of the body sheet 130 in an etching step (described later). The first vapor channel recess 153 thus has the wall face 153a having a curved shape as illustrated in FIG. 45. The wall face 153a defines the first vapor channel recess 153. As seen in the cross-section illustrated in FIG. 45, the wall face 153a has a curved shape such that the distance between the wall face 153a on one side and the wall face 153a on the other, opposite side decreases with increasing proximity to the second body face 131b. The first vapor channel recess 153 configured as described above constitutes a portion (the lower half) of the first vapor passage 151, and a portion (the lower half) of the second vapor passage 152.

The second vapor channel recess 154 is a recess formed in the second body face 131b through etching performed from the second body face 131b of the body sheet 130 in an etching step (described later). The second vapor channel recess 154 thus has the wall face 154a having a curved shape as illustrated in FIG. 45. The wall face 154a defines the second vapor channel recess 154. As seen in the cross-section illustrated in FIG. 45, the wall face 154a has a curved shape such that the distance between the wall face 154a on one side and the wall face 154a on the other, opposite side decreases with increasing proximity to the first body face 131a. The second vapor channel recess 154 configured as described above constitutes a portion (the upper half) of the first vapor passage 151, and a portion (the upper half) of the second vapor passage 152.

As illustrated in FIG. 45, the wall face 153a of the first vapor channel recess 153, and the wall face 154a of the second vapor channel recess 154 may be connected contiguously to form the through-part 134. The wall face 153a and the wall face 154a are each curved toward the through-part 134. The first vapor channel recess 153 and the second vapor channel recess 154 thus communicate with each other. The through-part 134 in the first vapor passage 151 may have the shape of a rectangular frame in plan view similar to that of the first vapor passage 151. The through-part 134 in the second vapor passage 152 may have the shape of an elongated rectangle in plan view similar to that of the second vapor passage 152. The through-part 134 may be defined by an inwardly projecting edge where the wall face 153a of the first vapor channel recess 153, and the wall face 154a of the second vapor channel recess 54 meet. The area of the vapor channel part 150 in plan view is at its minimum at the through-part 134. The through-part 134 may have a width ww2 or ww2′ (see FIG. 45) of, for example, 100 μm to 3000 μm. The width ww2 of the through-part 134 in this case corresponds to the gap between the land parts 133 that are adjacent to each other in the Y-direction. The width ww2′ of the through-part 134 corresponds to the gap in the Y-direction (or the X-direction) between the frame part 132 and the land part 133.

The position of the through-part 134 in the Z-direction may be the midway position between the first body face 131a and the second body face 131b, or may be displaced downward or upward relative to the midway position. The through-part 134 may be located at any position as long as the first vapor channel recess 153 and the second vapor channel recess 154 communicate with each other.

In the illustrated example, the first vapor passage 151 and the second vapor passage 152 each have a cross-sectional shape that includes the through-part 134 defined by the inwardly projecting edge. This, however, is not intended to be limiting. For example, the first vapor passage 151 and the second vapor passage 152 may each have a cross-section that is a trapezoid or a parallelogram, or a cross-section that is barrel-shaped.

The vapor channel part 150 including the first vapor passage 151 and the second vapor passage 152 configured as described above constitutes a portion of the hermetically sealed space 103 mentioned above. As illustrated in FIG. 41, the first vapor passage 151 and the second vapor passage 152 are defined mainly by the first sheet 110, the second sheet 120, and the frame part 132 and the land part 133 of the sheet body 131 mentioned above. The vapor passages 151 and 152 each have a relatively large channel cross-sectional area to allow passage of the working vapor 102a therethrough.

It is to be noted that for clarity of illustration, FIG. 41 depicts features such as the first vapor passage 151 and the second vapor passage 152 in enlarged scale. The numbers, locations, or other details of the features such as the vapor passages 151 and 152 in FIG. 41 differ from those illustrated in FIGS. 38 to 40 and FIG. 44.

Although not illustrated, a plurality of supports for supporting the land part 133 to the frame part 132 may be disposed in the vapor channel part 150. A support for supporting the land parts 133 that are adjacent to each other may be provided. These supports may be disposed on both sides of the land part 133 in the X-direction, or may be disposed on both sides of the land part 133 in the Y-direction. Each support may be provided in a manner that does not obstruct the flow of the working vapor 102a that diffuses in the vapor channel part 150. For example, the support may be disposed near one of the first body face 131a and the second body face 131b of the body sheet 130, and a space defining a vapor channel recess may be provided near the other one of the first body face 131a and the second body face 131b. The support can be thus made thinner than the sheet body 131. This can prevent the first vapor passage 151 and the second vapor passage 152 from being divided into separate parts in the X-direction and the Y-direction.

As illustrated in FIGS. 41, 44, and 45, a liquid channel part 160 through which mainly the working liquid 102b passes is disposed in the second body face 131b of the sheet body 131 of the body sheet 130. More specifically, the liquid channel part 160 is disposed in the second body face 131b of each land part 133 of the body sheet 130. The working vapor 102a may also pass through the liquid channel part 160. The liquid channel part 160 constitutes a portion of the hermetically sealed space 103 mentioned above. The liquid channel part 160 communicates with the vapor channel part 150. The liquid channel part 160 is implemented as a capillary structure (wick) for transporting the working liquid 102b to the evaporation regions SR1 and SR2. The liquid channel part 160 may be provided across the entire second body face 131b of each land part 133. The liquid channel part 160 is positioned to extend in the first direction, that is, the X-direction. In the illustrated example, the liquid channel part 160 is not disposed in the first body face 131a in the land part 133 of the sheet body 131. Alternatively, however, the liquid channel part 160 may be disposed in the second body face 131b in the land part 133 of the sheet body 131.

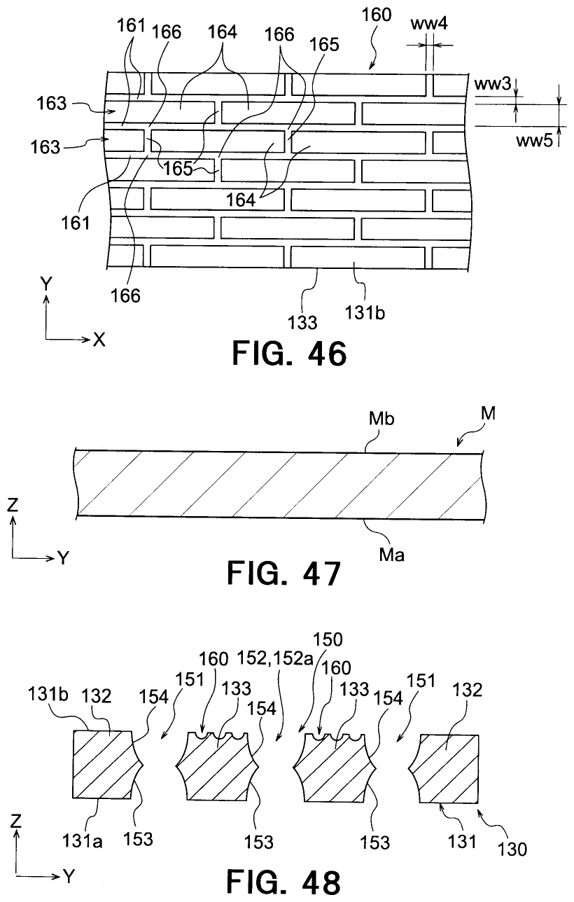

As illustrated in FIG. 46, the liquid channel part 160 includes a plurality of grooves disposed in the second body face 131b. More specifically, the liquid channel part 160 includes a plurality of liquid-channel main flow grooves 161 through which the working liquid 102b passes, and a plurality of liquid-channel communication grooves 165 communicating with the liquid-channel main flow grooves 161.

Each liquid-channel main flow groove 161 extends in the X-direction as illustrated in FIG. 46. To ensure that mainly the working liquid 102b flows through the liquid-channel main flow groove 161 due to capillary action, the liquid-channel main flow groove 161 has a channel cross-sectional area smaller than that of the first vapor passage 151 or the second vapor passage 152 of the vapor channel part 150. The liquid-channel main flow groove 161 is thus configured to transport, to the evaporation regions SR1 and SR2, the working liquid 102b that has condensed from the working vapor 102a. The liquid-channel main flow grooves 161 may be spaced apart from each other in the Y-direction.

The liquid-channel main flow groove 161 is formed in an etching step (described later) through etching performed from the second body face 131b of the sheet body 131 of the body sheet 130. The liquid-channel main flow groove 161 thus has a curved wall face 162 as illustrated in FIG. 45. The wall face 162 defines the liquid-channel main flow groove 161, and has a curved shape that is recessed toward the first body face 131a.

The liquid-channel main flow groove 161 illustrated in FIGS. 45 and 46 may have a width ww3 (a dimension in the Y-direction) of, for example, 5 μm to 150 μm. The width ww3 of the liquid-channel main flow groove 161 means a dimension at the location of the second body face 131b. The liquid-channel main flow groove 161 illustrated in FIG. 45 may have a depth hh1 (a dimension in the Z-direction) of, for example, 3 μm to 150 μm.

As illustrated in FIG. 46, each liquid-channel communication groove 165 extends in a direction different from the X-direction. In the illustrated example, each liquid-channel communication groove 165 extends in the Y-direction, and is perpendicular to the liquid-channel main flow groove 161. Some liquid-channel communication grooves 165 are positioned to provide communication between the liquid-channel main flow grooves 161 that are adjacent to each other. Other liquid-channel communication grooves 165 are positioned to provide communication between the vapor channel part 150 (the first vapor passage 151 or the second vapor passage 152) and the liquid-channel main flow groove 161. That is, each of the other liquid-channel communication grooves 165 extends from a side edge of the land part 133 in the Y-direction to the liquid-channel main flow groove 161 adjacent to the side edge. In this way, the first vapor passage 151 or the second vapor passage 152 of the vapor channel part 150, and the liquid-channel main flow groove 161 communicate with each other.

To ensure that mainly the working liquid 102b flows through the liquid-channel communication groove 165 due to capillary action, the liquid-channel communication groove 165 has a channel cross-sectional area smaller than that of the first vapor passage 151 or the second vapor passage 152 of the vapor channel part 150. The liquid-channel communication grooves 165 may be spaced apart from each other in the X-direction.

As with the liquid-channel main flow groove 161, the liquid-channel communication groove 165 is formed through etching. As with the liquid-channel main flow groove 161, the liquid-channel communication groove 165 has a curved wall face (not illustrated). The liquid-channel communication groove 165 illustrated in FIG. 46 may have a width ww4 (a dimension in the X-direction) equal to the width ww3 of the liquid-channel main flow groove 161. Alternatively, however, the width ww4 may be greater than the width ww3, or may be less than the width ww3. The liquid-channel communication groove 165 may have a depth equal to the depth hh1 of the liquid-channel main flow groove 161. Alternatively, however, the depth of the liquid-channel communication groove 165 may be greater than the depth hh1, or may be less than the depth hh1.

As illustrated in FIG. 46, the liquid channel part 160 includes liquid-channel projection rows 163 disposed in the second body face 131b of the sheet body 131. Each liquid-channel projection row 163 is disposed between the liquid-channel main flow grooves 161 that are adjacent to each other. Each liquid-channel projection row 163 includes a plurality of liquid-channel projections 164 arranged in the X-direction. The liquid-channel projection 164 is disposed in the liquid channel part 160, and abuts on the second sheet 120. Each liquid-channel projection 164 has a rectangular shape in plan view with its longitudinal direction aligned with the X-direction. The liquid-channel main flow groove 161 is interposed between the liquid-channel projections 164 that are adjacent to each other in the Y-direction. The liquid-channel communication groove 165 is interposed between the liquid-channel projections 164 that are adjacent to each other in the X-direction. The liquid-channel communication groove 165 extends in the Y-direction, and provides communication between the liquid-channel main flow grooves 161 that are adjacent to each other in the Y-direction. This allows the working liquid 102b to move back and forth between the adjacent liquid-channel main flow grooves 161.

The liquid-channel projection 164 is a part where the material of the body sheet 130 remains without being etched away in an etching step (described later). In the example illustrated in FIG. 46, the shape of the liquid-channel projection 164 in plan view (its shape at the location of the second body face 131b of the sheet body 131 of the body sheet 130) is a rectangle.

In the example illustrated in FIG. 46, the liquid-channel projections 164 are disposed in a staggered arrangement. More specifically, the liquid-channel projections 164 of the liquid-channel projection rows 163 that are adjacent to each other in the Y-direction are displaced relative to each other in the X-direction. The amount of displacement may be half the arrangement pitch of the liquid-channel projections 164 in the X-direction. The liquid-channel projection 164 may have a width ww5 (a dimension in the Y-direction) of, for example, 5 μm to 500 μm. The width ww5 of the liquid-channel projection 164 means a dimension at the location of the second body face 131b. The liquid-channel projections 164 are not necessarily disposed in a staggered arrangement. Alternatively, the liquid-channel projections 164 may be arranged in parallel. In this case, the liquid-channel projections 164 of the liquid-channel projection rows 163 that are adjacent to each other in the Y-direction are aligned in the X-direction as well.

The liquid-channel main flow groove 161 includes a liquid-channel intersection 166 communicating with the liquid-channel communication groove 165. At the liquid-channel intersection 166, the liquid-channel main flow groove 161 and the liquid-channel communication groove 165 communicate with each other by intersecting in a T-shape. This configuration makes it possible to avoid a situation in which, at the liquid-channel intersection 166 where one liquid-channel main flow groove 161, and the liquid-channel communication groove 165 located on one side (e.g., the upper side in FIG. 46) of the one liquid-channel main flow groove 161 communicate with each other, the liquid-channel communication groove 165 located on the other side (e.g., the lower side in FIG. 46) of the one liquid-channel main flow groove 161 communicates with the one liquid-channel main flow groove 161. Consequently, at the above-mentioned liquid-channel intersection 166, the wall face 162 of the liquid-channel main flow groove 161 can be prevented from being cut away on both sides (the upper side and the lower side in FIG. 46), and the wall face 162 is thus allowed to remain on one side. As a result, even at the liquid-channel intersection 166, capillary action can be imparted to the working liquid within the liquid-channel main flow groove 161. This can reduce the risk that the propulsion force that causes the working liquid 102b to travel toward the evaporation region SR decreases at the liquid-channel intersection 166.

As illustrated in FIG. 44, an alignment hole 135 may be disposed at each of the four corners of the sheet body 131 of the body sheet 130. Although the alignment hole 135 has a circular shape in plan view in the example illustrated in FIG. 44, this is not intended to be limiting. The alignment hole 135 may extend through the sheet body 131 of the body sheet 130.

As illustrated in FIG. 40, the vapor chamber 101 may include an injection part 104 for injecting the working liquid 102b into the hermetically sealed space 103. The injection part 104 is disposed at an edge of the vapor chamber 101 that is located at the negative side in the X-direction (the left side in FIG. 40). In the example illustrated in FIG. 40, the injection part 104 is disposed near the condensation regions CR1 and CR2. The injection part 104 may include an injection channel 137 provided in the body sheet 130. The injection channel 137 may be sealed off after the working liquid 102b is injected.

As described above, the vapor chamber 101 according to the fourth embodiment is bent along the bend line BL (see FIGS. 38 and 39). The bend line BL extends in a direction parallel to the first direction in which the vapor passage 152a mentioned above extends. The vapor chamber 101 is thus bent in the direction parallel to the first direction. As mentioned above, according to the fourth embodiment, the first direction is the X-direction. As illustrated in FIG. 39, the vapor chamber 101 may be bent in such a way that the first sheet 110 is located at the outer side of the bend, and the second sheet 120 is located at the inner side of the bend.

The vapor chamber 101 may be bent at a position where the vapor passage 152a is disposed. That is, the vapor chamber 101 may be bent along the vapor passage 152a.

The vapor passage 152a may have a decreased channel cross-sectional area in the bend part BP. For example, as illustrated in FIG. 39, the vapor passage 152a may have a decreased channel cross-sectional area in the bend part BP due to contact between the first-sheet inner face 110b of the first sheet 110, and the second-sheet inner face 120a of the second sheet 120. This results in reduced back-and-forth movement of the working vapor 102a between the first region RR1 and the second region RR2.

As the vapor chamber 101 is bent, the first sheet 110 deforms under tensile stress in the bend part BP in such a way that the first sheet 110 is recessed inward (toward the second sheet 120). The second sheet 120 deforms under compressive stress in the bend part BP in such a way that the second sheet 120 is recessed inward (toward the first sheet 110). Consequently, as illustrated in FIG. 39, bending the vapor chamber 1 may cause contact to be made between the first-sheet inner face 110b of the first sheet 110 and the second-sheet inner face 120a of the second sheet 120, which may in turn cause the vapor passage 152a to decrease in cross-sectional area.

In the above-mentioned illustrated example, the first-sheet inner face 110b of the first sheet 110, and the second-sheet inner face 120a of the second sheet 120 are in contact with each other. This, however, is not intended to be limiting. In the bend part BP, the first-sheet inner face 110b of the first sheet 110, and the second-sheet inner face 120a of the second sheet 120 may have a gap therebetween rather than making contact with each other. In such a case well, in the bend part BP, the channel cross-sectional area of the vapor passage 152a decreases, which allows for reduced back-and-forth movement of the working vapor 102a between the first region RR1 and the second region RR2.

The first sheet 110, the second sheet 120, and the body sheet 130 may be made of any material without particular limitation, as long as the material has favorable thermal conductivity. For example, the first sheet 110, the second sheet 120, and the body sheet 130 may contain copper or a copper alloy. This can improve the thermal conductivity of the sheets 110, 120, and 130, and consequently improve the heat dissipation efficiency of the vapor chamber 101. This can also prevent corrosion for cases where pure water is used as the working fluids 102a and 102b. The sheets 110, 120, and 130 can be made of other metals such as aluminum or titanium, or other metallic alloys such as stainless steel, as long as use of such metallic materials allows a desired heat dissipation efficiency to be attained and also enables corrosion prevention.

The vapor chamber 101 illustrated in FIG. 41 may have a thickness tt1 of, for example, 100 μm to 1000 μm. Making the thickness tt1 of the vapor chamber 101 greater than or equal to 100 μm can ensure adequate space for the vapor channel part 150, and proper functioning of the vapor chamber 101. By contrast, making the thickness tt1 of the vapor chamber 101 less than or equal to 100 μm can mitigate an increase in the thickness tt1 of the vapor chamber 101.

The first sheet 110 illustrated in FIG. 41 may have a thickness tt2 of, for example, 6 μm to 100 μm. Making the thickness tt2 of the first sheet 110 greater than or equal to 6 μm can ensure mechanical strength of the first sheet 110. By contrast, making the thickness tt2 of the first sheet 110 less than or equal to 100 μm can mitigate an increase in the thickness tt1 of the vapor chamber 101. Likewise, the second sheet 120 illustrated in FIG. 41 may have a thickness tt3 that is set similarly to the thickness tt2 of the first sheet 110. The thickness tt3 of the second sheet 120, and the thickness tt2 of the first sheet 110 may be different.

The body sheet 130 illustrated in FIG. 41 may have a thickness tt4 of, for example, 50 μm to 400 μm. Making the thickness tt4 of the body sheet 130 greater than or equal to 50 μm can ensure adequate space for the vapor channel part 150, and proper functioning of the vapor chamber 101. By contrast, making the thickness tt4 of the body sheet 130 less than or equal to 400 μm can mitigate an increase in the thickness tt1 of the vapor chamber 101.

A method for manufacturing the vapor chamber 101 configured as described above is now described with reference to FIGS. 47 to 50.

Now, reference is first made to a sheet preparing step, which is a step of preparing the sheets 110, 120, and 130. The sheet preparing step includes the following steps: a first-sheet preparing step of preparing the first sheet 110; a second-sheet preparing step of preparing the second sheet 120; and a body-sheet preparing step of preparing the body sheet 130.

In the first-sheet preparing step, first, a first-sheet base material with a desired thickness is prepared. The first-sheet base material may be a rolled material. Subsequently, the first sheet 110 having a desired shape in plan view is formed through etching of the first-sheet base material. Alternatively, the first sheet 110 having a desired shape in plan view may be formed through press working of the first-sheet base material. In this way, the first sheet 110 having an outline shape as illustrated in FIG. 42 can be prepared.

Likewise, in the second-sheet preparing step, first, a second sheet base material with a desired thickness is prepared in a manner similar to the first-sheet preparing step. The second sheet base material may be a rolled material. Subsequently, the second sheet 120 having a desired shape in plan view is formed through etching of the second-sheet base material. Alternatively, the second sheet 120 having a desired shape in plan view may be formed through press working of the second-sheet base material. In this way, the second sheet 120 having an outline shape as illustrated in FIG. 43 can be prepared.

The body-sheet preparing step includes a material-sheet preparing step of preparing a metallic material sheet M, and an etching step of etching the metallic material sheet M.

First, in the material-sheet preparing step, the metallic material sheet M having a flat shape and including a first material face Ma and a second material face Mb is prepared as illustrated in FIG. 47. The metallic material sheet M may be a rolled material with a desired thickness.

In the subsequent etching step, as illustrated in FIG. 48, etching is performed on the metallic material sheet M from the first material face Ma and the second material face Mb to form the vapor channel part 150 and the liquid channel part 160.

More specifically, a patterned resist film (not illustrated) is formed on the first material face Ma and the second material face Mb of the metallic material sheet M by the photolithography technique. The patterned resist film includes a pattern for, for example, the vapor channel part 150 and the liquid channel part 160 mentioned above. Subsequently, the first material face Ma and the second material face Mb of the metallic material sheet M are etched through an opening provided in the patterned resist film. Consequently, the first material face Ma and the second material face Mb of the metallic material sheet M are etched into a patterned shape, and the vapor channel part 150 and the liquid channel part 160 as illustrated in FIG. 48 are formed. Suitable examples of the etchant to be used at this time may include an iron chloride etchant such as a ferric chloride aqueous solution, and a copper chloride etchant such as a copper chloride aqueous solution.

In the etching step, the first material face Ma and the second material face Mb of the metallic material sheet M may be etched simultaneously. This, however, is not intended to be limiting. Alternatively, etching of the first material face Ma, and etching of the second material face Mb may be performed individually as separate steps. The vapor channel part 150 and the liquid channel part 160 may be formed simultaneously by etching, or may be formed individually in separate steps.

In the etching step, through etching of the first material face Ma and the second material face Mb of the metallic material sheet M, a predetermined outline shape as illustrated in FIG. 44 can be obtained. That is, the body sheet 130 having outer edges as illustrated in FIG. 44 can be obtained.

In this way, the body sheet 130 as illustrated in FIG. 44 can be prepared.

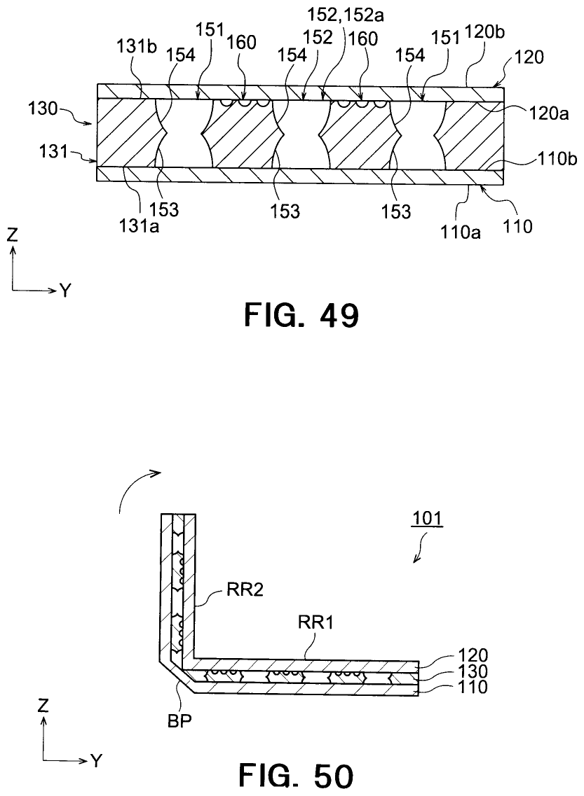

The preparing step is followed by a bonding step in which, as illustrated in FIG. 49, the first sheet 110, the second sheet 120, and the body sheet 130 are bonded to each other.

More specifically, first, the first sheet 110, the second sheet 120, and the body sheet 130 are stacked in this order. In this case, the first body face 131a of the body sheet 130 is overlaid on the first-sheet inner face 110b of the first sheet 110, and the second-sheet inner face 120a of the second sheet 120 is then overlaid on the second body face 131b of the body sheet 130. At this time, positioning of the sheets 110, 120, and 130 may be performed by using the alignment hole 112 of the first sheet 110, the alignment hole 135 of the body sheet 130, and the alignment hole 122 of the second sheet 120.

Subsequently, the first sheet 110, the second sheet 120, and the body sheet 130 are temporarily fastened together. For example, the sheets 110, 120, and 130 may be temporarily fastened together by resistance spot welding, or the sheets 110, 120, and 130 may be temporarily fastened together by laser welding.

Subsequently, the first sheet 110, the second sheet 120, and the body sheet 130 are permanently bonded to each other by thermocompression bonding. For example, the sheets 110, 120, and 130 may be permanently bonded to each other by diffusion bonding. Consequently, the hermetically sealed space 103 including the vapor channel part 150 and the liquid channel part 160 is formed between the first sheet 110 and the second sheet 120. At this point, the hermetically sealed space 103 mentioned above has not yet been sealed off, and thus communicates with the external environment via the injection channel 137.

The bonding step is followed by an injection step, in which the working liquid 102b is injected into the hermetically sealed space 103 from the injection channel 137 of the injection part 104.

The injection step is followed by a sealing step, in which the injection channel 137 is sealed off. This cuts off communication between the hermetically sealed space 103 and the external environment, resulting in hermetic sealing of the hermetically sealed space 103. As a result, the hermetically sealed space 103 with the working liquid 102b sealed therein can be obtained. This can prevent external leakage of the working liquid 102b sealed in the hermetically sealed space 103.

In this way, the vapor chamber 101 as illustrated in FIG. 40 can be obtained, which is in the form of a thin flat plate with the working liquid 102b sealed therein.

The sealing step is followed by a bending step. In the bending step, as illustrated in FIG. 50, the first sheet 110, the second sheet 120, and the body sheet 130 are bent along the bend line BL, that is, in a direction parallel to the first direction in which the vapor passage 152a extends. Consequently, the first region RR1 and the second region RR2 separated via the bend part BP are formed in the vapor chamber 101. The vapor chamber 101 is bent at a position where the vapor passage 152a is disposed. Consequently, as the vapor chamber 101 is bent, the first sheet 110 deforms under tensile stress in the bend part BP in such a way that the first sheet 110 is recessed inward, and the second sheet 120 deforms under compressive stress in the bend part BP in such a that the second sheet 120 is recessed inward. As a result, in the bend part BP, the first-sheet inner face 110b of the first sheet 110, and the second-sheet inner face 120a of the second sheet 120 make contact with each other, which causes the second vapor passage 152 to decrease in channel cross-sectional area. This results in reduced back-and-forth movement of the working vapor 102a between the first region RR1 and the second region RR2. Through the process mentioned above, the vapor chamber 101 in its bent state as illustrated in FIGS. 38 and 39 can be obtained.

Reference is now made to how the vapor chamber 101 operates, that is, how the device D is cooled.

The vapor chamber 101 obtained as described above is installed inside the housing H of, for example, a mobile terminal. At this time, the first-sheet outer face 110a of the first sheet 110 is covered by the housing component Ha, and the devices D1 and D2, which are devices to be cooled such as CPUs, are mounted to the second-sheet outer face 120b of the second sheet 120. The first device D1 is mounted to the first region RR1 of the vapor chamber 101, and the second device D2 is mounted to the second region RR2 of the vapor chamber 101. The working liquid 102b within the hermetically sealed space 103 adheres, due to its surface tension, to the wall faces of the hermetically sealed space 103 including: the wall face 153a of the first vapor channel recess 153; the wall face 154a of the second vapor channel recess 154; the wall face 162 of the liquid-channel main flow groove 161 of the liquid channel part 160; and the wall face of the liquid-channel communication groove 165 of the liquid channel part 160. The working liquid 102b may also adhere to a portion of the first-sheet inner face 110b of the first sheet 110 that is exposed to the first vapor channel recess 153. Further, the working liquid 102b may also adhere to portions of the second-sheet inner face 120a of the second sheet 120 that are exposed to the following areas: the second vapor channel recess 154, the liquid-channel main flow groove 161, and the liquid-channel communication groove 165.

When the first device D1 generates heat in this state, the working liquid 102b in the first evaporation region SR1 (see FIG. 44) receives heat from the first device D1. As the received heat is absorbed as latent heat, the working liquid 102b evaporates (gasifies), and the working vapor 102a is generated. Most of the generated working vapor 102a diffuses within the first vapor channel recess 153 and the second vapor channel recess 154 that constitute the hermetically sealed space 103 (see solid arrows in FIG. 44). The working vapor 102a within each of the vapor channel recesses 153 and 154 moves away from the first evaporation region SR1, and most of the working vapor 102a is transported to the first condensation region CR1 (located at the left side in FIG. 44) that is at a relatively low temperature. In the first condensation region CR1, the working vapor 102a is cooled by rejecting heat mainly to the first sheet 110. The heat received by the first sheet 110 from the working vapor 102a is transferred to the outside air via the housing component Ha (see FIG. 39).

As the working vapor 102a rejects heat to the first sheet 110 in the first condensation region CR1, the working vapor 102a condenses by giving off the latent heat absorbed in the first evaporation region SR1, and the working liquid 102b is generated. The generated working liquid 102b adheres to the respective wall faces 153a and 154a of the vapor channel recesses 153 and 154, the first-sheet inner face 110b of the first sheet 110, and the second-sheet inner face 120a of the second sheet 120. At this time, the working liquid 102b keeps evaporating in the first evaporation region SR1. Accordingly, the working liquid 102b in the first condensation region CR1 is transported by the capillary action of each liquid-channel main flow groove 161 toward the first evaporation region SR1 (see dashed arrows in FIG. 44). Consequently, the working liquid 102b adhering on the wall faces 153a and 154a, the first-sheet inner face 110b, and the second-sheet inner face 120a moves to the liquid channel part 160, where the working liquid 102b passes through the liquid-channel communication groove 165 into the liquid-channel main flow groove 161. In this way, each liquid-channel main flow groove 161 and each liquid-channel communication groove 165 are filled with the working liquid 102b. The working liquid 102b now filling these grooves thus gains, due to the capillary action of each liquid-channel main flow groove 161, a propulsion force that causes the working liquid 102b to move toward the first evaporation region SR1. The working liquid 102b is thus smoothly transported toward the first evaporation region SR1.

In the liquid channel part 160, each liquid-channel main flow groove 161 communicates with another adjacent liquid-channel main flow groove 161 via the corresponding liquid-channel communication groove 165. The working liquid 102b thus moves back and forth between the liquid-channel main flow grooves 161 that are adjacent to each other. This reduces the risk of dry-out in the liquid-channel main flow grooves 161. As a result, capillary action is imparted to the working liquid 102b within each liquid-channel main flow groove 161, and the working liquid 102b is thus smoothly transported toward the first evaporation region SR1.

Upon reaching the first evaporation region SR1, the working liquid 102b evaporates by receiving heat from the first device D1 again. The working vapor 102a evaporated from the working liquid 102b passes through the liquid-channel communication groove 165 within the first evaporation region SR1 to the first vapor channel recess 153 and the second vapor channel recess 154, each of which has a large channel cross-sectional area. The working vapor 102a then diffuses within each of the vapor channel recesses 153 and 154. In this way, as the working fluids 102a and 102b undergo refluxing within the hermetically sealed space 103 while repeating phase changes, that is, evaporation and condensation, the heat from the first device D1 is transported and released. As a result, the first device D1 is cooled.

Likewise, when the second device D2 generates heat, the working liquid 102b in the second evaporation region SR2 (see FIG. 44) receives heat from the second device D2. As the received heat is absorbed as latent heat, the working liquid 102b evaporates (gasifies), and the working vapor 102a is generated. Most of the generated working vapor 102a diffuses within the first vapor channel recess 153 and the second vapor channel recess 154 that constitute the hermetically sealed space 103 (see solid arrows in FIG. 44). The working vapor 102a within each of the vapor channel recesses 153 and 154 moves away from the second evaporation region SR2, and most of the working vapor 102a is transported to the second condensation region CR2 (located at the left side in FIG. 44) that is at a relatively low temperature. In the first condensation region CR2, the working vapor 102a is cooled by rejecting heat mainly to the first sheet 110. The heat received by the first sheet 110 from the working vapor 102a is transferred to the outside air via the housing component Ha (see FIG. 39).

As the working vapor 102a rejects heat to the first sheet 110 in the second condensation region CR2, the working vapor 102a condenses by giving off the latent heat absorbed in the second evaporation region SR2, and the working liquid 102b is generated. The generated working liquid 102b adheres to the respective wall faces 153a and 154a of the vapor channel recesses 153 and 154, the first-sheet inner face 110b of the first sheet 110, and the second-sheet inner face 120a of the second sheet 120. At this time, the working liquid 102b keeps evaporating in the second evaporation region SR2. Accordingly, the working liquid 102b in the second condensation region CR2 is transported by the capillary action of each liquid-channel main flow groove 161 toward the second evaporation region SR2 (see dashed arrows in FIG. 44). Consequently, the working liquid 102b adhering on the wall faces 153a and 154a, the first-sheet inner face 110b, and the second-sheet inner face 120a moves to the liquid channel part 160, where the working liquid 102b passes through the liquid-channel communication groove 165 into the liquid-channel main flow groove 161. In this way, each liquid-channel main flow groove 161 and each liquid-channel communication groove 165 are filled with the working liquid 102b. The working liquid 102b now filling these grooves thus gains, due to the capillary action of each liquid-channel main flow groove 161, a propulsion force that causes the working liquid 102b to move toward the second evaporation region SR2. The working liquid 102b is thus smoothly transported toward the second evaporation region SR2.

In the liquid channel part 160, each liquid-channel main flow groove 161 communicates with another adjacent liquid-channel main flow groove 161 via the corresponding liquid-channel communication groove 165. The working liquid 102b thus moves back and forth between the liquid-channel main flow grooves 161 that are adjacent to each other. This reduces the risk of dry-out in the liquid-channel main flow grooves 161. As a result, capillary action is imparted to the working liquid 102b within each liquid-channel main flow groove 161, and the working liquid 102b is thus smoothly transported toward the second evaporation region SR2.

Upon reaching the second evaporation region SR2, the working liquid 102b evaporates by receiving heat from the second device D2 again. The working vapor 102a evaporated from the working liquid 102b passes through the liquid-channel communication groove 165 within the second evaporation region SR2 to the first vapor channel recess 153 and the second vapor channel recess 154, each of which has a large channel cross-sectional area. The working vapor 102a then diffuses within each of the vapor channel recesses 153 and 154. In this way, as the working fluids 102a and 102b undergo refluxing within the hermetically sealed space 103 while repeating phase changes, that is, evaporation and condensation, the heat from the second device D2 is transported and released. As a result, the second device D2 is cooled.

According to the fourth embodiment, the vapor chamber 101 is bent in a direction parallel to the first direction in which the vapor passage 152a extends. As previously mentioned, in the bend part BP, back-and-forth movement of the working vapor 102a between the first region RR1 and the second region RR2 is reduced. As a result, for the vapor chamber 101 in its bent state, heat transfer via the bend part BP can be reduced. This can provide the ability for a single vapor chamber 101 to function as a plurality of vapor chambers (two vapor chambers according to the fourth embodiment).

The above-mentioned ability can for instance reduce the risk that, when the first device D1 is in operation and generating heat and the second device D2 is not in operation and not generating heat, the working vapor 102a that has received heat from the first device D1 moves from the first region RR1 to the second region RR2, and thus transfers heat to the second device D2. The above-mentioned ability can for instance also reduce the risk that, when the first device D1 is generating a relatively large amount of heat and the second device D2 is generating a relatively small amount of heat, the working vapor 102a that has received heat from the first device D1 moves from the first region RR1 to the second region RR2, and thus transfers heat to the second device D2. In this regard, different kinds of devices D have different heat-resistant temperatures. This means that for a case where the second device D2 has a heat-resistant temperature lower than the heat-resistant temperature of the first device D1, the above-mentioned ability can prevent the second device D2 from being thermally damaged as the heat from the first device D1 is transferred to the second device D2.

As described above, according to the fourth embodiment, the vapor chamber 101 is bent in a direction parallel to the first direction. This can reduce back-and-forth movement of the working vapor 102a between the first region RR1 and the second region RR2 in the bend part BP. As a result, for the vapor chamber 101 in its bent state, heat transfer via the bend part BP can be reduced.

The fourth embodiment can provide the ability for a single vapor chamber 101 to function as a plurality of vapor chambers 101. This allows for reduced cost of manufacturing the vapor chamber 101 in comparison to the cost of manufacturing a plurality of vapor chambers 101.

According to the fourth embodiment, the vapor chamber 101 is bent in a direction parallel to the first direction. This makes it possible to avoid a situation where the bend part BP crosses the vapor passage 152a. This in turn can mitigate an increase in the pressure loss for the working vapor 102a flowing through the vapor passage 152a within each of the regions RR1 and RR2. As a result, deterioration of the heat transport capacity of the vapor chamber 101 can be reduced.

According to the fourth embodiment, the vapor chamber 101 is bent at a position where the vapor passage 152a is disposed. This makes it possible to increase the pressure loss for the working vapor 102a flowing through the vapor passage 152a in the bend part BP. This in turn makes it possible to further reduce back-and-forth movement of the working vapor 102a between the first region RR1 and the second region RR2 in the bend part BP. As a result, heat transfer via the bend part BP can be further reduced.

According to the fourth embodiment, the vapor chamber 101 is bent at a position where the vapor passage 152a is disposed. The vapor chamber 101 can be thus bent easily when the vapor chamber 101 is to be bent in the bending step. This can facilitate manufacture of the vapor chamber 101 that is in a bent state.

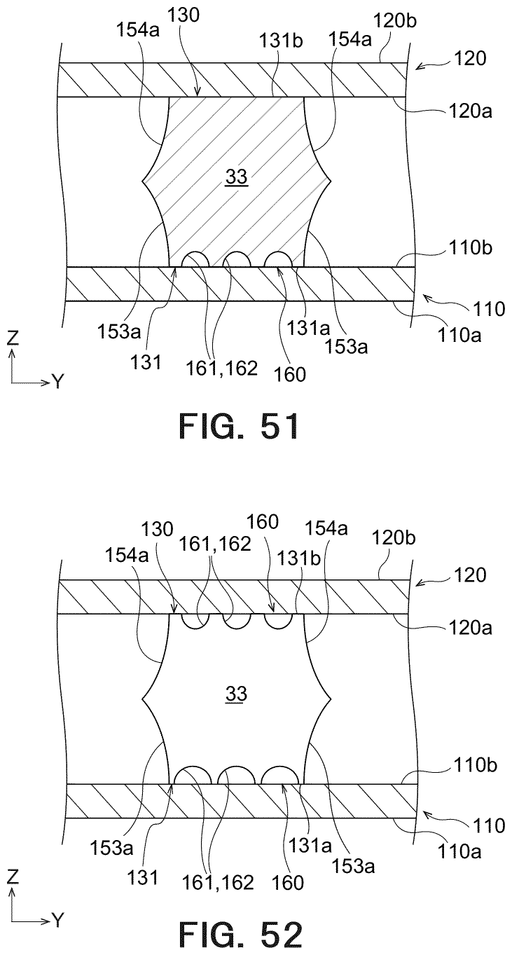

The foregoing description of the fourth embodiment is directed to the example in which the second body face 131b of the land part 133 is provided with the liquid channel part 160, and the first body face 131a of the land part 133 is not provided with the liquid channel part 160. This, however, is not intended to be limiting. Alternatively, as illustrated in FIG. 51, the second body face 131b of the land part 133 may be provided with no liquid channel part 160, and the first body face 131a of the land part 133 may be provided with the liquid channel part 160.

As illustrated in FIG. 52, the second body face 131b of the land part 133 may be provided with the liquid channel part 160, and also the first body face 131a of the land part 133 may be provided with the liquid channel part 160. In this case, the liquid channel part 160 disposed in the first body face 131a, and the liquid channel part 160 disposed in the second body face 131b may be similar to each other in configuration or, alternatively, may be different from each other in configuration. For example, as illustrated in FIG. 52, the liquid channel part 160 disposed in the first body face 131a may have a channel cross-sectional area greater than the channel cross-sectional area of the liquid channel part 160 disposed in the second body face 131b. The liquid channel part 160 disposed in the first body face 131a may, during a period when the electronic device D is not generating heat, function as a liquid reservoir.

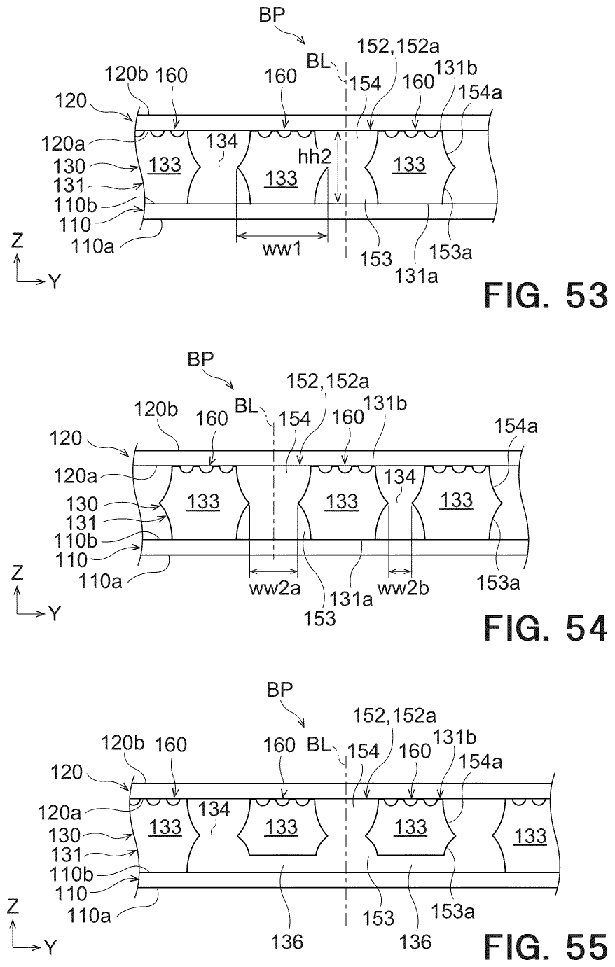

According to the fourth embodiment mentioned above, as illustrated in FIG. 53, the vapor passage 152a in the bend part BP may have a height hh2 less than the width ww1 of the land part 133. The height hh2 of the vapor passage 152a in this case means the minimum dimension of the vapor passage 152a in the Z-direction. The height hh2 corresponds to the minimum distance in the Z-direction between the first-sheet inner face 110b and the second-sheet inner face 120a. The width ww1 of the land part 133 is a dimension of the land part 133 in the Y-direction, and is a dimension at a position in the Z-direction where the through-part 134 exists. The configuration mentioned above can ensure that, in the bend part BP, the gap created between the first-sheet inner face 110b and the second-sheet inner face 120a upon bending of the vapor chamber 101 along the bend line BL can be further reduced, and thus the channel cross-sectional area of the vapor passage 152a can be further reduced. This makes it possible to further increase the pressure loss for the working vapor 102a flowing through the vapor passage 152a in the bend part BP. This in turn makes it possible to further reduce back-and-forth movement of the working vapor 102a between the first region RR1 and the second region RR2 in the bend part BP, and consequently to further reduce heat transfer via the bend part BP.

According to the fourth embodiment mentioned above, as illustrated in FIG. 54, the vapor passage 152a where the bend line BL is located may have a width ww2a greater than a width ww2b of the vapor passage 152a where the bend line BL is not located. In this case, each of the widths ww2a and ww2b of the vapor passage 152a is a dimension of the vapor passage 152a in the Y-direction, and is a dimension at a position in the Z-direction where the through-part 134 exists. Each of the widths ww2a and ww2b of the vapor passage 152a corresponds to the gap between the land parts 133 that are adjacent to each other in the Y-direction. The configuration mentioned above can as well ensure that, in the bend part BP, the gap created between the first-sheet inner face 110b and the second-sheet inner face 120a upon bending of the vapor chamber 101 along the bend line BL can be further reduced, and thus the channel cross-sectional area of the vapor passage 152a can be further reduced. This makes it possible to further increase the pressure loss for the working vapor 102a flowing through the vapor passage 152a in the bend part BP. This in turn makes it possible to further reduce back-and-forth movement of the working vapor 102a between the first region RR1 and the second region RR2 in the bend part BP, and consequently to further reduce heat transfer via the bend part BP.

According to the fourth embodiment mentioned above, as illustrated in FIG. 55, the land part 133 adjacent to the vapor passage 152a where the bend line BL is located may be provided with a communicating groove 136. The communicating groove 136 provides communication between the vapor passage 152a where the bend line BL is located, and the vapor passage 152a where the bend line BL is not located. In this case, the working vapor 102a is allowed to diffuse from the vapor passage 152a that is an unbent state to the vapor passage 152a that is in a bent state. The vapor passage 152a that is in a bent state can be thus effectively utilized as a vapor passage. The communicating groove 136 can, during a period when the electronic device D is not generating heat, store the working liquid 102b due to capillary action. Although the communicating groove 136 may be disposed contiguously in the X-direction, in an alternative configuration, the communicating groove 136 may be disposed in discrete portions in the X-direction. This configuration allows the above-mentioned effect to be obtained while mitigating a decrease in the mechanical strength of the vapor chamber 101.

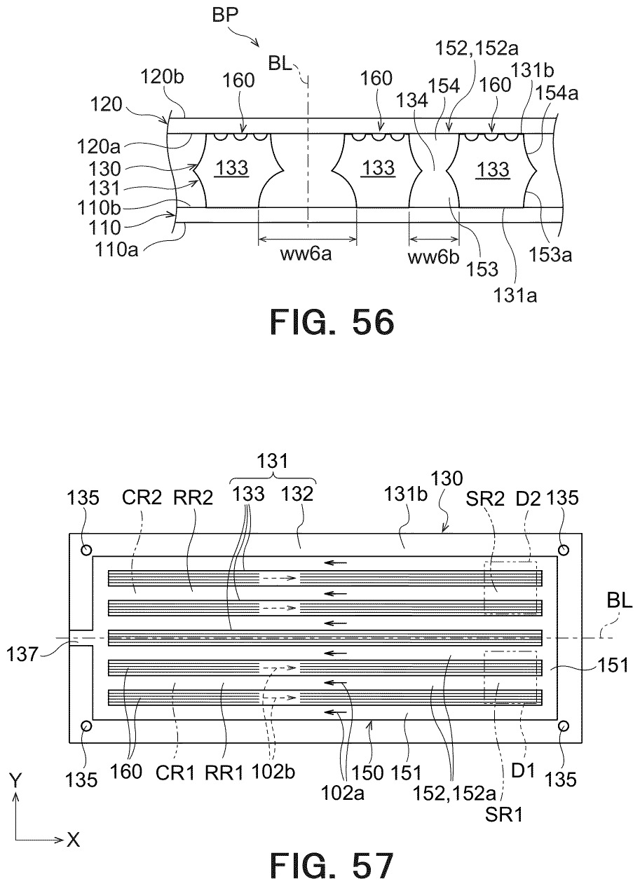

According to the fourth embodiment mentioned above, as illustrated in FIG. 56, the vapor passage 152a where the bend line BL is located may have, in the opening part thereof, a width ww6a greater than a width ww6b in the opening part of the vapor passage 152a where the bend line BL is not located. In this case, each of the widths ww6a and ww6b in the opening part of the vapor passage 152a means a dimension in the opening part of the vapor passage 152a in the Y-direction, and a dimension at the location of the first body face 131a or the second body face 131b. As illustrated in FIG. 56, the width ww6a in the opening part of the first vapor channel recess 153 provided in the vapor passage 152a where the bend line BL is located may be greater than the width ww6b in the opening part of the first vapor channel recess 153 provided in the vapor passage 152a where the bend line BL is not located. Although not illustrated, the opening part of the second vapor channel recess 154 provided in the vapor passage 152a where the bend line BL is located may have a width greater than the width in the opening part of the second vapor channel recess 154 provided in the vapor passage 152a where the bend line BL is not located. This configuration can ensure adequate channel cross-sectional area of the vapor passage 152a in the bend part BP while reducing heat transfer via the bend part BP, and consequently can mitigate an increase in the pressure loss for the working vapor 102a in the vapor passage 152a. As a result, deterioration of the heat transport capacity of the vapor chamber 101 can be reduced.

The foregoing description of the fourth embodiment is directed to the example in which the vapor chamber 101 is bent at a position where the vapor passage 152a is disposed (see FIG. 44). This, however, is not intended to be limiting. Alternatively, as illustrated in FIG. 57, the vapor chamber 101 may be bent at a position where the liquid channel part 160 is disposed.

In the example illustrated in FIG. 57, the bend line BL overlaps one of the land parts 133. The vapor chamber 101 is thus bent at a position where the liquid channel part 160 is disposed.

In this case, in the bend part BP, the liquid channel part 160 disposed in the land part 133 may be crushed, which may cause the liquid channel part 160 to decrease in channel cross-sectional area. This results in reduced back-and-forth movement of the working liquid 102b between the first region RR1 and the second region RR2.

The vapor chamber 101 is otherwise similar in configuration to that according to the fourth embodiment mentioned above.

According to the modification illustrated in FIG. 57, the vapor chamber 101 is bent at a position where the liquid channel part 160 is disposed. Consequently, the capillary force exerted by the liquid channel part 160 can be increased in the bend part BP. In particular, a bent portion of the liquid channel part 160 has a deformed cross-section, which means that the bent portion has, at some locations, a decreased thickness or decreased cross-sectional area relative to other, unbent portions. This allows for increased capillary force at such locations. As a result, the working liquid 102b that has been condensed can be quickly recovered in the bend part BP.

In a bent portion of the liquid channel part 160, the working liquid 102b tends to collect more than in other, unbent portions. Accordingly, the working liquid 102b can be distributed via the bent liquid channel part 160 to regions where shortage of the working liquid 102b tends to occur. This can reduce maldistribution of the working liquid 102b in the regions RR1 and RR2. This in turn allows for temperature equalization of the vapor chamber 101 in the regions RR1 and RR2.

According to the modification illustrated in FIG. 57, the vapor chamber 101 is bent at a position where the liquid channel part 160 is disposed. This configuration can mitigate an increase in the pressure loss for the working vapor 102a in the vapor passage 152a. This makes it possible to reduce deterioration of the overall heat transport capacity of the vapor chamber 101 while reducing heat transfer via the bend part BP. For the vapor chamber 101, it is important to place as many channels as possible within a limited space. In particular, the vapor passage 152a is a passage through which the working vapor 102a flows, that is, a passage for transporting heat. Accordingly, it is desirable to place as many such vapor passages 152a as possible. The modification illustrated in FIG. 57 can ensure that as many vapor passages 152a as possible can be provided within a limited space. The modification also allows for effective utilization of available space within the vapor chamber 101, and consequently spacing saving for the vapor chamber 101.

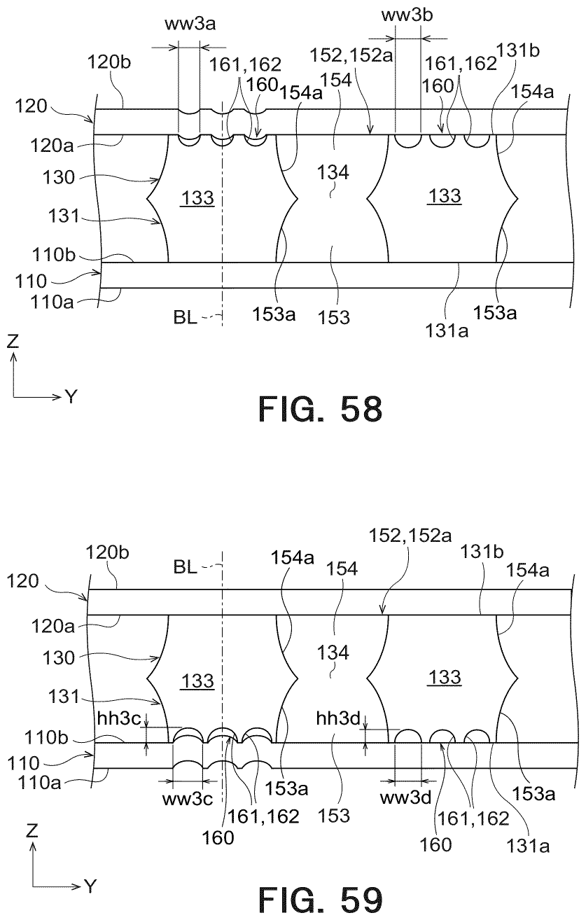

According to the modification illustrated in FIG. 57, if, as illustrated in FIG. 58, the liquid channel part 160 is disposed near the second sheet 120 located at the inner side of the bend, that is, if the liquid channel part 160 is disposed in the second body face 131b of the land part 133, the liquid-channel main flow groove 161 disposed in the land part 133 where the bend line BL is located may have a width ww3a less than a width ww3b of the liquid-channel main flow groove 161 disposed in the land part 133 where the bend line BL is not located. That is, the width ww3a of the liquid-channel main flow groove 161 in the bend part BP may be less than the width ww3b of the liquid-channel main flow groove 161 in each of the first region RR1 and the second region RR2. The same applies to the width of the liquid-channel communication groove 165. In this case, the capillary force of the liquid channel part 160 can be increased in the bend part BP. This can ensure that the working liquid 102b that has condensed is allowed to efficiently move from the vapor passage 152a to the liquid channel part 160. This can also reduce the risk that the liquid-channel main flow groove 161 and the liquid-channel communication groove 165 are crushed when the second sheet 120 is subjected to an external pressing force.

As illustrated in FIG. 58, in the bend part BP, the second sheet 120 may be recessed toward the liquid channel part 160. The amount of recessing of the second sheet 120 in the bend part BP may be greater than the amount of recessing of the second sheet 120 in each of the first region RR1 and the second region RR2. The amount of recessing of the second sheet 120 in each of the first region RR1 and the second region RR2 may be zero. In other words, in each of the first region RR1 and the second region RR2, the second sheet 120 does not have to be recessed toward the liquid channel part 160. The configuration mentioned above makes it possible to reduce, in the bend part BP, the angle formed between the second-sheet inner face 120a, and the wall face 162 of the liquid-channel main flow groove 161. The configuration mentioned above also makes it possible to reduce the angle formed between the second-sheet inner face 120a, and the wall face of the liquid-channel communication groove 165. Consequently, the capillary force exerted by the liquid channel part 160 can be increased. As a result, the working liquid 102b that has condensed can be transported smoothly toward the evaporation region SR.

According to the modification illustrated in FIG. 57, as illustrated in FIG. 59, the liquid channel part 160 may be disposed near the first sheet 110, which is located at the outer side of the bend. That is, the liquid channel part 160 may be disposed in the first body face 131a of the land part 133. In this case, as illustrated in FIG. 59, the liquid-channel main flow groove 161 disposed in the land part 133 where the bend line BL is located may have a width ww3c greater than a width ww3d of the liquid-channel main flow groove 161 disposed in the land part 133 where the bend line BL is not located. That is, the width ww3c of the liquid-channel main flow groove 161 in the bend part BP may be greater than the width ww3d of the liquid-channel main flow groove 161 in each of the first region RR1 and the second region RR2. The same applies to the width of the liquid-channel communication groove 165. The liquid-channel main flow groove 161 disposed in the land part 133 where the bend line BL is located may have a depth hh3c less than a depth hh3d of the liquid-channel main flow groove 161 disposed in the land part 133 where the bend line BL is not located. That is, the depth hh3c of the liquid-channel main flow groove 161 in the bend part BP may be greater than the depth hh3d of the liquid-channel main flow groove 161 in each of the first region RR1 and the second region RR2. The same applies to the depth of the liquid-channel communication groove 165. The configuration mentioned above makes it possible to reduce, in the bend part BP, the angle formed between the first-sheet inner face 110b, and the wall face 162 of the liquid-channel main flow groove 161. The configuration mentioned above also makes it possible to reduce the angle formed between the first-sheet inner face 110b, and the wall face of the liquid-channel communication groove 165. Consequently, the capillary force exerted by the liquid channel part 160 can be increased. As a result, the working liquid 102b that has condensed can be transported smoothly toward the evaporation region SR.

As illustrated in FIG. 59, in the bend part BP, the first sheet 110 may be recessed toward the liquid channel part 160. The amount of recessing of the first sheet 110 in the bend part BP may be greater than the amount of recessing of the first sheet 110 in each of the first region RR1 and the second region RR2. The amount of recessing of the first sheet 110 in each of the first region RR1 and the second region RR2 may be zero. In other words, in each of the first region RR1 and the second region RR2, the first sheet 110 does not have to be recessed toward the liquid channel part 160. The configuration mentioned above makes it possible to reduce, in the bend part BP, the angle formed between the first-sheet inner face 110b, and the wall face 162 of the liquid-channel main flow groove 161. The configuration mentioned above also makes it possible to reduce the angle formed between the first-sheet inner face 110b, and the wall face of the liquid-channel communication groove 165. Consequently, the capillary force exerted by the liquid channel part 160 can be increased. As a result, the working liquid 102b that has condensed can be transported smoothly toward the evaporation region SR.

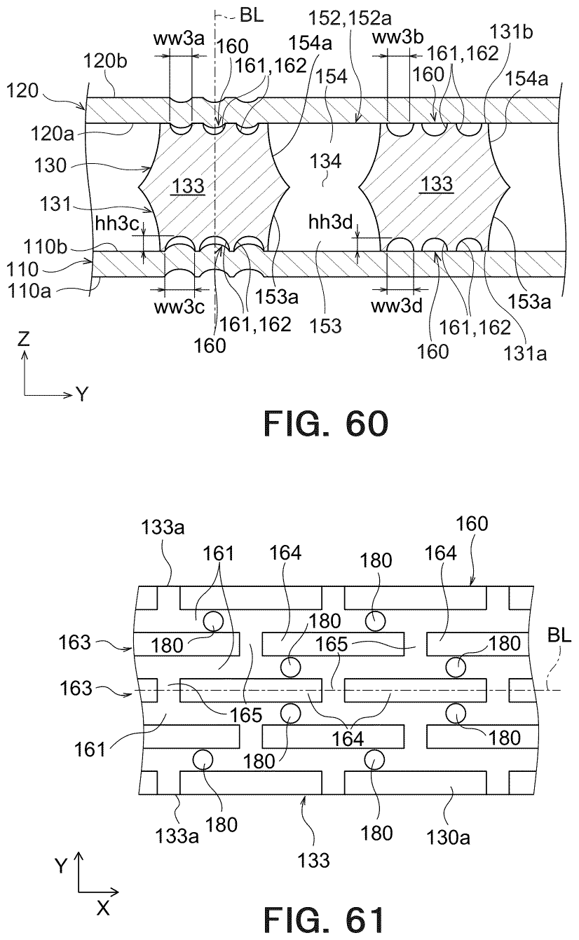

According to the modification illustrated in FIG. 57, as illustrated in FIG. 60, the second body face 131b of the land part 133 may be provided with the liquid channel part 160, and also the first body face 131a of the land part 133 may be provided with the liquid channel part 160. In this case, as with the example illustrated in FIG. 58, the width ww3a of the liquid-channel main flow groove 161 may be less than the width ww3b of the liquid-channel main flow groove 161 as illustrated in FIG. 60. The same applies to the width of the liquid-channel communication groove 165. In the bend part BP, the second sheet 120 may be recessed toward the liquid channel part 160. Further, as with the example illustrated in FIG. 59, the width ww3c of the liquid-channel main flow groove 161 may be greater than the width ww3d of the liquid-channel main flow groove 161. The same applies to the width of the liquid-channel communication groove 165. The depth hh3c of the liquid-channel main flow groove 161 may be less than the depth hh3d of the liquid-channel main flow groove 161. The same applies to the depth of the liquid-channel communication groove 165. In the bend part BP, the first sheet 110 may be recessed toward the liquid channel part 160. In this case, both the effect of the example illustrated in FIG. 58, and the effect of the example illustrated in FIG. 59 can be obtained. In the example illustrated in FIG. 60, the liquid channel part 160 disposed in the first body face 131a may have a channel cross-sectional area greater than the channel cross-sectional area of the liquid channel part 160 disposed in the second body face 131b. The liquid channel part 160 disposed in the first body face 131a may, during a period when the electronic device D is not generating heat, function as a liquid reservoir. In this case, due to the increased capillary action of the liquid channel part 160, the working liquid 102b can be easily drawn into the liquid channel part 160 that is disposed in the first body face 131a and that serves as a liquid reservoir.

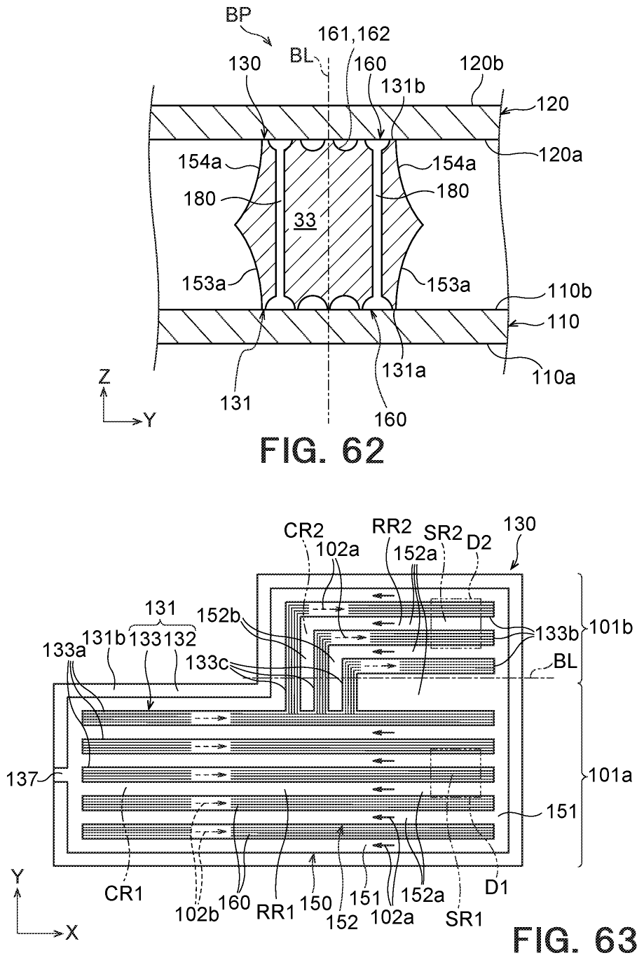

As illustrated in FIGS. 61 and 62, if the liquid channel part 160 is disposed in the second body face 131b of the land part 133, and the liquid channel part 160 is disposed in the first body face 131a of the land part 133, a communicating path 180 may be provided to provide communication between the liquid channel part 160 disposed in the second body face 131b and the liquid channel part 160 disposed in the second body face 131b. As illustrated in FIG. 62, the communicating path 180 may extend straight in the Z-direction, and penetrate the land part 133. The communicating path 180 may be positioned at any location in the land part 133. As illustrated in FIG. 61, in plan view, the communicating path 180 may be positioned to overlap the liquid-channel main flow groove 161. The communicating path 180 may provide connection between the liquid-channel main flow groove 161 disposed in the second body face 131b, and the liquid-channel main flow groove 161 disposed in the second body face 131b. Although not illustrated, in plan view, the communicating path 180 may be positioned to overlap the liquid-channel communication groove 165. The communicating path 180 may provide connection between the liquid-channel communication groove 165 disposed in the second body face 131b, and the liquid-channel communication groove 165 disposed in the second body face 131b. The presence of the communicating path 180 can for instance ensure that, even when the working liquid 102b ceases to flow smoothly at a location in one liquid channel part 160 other than where the bend line BL is present, the working liquid 102b is allowed to pass through the communicating path 180 to the other liquid channel part 160. The working liquid 102b can be thus transported smoothly toward the evaporation region SR. Further, stagnation of the working liquid 102b in the bend part BP can be reduced. Consequently, a rise in the temperature of the bend part BP can be mitigated. This can mitigate a decrease in the reduction of heat transfer via the bend part BP.

The foregoing description of the fourth embodiment is directed to the example in which the vapor chamber 101 has a rectangular shape in plan view (see FIGS. 40 and 44). This, however, is not intended to be limiting. The vapor chamber 101 may have any shape in plan view. For example, as illustrated in FIG. 63, the vapor chamber 101 may be shaped like a combination of two rectangles in plan view.

In the example illustrated in FIG. 63, the vapor chamber 101 includes a first part 101a and a second part 101b each having a rectangular shape. The second part 101b has an area in plan view less than the area of the first part 101a in plan view. The second part 101b projects from a portion (right-half portion) of the first part 101a that is located at the positive side in the X-direction (the right side in FIG. 63), toward the positive side in the Y-direction (the upper side in FIG. 63). The frame part 132 is disposed along the perimeter of a region that is defined by the first part 101a and the second part 101b. A plurality of land parts 133 are disposed inside the frame part 132.

The land parts 133 include a plurality of first land parts 133a, a plurality of second land parts 133b, and a plurality of third land parts 133c.

The first land parts 133a are located in the first part 101a. The first land parts 133a extend in the X-direction, and are disposed in spaced parallel relation to each other in the Y-direction. In the example illustrated in FIG. 63, five first land parts 133a are provided.

The second land parts 133b are located in the second part 101b. The second land parts 133b extend in the X-direction, and are disposed in spaced parallel relation to each other in the Y-direction. In the example illustrated in FIG. 63, three second land parts 133b are provided. The second land part 133b has a dimension in the X-direction less than the dimension of the first land part 133a in the X-direction. As illustrated in FIG. 63, each second land part 133b may have a different dimension in the X-direction.

Each third land part 133c connects the first land part 133a and the second land part 133b to each other. The third land parts 133c extend in the Y-direction, and are disposed in spaced parallel relation to each other in the X-direction. In the example illustrated in FIG. 63, three third land parts 133c are provided. As illustrated in FIG. 63, each third land part 133c may be connected to an edge of the corresponding second land part 133b that is located at the negative side in the X-direction (the left side in FIG. 63). Each third land part 133c may be connected to one of the first land parts 133a that is located on the most positive side in the Y-direction (the upper side in FIG. 63).

The first land part 133a, the second land part 133b, and the third land part 133c are each provided with the liquid channel part 160. The liquid channel part 160 of the first land part 133a communicates with the liquid channel part 160 of the third land part 133c, and the liquid channel part 160 of the third land part 133c communicates with the liquid channel part 160 of the second land part 133b.

The second vapor passage 152 includes the vapor passage 152a extending in the first direction, and a vapor passage 152b extending in the second direction orthogonal to the first direction. In the illustrated example, the first direction is the X-direction. That is, the vapor passage 152a extends in the X-direction, and the vapor passage 152b extends in the Y-direction. The vapor passage 152a is disposed between the first land parts 133a, between the second land parts 133b, and between the first land part 133a and the second land part 133b. The vapor passage 152b is disposed between the third land parts 133c.

In the example illustrated in FIG. 63, the bend line BL is disposed at the boundary between the first part 101a and the second part 101b of the vapor chamber 101. Accordingly, the first region RR1 is located in the first part 101a of the vapor chamber 101, and the second region RR2 is located in the second part 101b of the vapor chamber 101.

In the example illustrated in FIG. 63, the first evaporation region SR1 is disposed in the first region RR1 of the vapor chamber 101, and the second evaporation region SR2 is disposed in the second region RR2 of the vapor chamber 101. More specifically, the first evaporation region SR1 is provided at the positive side in the X-direction of the first region RR1 of the vapor chamber 101 (the right side in FIG. 63). That is, the first device D1 is mounted at the positive side in the X-direction of the first region RR1. The second evaporation region SR2 is provided at the positive side in the X-direction of the second region RR2 of the vapor chamber 101. That is, the second device D2 is mounted at the positive side in the X-direction of the second region RR2. The first condensation region CR1 is provided at the negative side in the X-direction of the first region RR1 of the vapor chamber 101 (the left side in FIG. 63). The second condensation region CR2 is provided at the negative side in the X-direction of the second region RR2 of the vapor chamber 101.

In the example illustrated in FIG. 63, the bend line BL extends in a direction parallel to the first direction in which the vapor passage 152a extends. The vapor chamber 101 is thus bent in the direction parallel to the first direction.

In the example illustrated in FIG. 63, the vapor chamber 101 is bent at a position where the vapor passage 152a is disposed. That is, the vapor chamber 101 is bent along the vapor passage 152a. The vapor chamber 101 is otherwise similar in configuration to that according to the fourth embodiment mentioned above.

According to the modification illustrated in FIG. 63, the vapor chamber 101 is bent at a position where the vapor passage 152a is disposed. This makes it possible to increase the pressure loss for the working vapor 102a flowing through the vapor passage 152a in the bend part BP. This in turn makes it possible to reduce back-and-forth movement of the working vapor 102a between the first region RR1 and the second region RR2 in the bend part BP. As a result, heat transfer via the bend part BP can be further reduced.

The modification illustrated in FIG. 63 makes it possible to reduce, but still allow, back-and-forth movement of the working vapor 102a between the first region RR1 and the second region RR2. Consequently, for example, heat from the second device D2 can be transferred also to the first region RR1, so that the first condensation region CR1 can serve as a condensation region for the working vapor 102a flowing from the second evaporation region SR2. This allows for an efficient heat dissipation design, which can lead to space saving for the vapor chamber 101.

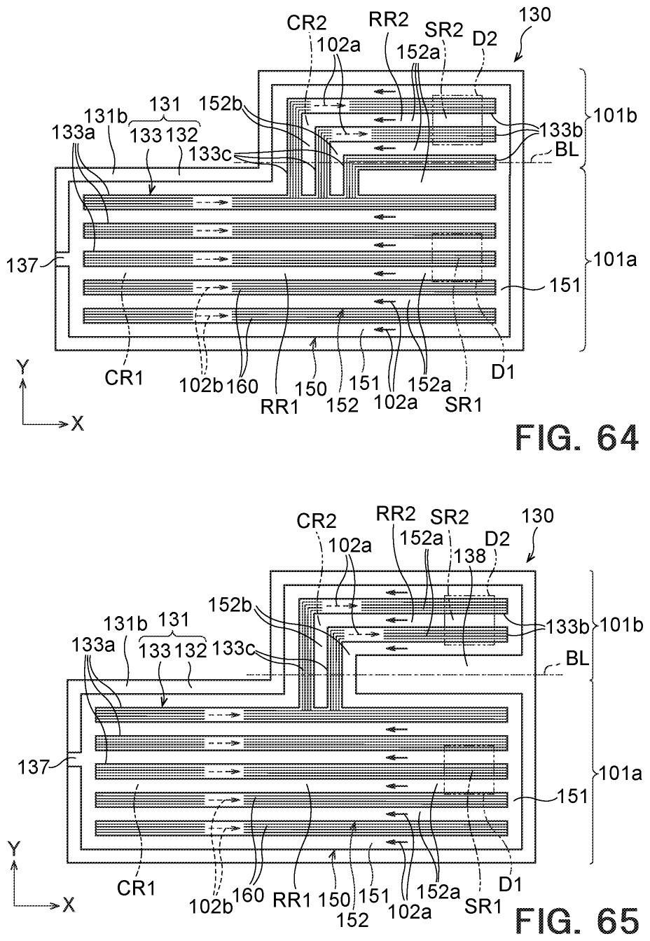

The foregoing description of the modification illustrated in FIG. 63 is directed to the example in which the vapor chamber 101 is bent at a position where the vapor passage 152a is disposed. This, however, is not intended to be limiting. Alternatively, as illustrated in FIG. 64, the vapor chamber 101 may be bent at a position where the liquid channel part 160 is disposed.

In the example illustrated in FIG. 64, one of the land parts 133 is disposed at the boundary between the first part 101a and the second part 101b. The one land part 133 lies on the bend line BL. The vapor chamber 101 is thus bent at a position where the liquid channel part 160 is disposed.

In this case, in the bend part BP, the liquid channel part 160 disposed in the land part 133 may be crushed and thus decrease in channel cross-sectional area. This results in reduced back-and-forth movement of the working liquid 102b between the first region RR1 and the second region RR2. The vapor chamber 101 is otherwise similar in configuration to that according to the modification illustrated in FIG. 63.

According to the modification illustrated in FIG. 64, the vapor chamber 101 is bent at a position where the liquid channel part 160 is disposed. Consequently, the capillary force exerted by the liquid channel part 160 can be increased in the bend part BP. In particular, a bent portion of the liquid channel part 160 has a deformed cross-section, which means that the bent portion has, at some locations, a decreased thickness or decreased cross-sectional area relative to other, unbent portions. This allows for increased capillary force at such locations. As a result, the working liquid 102b that has been condensed can be quickly recovered in the bend part BP.

In a bent portion of the liquid channel part 160, the working liquid 102b tends to collect more than in other, unbent portions. Accordingly, the working liquid 102b can be distributed via the bent liquid channel part 160 to regions where shortage of the working liquid 102b tends to occur. This can reduce maldistribution of the working liquid 102b in the regions RR1 and RR2. This in turn allows for temperature equalization of the vapor chamber 101 in the regions RR1 and RR2.

According to the modification illustrated in FIG. 64, the vapor chamber 101 is bent at a position where the liquid channel part 160 is disposed. This configuration can mitigate an increase in the pressure loss for the working vapor 102a in the vapor passage 152a. The above-mentioned configuration thus makes it possible to reduce deterioration of the overall heat transport capacity of the vapor chamber 101 while reducing heat transfer via the bend part BP. For the vapor chamber 101, it is important to place as many channels as possible within a limited space. In particular, the vapor passage 152a is a passage through which the working vapor 102a flows, that is, a passage for transporting heat. Accordingly, it is desirable to place as many such vapor passages 152a as possible. The modification illustrated in FIG. 64 can ensure that as many vapor passages 152a as possible can be provided within a limited space. The modification also allows for effective utilization of available space within the vapor chamber 101, and consequently spacing saving for the vapor chamber 101.

The modification illustrated in FIG. 64 makes it possible to reduce, but still allows, back-and-forth movement of the working vapor 102a between the first region RR1 and the second region RR2. Consequently, for example, heat from the second device D2 can be transferred also to the first region RR1, so that the first condensation region CR1 can serve as a condensation region for the working vapor 102a flowing from the second evaporation region SR2. This allows for an efficient heat dissipation design, which can lead to space saving for the vapor chamber 101.

The foregoing description of the modification illustrated in FIG. 63 is directed to the example in which the vapor chamber 101 is bent at a position where the vapor passage 152a is disposed. This, however, is not intended to be limiting. Alternatively, as illustrated in FIG. 65, the vapor chamber 101 may be bent at a position where a reinforcement part 138 is disposed.

In the example illustrated in FIG. 65, the body sheet 130 includes the reinforcement part 138 extending inward from the frame part 132. In the reinforcement part 138, neither the vapor channel part 150 nor the liquid channel part 160 is disposed. The reinforcement part 138 is a part where the material of the body sheet 130 remains without being etched away in an etching step. The frame part 132 and the reinforcement part 138 may be provided contiguously. The first body face 131a in the frame part 132 of the body sheet 130, and the first body face 131a in the reinforcement part 138 of the body sheet 130 may lie in the same plane. The second body face 131b in the frame part 132 of the body sheet 130, and the second body face 131b in the reinforcement part 138 of the body sheet 130 may lie in the same plane. As illustrated in FIG. 65, the reinforcement part 138 may have a shape in plan view that is an elongated rectangle extending in the X-direction. The reinforcement part 138 may project from a portion of the frame part 132 that is located at the positive side in the X-direction (the right side in FIG. 65), toward the negative side in the X-direction (the left side in FIG. 65). The reinforcement part 138 may be disposed between the first land part 133a and the second land part 133b.

In the example illustrated in FIG. 65, the bend line BL overlaps the reinforcement part 138. The vapor chamber 101 is thus bent at a position where the reinforcement part 138 is disposed.

The vapor chamber 101 is otherwise similar in configuration to that according to the modification illustrated in FIG. 63.

According to the modification illustrated in FIG. 65, the vapor chamber 101 is bent at a position where the reinforcement part 138 is disposed. Consequently, in the bend part BP, the presence of the reinforcement part 138 can further reduce back-and-forth movement of the working vapor 102a and the working liquid 102b between the first region RR1 and the second region RR2. Heat transfer in the reinforcement part 138 is effected mainly through heat transfer by the material of the body sheet 130. If, for instance, the body sheet 130 is made of copper, the body sheet 130 has a thermal conductivity of about 400 W/(m·K), whereas the vapor chamber 101 can be expected to have an equivalent thermal conductivity that is ten times or more the above-mentioned thermal conductivity. This means that the reinforcement part 138 has a relatively low thermal conductivity. As a result, for the vapor chamber 101 in its bent state, heat transfer via the bend part BP can be further reduced.

According to the modification illustrated in FIG. 65, the presence of the reinforcement part 138 allows for enhanced mechanical strength of the vapor chamber 101 in the bend part BP. Although the vapor chamber 101 is hollow inside, the presence of the reinforcement part 138 allows a large bulk portion to be left inside the vapor chamber 101. This can lead to enhanced mechanical strength of the vapor chamber 101.

According to the modification illustrated in FIG. 65, the vapor chamber 101 is bent at a position where the reinforcement part 138 is disposed. As a result, deformation of, for example, the vapor passage 152a or the liquid channel part 160 can be reduced. This makes it possible to reduce deterioration of the heat transport capacity of the vapor chamber 101 while reducing heat transfer via the bend part BP.

The modification illustrated in FIG. 65 makes it possible to reduce, but still allow, back-and-forth movement of the working vapor 102a between the first region RR1 and the second region RR2. Consequently, for example, heat from the second device D2 can be transferred also to the first region RR1, so that the first condensation region CR1 can serve as a condensation region for the working vapor 102a flowing from the second evaporation region SR2. This allows for an efficient heat dissipation design, which can lead to space saving for the vapor chamber 101.

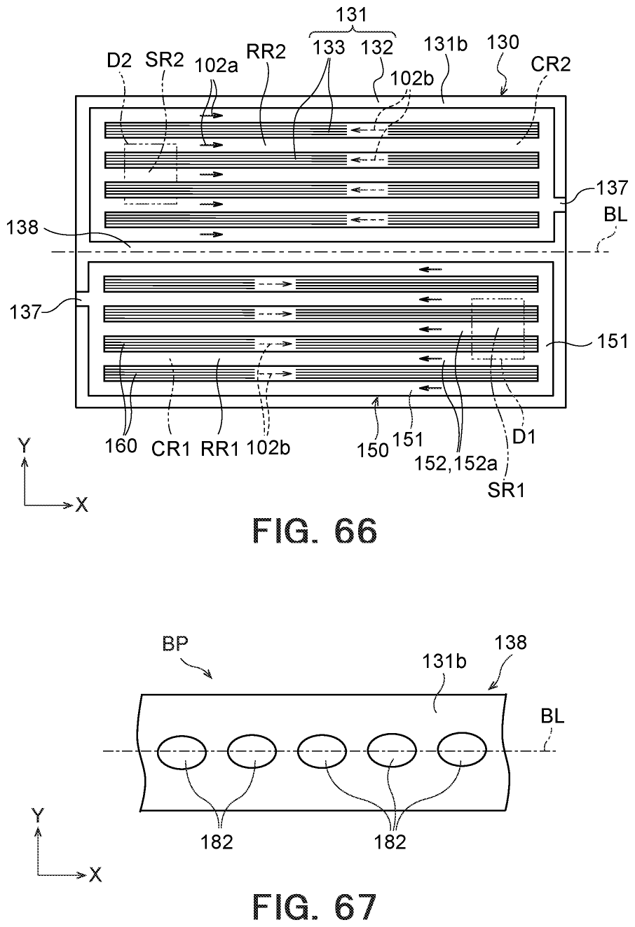

The foregoing description of the modification illustrated in FIG. 65 is directed to the example in which the vapor chamber 101 is shaped like a combination of two rectangles in plan view. This, however, is not intended to be limiting. The vapor chamber 101 may have any shape in plan view. For example, as illustrated in FIG. 66, the vapor chamber 101 may have a rectangular shape in plan view. In this case, as illustrated in FIG. 66, the body sheet 130 may include the reinforcement part 138, and the bend line BL may overlap the reinforcement part 138. That is, the vapor chamber 101 may be bent at a position where the reinforcement part 138 is disposed.

In the example illustrated in FIG. 66, the reinforcement part 138 is located between the first region RR1 and the second region RR2. As illustrated in FIG. 66, the reinforcement part 138 may have a shape in plan view that is an elongated rectangle extending in the X-direction. The reinforcement part 138 may extend from a portion of the frame part 132 that is located at the positive side in the X-direction (the right side in FIG. 65), to a portion of the frame part 132 that is located at the negative side in the X-direction (the left side in FIG. 65). In the example illustrated in FIG. 66, the first region RR1 and the second region RR2 are separated from each other by the reinforcement part 138. That is, due to the presence of the reinforcement part 138, the working vapor 102a and the working liquid 102b do not move back and forth between the first region RR1 and the second region RR2. The regions RR1 and RR2 are allowed to function as if each of these regions is an independent vapor chamber.

According to the modification illustrated in FIG. 66, the first region RR1 and the second region RR2 are separated from each other by the reinforcement part 138. This configuration can further reduce heat transfer via the bend part BP. Further, the presence of the bend part BP as mentioned above allows for enhanced mechanical strength of the vapor chamber 101. Further, a single vapor chamber 101 is allowed to function as a plurality of vapor chambers 101. This allows for reduced cost of manufacturing the vapor chamber 101 in comparison to the cost of manufacturing a plurality of vapor chambers 101.

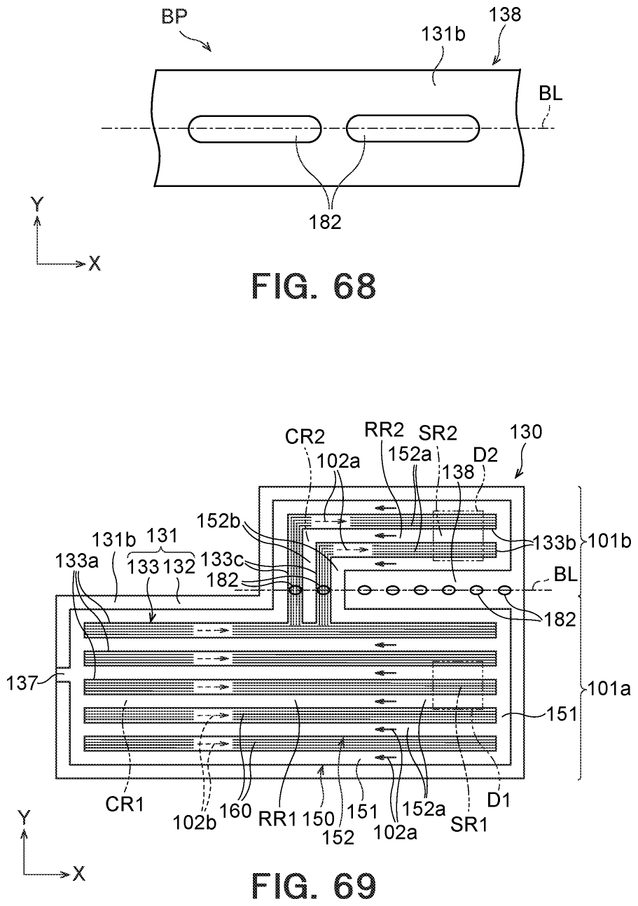

According to the modifications illustrated in FIGS. 65 and 66, in the bend part BP, a body-face recess 182 may be provided in the first body face 131a or the second body face 131b of the reinforcement part 138. In the examples illustrated in FIGS. 67 and 68, the body-face recess 182 is provided in the second body face 131b of the reinforcement part 138.

The body-face recess 182 may be in the form of a recess provided in the second body face 131b of the reinforcement part 138. The body-face recess 182 may have any shape in plan view. For example, as illustrated in FIG. 67, the body-face recess 182 may be in the form of a minute hole having the shape of a circle (e.g., a perfect circle or an ellipse) in plan view. For example, as illustrated in FIG. 68, the body-face recess 182 may be in the form of a groove extending in the Y-direction. As illustrated in FIGS. 67 and 68, a plurality of body-face recesses 182 may be arranged side by side in the X-direction. As illustrated in FIGS. 67 and 68, the body-face recesses 182 overlap the bend line BL in plan view. That is, the body-face recesses 182 are disposed along the bend line BL. In other words, each body-face recess 182 is positioned to overlap the bend line BL in plan view.

The body-face recess 182 may be formed through etching of the body sheet 130 in the above-mentioned etching step of the method for manufacturing the vapor chamber 101. With the vapor chamber 101 seen in plan view, the body-face recess 182 is visible also from outside the vapor chamber 101 through the first sheet 110 or the second sheet 120. The body-face recess 182 thus serves as a visual indication of where to bend the vapor chamber 101 in the above-mentioned bending step of the method for manufacturing the vapor chamber 101. That is, in the bending step, bending the vapor chamber 101 along the body-face recess 182 makes it possible to obtain the vapor chamber 101 bent along the bend line BL.

According to the modification illustrated in FIGS. 67 and 68, bending the vapor chamber 101 along the body-face recess 182 makes it possible to obtain the vapor chamber 101 that has been bent along the bend line BL. This allows for improved ease of bending operation. Further, the presence of the body-face recess 182 in the form of a minute hole or a groove can facilitate bending of the vapor chamber 1. This can facilitate manufacture of the vapor chamber 101 that is in a bent state. In particular, if the body-face recess 182 is provided in the second body face 131b of the reinforcement part 138, the vapor chamber 101 can be easily bent in such a way that the second sheet 120 is located at the inner side of the bend.

The body-face recess 182 may be provided in the first body face 131a of the reinforcement part 138. In this case, the vapor chamber 101 can be easily bent in such a way that the first sheet 110 is located at the inner side of the bend. The body-face recess 182 may be provided in both the first body face 131a and the second body face 131b of the reinforcement part 138. In this case, the vapor chamber 101 can be easily bent to either side.

According to the modification illustrated in FIG. 65, in the bend part BP, the body-face recess 182 may be provided at a position in the land part 133 where no liquid channel part 160 is disposed. In one example, if the liquid channel part 160 is disposed in the second body face 131b of the land part 133, the body-face recess 182 may be provided in the first body face 131a of the land part 133. In another example, if the liquid channel part 160 is disposed in the first body face 131a of the land part 133, the body-face recess 182 mat be provided in the second body face 131b of the land part 133. In another example, if the liquid channel part 160 is disposed in both the first body face 131a and the second body face 131b of the land part 133, the body-face recess 182 may be provided at any position in the first body face 131a or the second body face 131b of the land part 133 where no liquid channel part 160 is disposed. The body-face recess 182 may be provided in both the first body face 131a and the second body face 131b of the land part 133. As illustrated in FIG. 69, the body-face recess 182 may be provided in the reinforcement part 138, and the body-face recess 182 may be provided also in the land part 133. A plurality of body-face recesses 182 may be arranged side by side in the X-direction. Each body-face recess 182 may overlap the BL in plan view.

According to the modification illustrated in FIG. 69, the body-face recess 182 is provided also in the land part 133. This can further improve the ease of bending operation. Bending of the vapor chamber 101 can be further facilitated. This can facilitate manufacture of the vapor chamber 101 that is in a bent state.

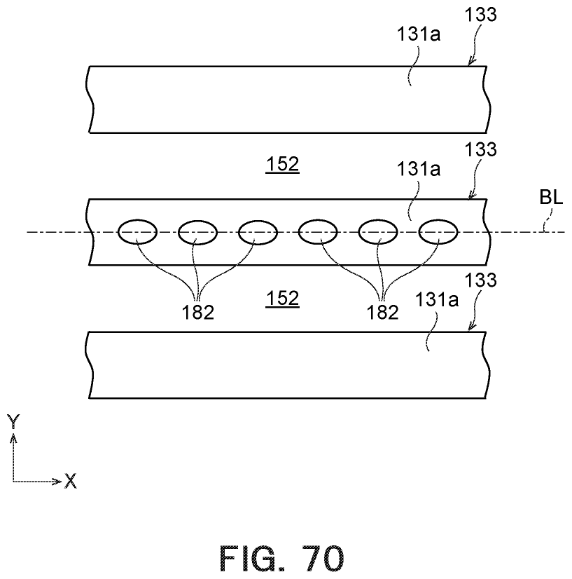

Even if the vapor chamber 101 does not include the reinforcement part 138, the land part 133 may be provided with the body-face recess 182. If, as with the modification illustrated in FIG. 57, the vapor chamber 101 is bent at a position where the liquid channel part 160 is disposed, and the second body face 131b of the land part 133 is provided with the liquid channel part 160, the first body face 131a of the land part 133 may be provided with the body-face recess 182 as illustrated in FIG. 70. As illustrated in FIG. 70, a plurality of body-face recesses 182 may be arranged side by side in the X-direction. Each body-face recess 182 may overlap the BL in plan view.

According to the modification illustrated in FIG. 70 as well, the body-face recess 182 is provided in the land part 133. This can further improve the ease of bending operation. Bending of the vapor chamber 101 can be facilitated. This can facilitate manufacture of the vapor chamber 101 that is in a bent state.

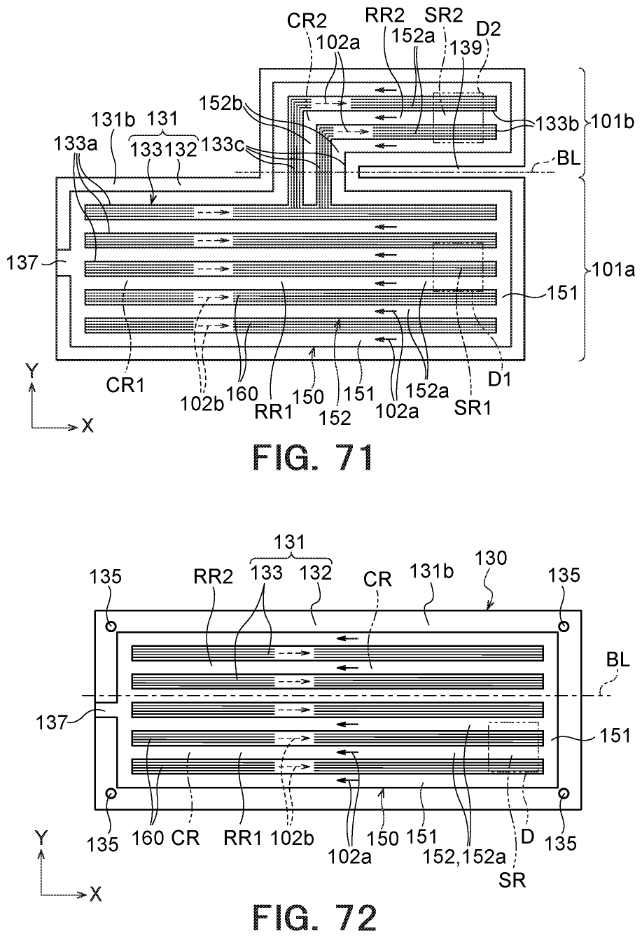

The modification illustrated in FIG. 63 mentioned above is directed to the example in which the vapor chamber 101 is bent at a position where the vapor passage 152a is disposed. This, however, is not intended to be limiting. Alternatively, as illustrated in FIG. 71, the vapor chamber 101 may be bent at a position where a space part 139 is disposed.

In the example illustrated in FIG. 71, the body sheet 130 includes the space part 139 disposed between the first region RR1 and the second region RR2. In the space part 139, neither the vapor channel part 150 nor the liquid channel part 160 is disposed. The space part 139 is contiguous with a space external to the vapor chamber 101, and constitutes a portion of the space external to the vapor chamber 101. As illustrated in FIG. 71, the space part 139 may have a shape in plan view that is an elongated rectangle extending in the X-direction. The space part 139 may be disposed between the first land part 133a and the second land part 133b. In other words, the space part 139 provided between the first land part 133a and the second land part 133b may be in the form of a recess extending from a portion of the frame part 132 located at the positive side in the X-direction (the right side in FIG. 71) toward the negative side in the X-direction (the left side in FIG. 71).

In the example illustrated in FIG. 71, the bend line BL (or its extension) overlaps the space part 139. The vapor chamber 101 is thus bent at a position where the space part 139 is disposed.

The vapor chamber 101 is otherwise similar in configuration to that according to the modification illustrated in FIG. 63.

According to the modification illustrated in FIG. 71, the vapor chamber 101 is bent at a position where the space part 139 is disposed. Consequently, in the bend part BP, the presence of the space part 139 can further reduce back-and-forth movement of the working vapor 102a and the working liquid 102b between the first region RR1 and the second region RR2. As a result, for the vapor chamber 101 in its bent state, heat transfer via the bend part BP can be further reduced.

According to the modification illustrated in FIG. 71, the vapor chamber 101 is bent at a position where the space part 139 is disposed. The vapor chamber 101 can be thus bent easily when the vapor chamber 101 is to be bent in the bending step. This can facilitate manufacture of the vapor chamber 101 that is in a bent state.

According to the modification illustrated in FIG. 71, the vapor chamber 101 is bent at a position where the space part 139 is disposed. Consequently, deformation of, for example, the vapor passage 152a or the liquid channel part 160 can be reduced. This makes it possible to reduce deterioration of the heat transport capacity of the vapor chamber 101 while reducing heat transfer via the bend part BP.

According to the modification illustrated in FIG. 71, another component may be disposed in the space part 139. This allows for effective utilization of available space within the housing H. In one such example, a protrusion to be used for positioning of the vapor chamber 101 may be disposed in the space part 139. This can facilitate positioning in placing the vapor chamber 101 within the housing H. In another such example, the wiring for, for example, a device can be passed through the space part 139. This allows for reduced length of the wiring, and consequently reduced signal loss.

The modification illustrated in FIG. 71 makes it possible to reduce, but still allow, back-and-forth movement of the working vapor 102a between the first region RR1 and the second region RR2. Consequently, for example, heat from the second device D2 can be transferred also to the first region RR1, so that the first condensation region CR1 can serve as a condensation region for the working vapor 102a flowing from the second evaporation region SR2. This allows for an efficient heat dissipation design, which can lead to space saving for the vapor chamber 101.

The foregoing description of the fourth embodiment is directed to the example in which the first evaporation region SR1 is disposed in the first region RR1 of the vapor chamber 101, and the second evaporation region SR2 is disposed in the second region RR2 of the vapor chamber 101 (see FIGS. 40 and 44). This, however, is not intended to be limiting. The evaporation region SR may be disposed in one of the first region RR1 and the second region RR2.

In the example in FIG. 72, the evaporation region SR is disposed in the first region RR1, and the evaporation region SR is not disposed in the second region RR2. More specifically, the evaporation region SR is provided at the positive side in the X-direction of the first region RR1 of the vapor chamber 101 (the right side in FIG. 72). That is, the device D is mounted at the positive side in the X-direction of the first region RR1. The condensation region CR is provided around the evaporation region SR. More specifically, the condensation region CR is provided at the negative side in the X-direction of the first region RR1 of the vapor chamber 101 (the left side in FIG. 72). The condensation region CR is provided in the second region RR2 of the vapor chamber 101.

The vapor chamber 101 is otherwise similar in configuration to that according to the fourth embodiment mentioned above.

According to the modification illustrated in FIG. 72, the evaporation region SR is disposed in the first region RR1, and the evaporation region SR is not disposed in the second region RR2. Such a configuration can as well reduce back-and-forth movement of the working vapor 2a between the first region RR1 and the second region RR2. As a result, for the vapor chamber 101 in its bent state, heat transfer via the bend part BP can be reduced.

The modification illustrated in FIG. 72 makes it possible to reduce transfer of heat from the first region RR1 to the second region RR2, and consequently to mitigate a temperature rise in the second region RR2. This can for instance reduce the risk that, when the housing component Ha mounted to the second region RR2 is located near a grip part of, for example, a mobile terminal, heat from the device D is transferred to the housing component Ha and causes the grip part to rise in temperature.

The modification illustrated in FIG. 63 mentioned above is directed to the example in which the first evaporation region SR1 is disposed in the first region RR1 of the vapor chamber 101, and the second evaporation region SR2 is disposed in the second region RR2 of the vapor chamber 101. This, however, is not intended to be limiting. Alternatively, as with the modification illustrated in FIG. 72, the evaporation region SR may be disposed in one of the first region RR1 and the second region RR2.

In an example illustrated in FIG. 73, the evaporation region SR is disposed in the first region RR1, and the evaporation region SR is not disposed in the second region RR2. More specifically, the evaporation region SR is provided at the negative side in the X-direction of the first region RR1 of the vapor chamber 101 (the left side in FIG. 73). That is, the device D is mounted at the negative side in the X-direction of the first region RR1. The condensation region CR is provided around the evaporation region SR. More specifically, the condensation region CR is provided at the positive side in the X-direction of the first region RR1 of the vapor chamber 101 (the right side in FIG. 73). The condensation region CR is provided in the second region RR2 of the vapor chamber 101.

The vapor chamber 101 is otherwise similar in configuration to that according to the modification illustrated in FIG. 63.

According to the modification illustrated in FIG. 73, the evaporation region SR is disposed in the first region RR1, and the evaporation region SR is not disposed in the second region RR2. Such a configuration can as well reduce back-and-forth movement of the working vapor 102a between the first region RR1 and the second region RR2. As a result, for the vapor chamber 101 in its bent state, heat transfer via the bend part BP can be reduced.

The modification illustrated in FIG. 73 makes it possible to reduce transfer of heat from the first region RR1 to the second region RR2, and consequently to mitigate a temperature rise in the second region RR2. This can for instance reduce the risk that, when the housing component Ha mounted to the second region RR2 is located near a grip part of, for example, a mobile terminal, heat from the device D is transferred to the housing component Ha and causes the grip part to rise in temperature.

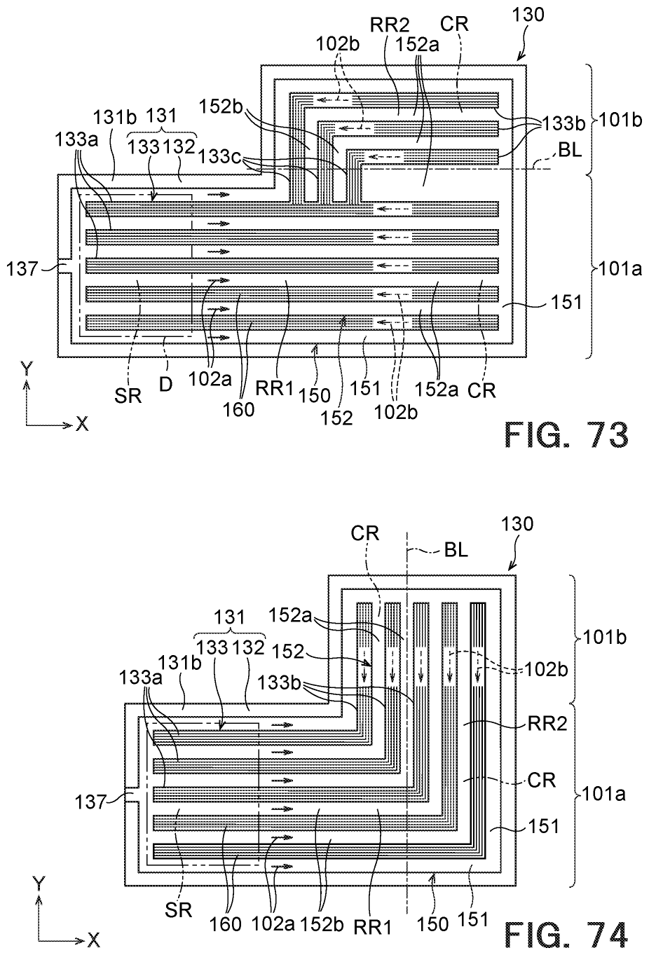

The modification illustrated in FIG. 73 mentioned above is directed to an example in which a plurality of land parts 133 include a plurality of first land parts 133a, a plurality of second land parts 133b, and a plurality of third land parts 133c. This, however, is not intended to be limiting. Such a plurality of land parts 133 may be of any configuration and arrangement. For example, as illustrated in FIG. 74, a plurality of land parts 133 may include a plurality of first land parts 133a extending in the X-direction, and a plurality of second land parts 133b extending in the Y-direction.

In the example illustrated in FIG. 74, a plurality of land parts 133 include a plurality of first land parts 133a, and a plurality of second land parts 133b.

The first land parts 133a are located in the first part 101a. The first land parts 133a extend in the X-direction. The first land parts 133a each extend from a position located at the negative side in the X-direction of the first part 101a (the left side in FIG. 74), toward the positive side in the X-direction (the right side in FIG. 74). The first land parts 133a are disposed in spaced parallel relation to each other in the Y-direction. In the example illustrated in FIG. 74, five first land parts 133a are provided. As illustrated in FIG. 74, each first land part 133a may have a different dimension in the X-direction.

Although the second land parts 133b are located mainly in the second part 101b, the second land parts 133b also extend over to the first part 101a. The second land parts 133b extend in the Y-direction. The second land parts 133b each extend from a position located at the positive side in the Y-direction of the second part 101b (the upper side in FIG. 74), toward the negative side in the Y-direction (the lower side in FIG. 74). The second land parts 133b are disposed in spaced parallel relation to each other in the X-direction. In the example illustrated in FIG. 74, five second land parts 133b are provided. As illustrated in FIG. 74, each second land part 133b may have a different dimension in the Y-direction.

In the example illustrated in FIG. 74, each second land part 133b is connected to the corresponding first land part 133a. More specifically, each second land part 133b is connected at its edge located at the negative side in the Y-direction (the lower side in FIG. 74) to an edge of the corresponding first land part 133a that is located at the positive side in the X-direction (the right side in FIG. 74). Consequently, the first land part 133a and the second land part 133b define the land part 133 having an L-shape in plan view.

The first land part 133a and the second land part 133b are each provided with the liquid channel part 160. The liquid channel part 160 in the first land part 133a communicates with the liquid channel part 160 in the second land part 133b.

The second vapor passage 152 includes the vapor passage 152a extending in the first direction, and the vapor passage 152b extending in the second direction orthogonal to the first direction. In the illustrated example, the first direction is the Y-direction. That is, the vapor passage 152a extends in the Y-direction, and the vapor passage 152b extends in the X-direction. The vapor passage 152a is disposed between the second land parts 133b. The vapor passage 152b is disposed between the first land parts 133a.

In the example illustrated in FIG. 74, the bend line BL is provided across the first part 101a and the second part 101b. The bend line BL extends in a direction parallel to the first direction in which the vapor passage 152a extends. The vapor chamber 101 is thus bent in a direction parallel to the first direction.

In the example illustrated in FIG. 74, the bend line BL overlaps the vapor passage 152a disposed between the second land parts 133b that are adjacent to each other. The vapor chamber 101 is thus bent at a position where the vapor passage 152a is disposed. That is, the vapor chamber 101 is bent along the vapor passage 152a.

The vapor chamber 101 is otherwise similar in configuration to that according to the modification illustrated in FIG. 73.

According to the modification illustrated in FIG. 74 as well, the vapor chamber 101 is bent at a position where the vapor passage 152a is disposed. This configuration can mitigate an increase in the pressure loss for the working vapor 102a flowing through the vapor passage 152a in the bend part BP. This in turn makes it possible to further reduce back-and-forth movement of the working vapor 102a between the first region RR1 and the second region RR2 in the bend part BP. As a result, heat transfer via the bend part BP can be further reduced.

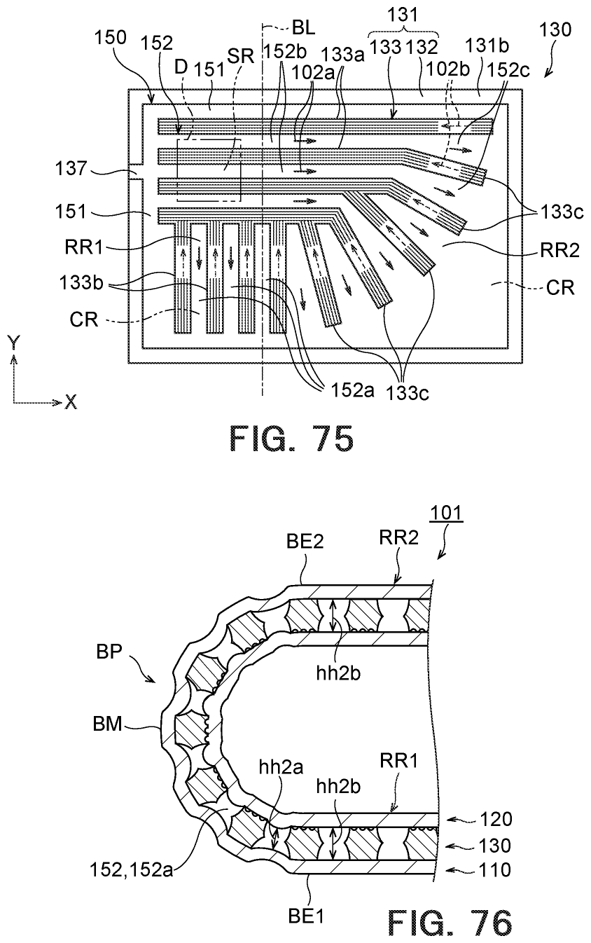

The foregoing description of the fourth embodiment is directed to the example in which a plurality of land parts 133 extend in the X-direction (see FIG. 44). This, however, is not intended to be limiting. Such a plurality of land parts 133 may be of any configuration and arrangement. For example, as illustrated in FIG. 75, a plurality of land parts 133 may include a plurality of first land parts 133a extending in the X-direction, a plurality of second land parts 133b extending in the Y-direction, and a plurality of third land parts 133c extending in a radial configuration.

In the example illustrated in FIG. 75, the vapor chamber 101 has a rectangular shape in plan view. The first region RR1 is disposed at the negative side in the X-direction of the vapor chamber 101 (the left side in FIG. 75), and the second region RR2 is disposed at the positive side in the X-direction of the vapor chamber 101 (the right side in FIG. 75). The evaporation region SR is disposed in the first region RR1. More specifically, the evaporation region SR is provided at the positive side in the Y-direction of the first region RR1 (the upper side in FIG. 75). The condensation region CR is provided around the evaporation region SR. More specifically, the condensation region CR is provided at the negative side in the X-direction of the first region RR1 of the vapor chamber 101 (the lower side in FIG. 75). The condensation region CR is provided in the second region RR2 of the vapor chamber 101.

In the example illustrated in FIG. 75, a plurality of land parts 133 include a plurality of first land parts 133a, a plurality of second land parts 133b, and a plurality of third land parts 133c.

The first land parts 133a are located at the positive side in the Y-direction of the vapor chamber 101 (the upper side in FIG. 75). The first land parts 133a extend in the X-direction. The first land parts 133a each extend from a position located at the negative side in the X-direction of the vapor chamber 101 (the left side in FIG. 75), toward the positive side in the X-direction (the right side in FIG. 75). The first land parts 133a are disposed in spaced parallel relation to each other in the Y-direction. In the example illustrated in FIG. 75, four first land parts 133a are provided. As illustrated in FIG. 75, each first land part 133a may have a different dimension in the X-direction.

The second land parts 133b are located at the negative side in the Y-direction of the vapor chamber 101 (the lower side in FIG. 75). The second land parts 133b extend in the Y-direction. The second land parts 133b extend toward the negative side in the Y-direction in such a way that the second land parts 133b branch off from the first land part 133a that is located at the most negative side in the Y-direction. The second land parts 133b are disposed in spaced parallel relation to each other in the Y-direction. In the example illustrated in FIG. 75, four second land parts 133b are provided.

The third land parts 133c are located at the positive side in the X-direction of the vapor chamber 101 (the right side in FIG. 75). The third land parts 133c extend in a radial configuration. The third land parts 133c each extend in a divergent manner from an edge or any location at the positive side in the X-direction of the corresponding first land part 133a. The third land parts 133c are disposed in such a way that the spacing between the third land parts 133c increases with increasing distance from the evaporation region SR. In the example illustrated in FIG. 75, five third land parts 133c are provided.

The first land part 133a, the second land part 133b, and the third land part 133c are each provided with the liquid channel part 160. The liquid channel part 160 of the first land part 133a communicates with the liquid channel part 160 of the second land part 133b and with the liquid channel part 160 of the third land part 133c.

The second vapor passage 152 includes the vapor passage 152a extending in the first direction, the vapor passage 152b extending in the second direction orthogonal to the first direction, and a vapor passage 152c extending in a radial configuration. In the illustrated example, the first direction is the Y-direction. That is, the vapor passage 152a extends in the Y-direction, and the vapor passage 152b extends in the X-direction. The vapor passage 152c extends in such a way that its width increases with increasing distance from the evaporation region SR. The vapor passage 152a is disposed between the second land parts 133b. The vapor passage 152b is disposed between the first land parts 133a. The vapor passage 152c is disposed between the third land parts 133c.

In the example illustrated in FIG. 75, the bend line BL extends in a direction parallel to the first direction in which the vapor passage 152a extends. The vapor chamber 101 is thus bent in a direction parallel to the first direction.

In the example illustrated in FIG. 75, the bend line BL overlaps the vapor passage 152a disposed between the second land parts 133b that are adjacent to each other. The vapor chamber 101 is thus bent at a position where the vapor passage 152a is disposed. That is, the vapor chamber 101 is bent along the vapor passage 152a.

The vapor chamber 101 is otherwise similar in configuration to that according to the fourth embodiment mentioned above.

According to the modification illustrated in FIG. 75 as well, the vapor chamber 101 is bent at a position where the vapor passage 152a is disposed. This configuration can mitigate an increase in the pressure loss for the working vapor 102a flowing through the vapor passage 152a in the bend part BP. This in turn makes it possible to further reduce back-and-forth movement of the working vapor 102a between the first region RR1 and the second region RR2 in the bend part BP. As a result, heat transfer via the bend part BP can be further reduced.

According to the modification illustrated in FIG. 75, the second vapor passage 152 includes the vapor passage 152c extending in a radial configuration. Consequently, in the XY-plane of the vapor chamber 101, the working vapor 102a can be transported uniformly, and heat can be thus spread uniformly. This can lead to improved heat dissipation efficiency of the vapor chamber 101.

The foregoing description of the fourth embodiment is directed to the example in which the vapor chamber 101 is bent in an L-shape such that the first region RR1 and the second region RR2 are orthogonal to each other (see FIG. 39). This, however, is not intended to be limiting. Alternatively, for example, the vapor chamber 101 may be bent in a U-shape such that the first region RR1 and the second region RR2 face each other as illustrated in FIG. 76. In the example illustrated in FIG. 76, the bend part BP of the vapor chamber 101 has the shape of a semi-circular arc. This can provide increased flexibility in where the vapor chamber 101 can be placed within the housing H. As a result, even if, for instance, the first device D1 and the second device D2 are located far from each other, the first device D1 can be brought into thermal contact with the first region RR1 of the vapor chamber 101, and the second device D2 can be brought into thermal contact with the second region RR2 of the vapor chamber 101. This can obviate the need to prepare a plurality of vapor chambers 101. This allows for reduced cost of manufacturing the vapor chamber 101 in comparison to the cost of manufacturing a plurality of vapor chambers 101.

In this case, in the bend part BP, the first sheet 110 may be recessed toward the vapor passage 152a as illustrated in FIG. 76. The amount of recessing of the first sheet 110 in the bend part BP may be greater than the amount of recessing of the first sheet 110 in each of the first region RR1 and the second region RR2. The amount of recessing of the first sheet 110 in each of the first region RR1 and the second region RR2 may be zero. In other words, in each of the first region RR1 and the second region RR2, the first sheet 110 does not have to be recessed toward the vapor passage 152a. In this case, in the bend part BP, a channel corner with enhanced capillary action can be formed between the first-sheet inner face 110b, and the wall face 153a of the first vapor channel recess 153. Consequently, the working liquid 102b that has been condensed can be quickly recovered in the bend part BP. This makes it possible to reduce deterioration of the heat transport capacity of the vapor chamber 101 while reducing heat transfer via the bend part BP.

As illustrated in FIG. 76, in the bend part BP, the second sheet 120 may be recessed toward the vapor passage 152a. The amount of recessing of the second sheet 120 in the bend part BP may be greater than the amount of recessing of the second sheet 120 in each of the first region RR1 and the second region RR2. The amount of recessing of the second sheet 120 in each of the first region RR1 and the second region RR2 may be zero. In other words, in each of the first region RR1 and the second region RR2, the second sheet 120 does not have to be recessed toward the vapor passage 152a. In this case, in the bend part BP, a channel corner with enhanced capillary action can be formed between the second-sheet inner face 120a, and the wall face 154a of the second vapor channel recess 154. Consequently, the working liquid 102b that has been condensed can be quickly recovered in the bend part BP. This makes it possible to reduce deterioration of the heat transport capacity of the vapor chamber 101 while reducing heat transfer via the bend part BP.

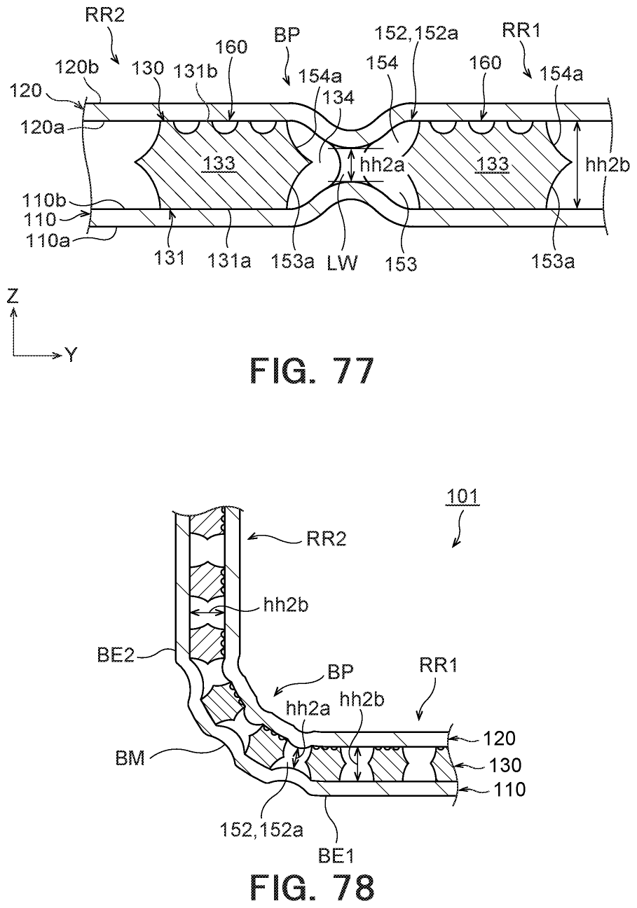

In this case, as illustrated in FIGS. 76 and 77, the vapor passage 152a may have a height hh2a in the bend part BP that is less than a height hh2b of the liquid-channel main flow groove 161 in each of the first region RR1 and the second region RR2. Each of the heights hh2a and hh2b of the vapor passage 152a in this case means the minimum dimension of the vapor passage 152a in the Z-direction, and correspond to the minimum distance in the Z-direction between the first-sheet inner face 110b and the second-sheet inner face 120a. In this case, the cross-sectional area of the vapor passage 152a can be reduced in the bend part BP. This makes it possible to increase the channel resistance for the working vapor 2a in the bend part BP, and consequently to further reduce heat transfer via the bend part BP.

Although the height hh2a of the vapor passage 152a in the bend part BP may be zero, the height hh2a does not have to be zero. In other words, a gap may be present between the first-sheet inner face 110b and the second-sheet inner face 120a. In this case, the capillary force exerted between the first-sheet inner face 110b and the second-sheet inner face 120a can be increased. Consequently, the working liquid 102b that has been condensed can be retained in the vapor passage 152a by the capillary force. In this case, as illustrated in FIG. 77, a wall LW of the condensed working liquid 102b may be formed in the vapor passage 152a. Consequently, in the bend part BP, the vapor passage 152a may decrease in cross-sectional area, which may lead to an increased channel resistance for the working vapor 2a. As a result, heat transfer via the bend part BP can be reduced.

As illustrated in FIG. 76, if a plurality of vapor passages 152a are located within the bend part BP, each vapor passage 152a may have a different height hh2a. Now, an end portion of the bend part BP near the first region RR1 is referred to as first bend end portion BE1, an end portion of the bend part BP near the second region RR2 is referred to as second bend end portion BE2, and a portion of the bend part BP midway between the first bend end portion BE1 and the second bend end portion BE2 is referred to as bend middle portion BM. In this case, for example, within the bend part BP, the height hh2a of the vapor passage 152a located near the bend middle portion BM may be less than the height hh2a of the vapor passage 152a located near the first bend end portion BE1 and the height hh2a of the vapor passage 152a located near the second bend end portion BE2. That is, within the bend part BP, the height hh2a of each vapor passage 152a may decrease with increasing distance from the first bend end portion BE1 toward the bend middle portion BM, and may increase with increasing distance from the bend middle portion BM toward the second bend end portion BE2. In this case, the channel resistance for the working vapor 2a in the bend middle portion BM can be increased. This can ensure that even if the bend part BP extends over a large area, heat transfer via the bend part BP can be reduced. Further, in the bend middle portion BM, the capillary force exerted between the first-sheet inner face 110b and the second-sheet inner face 120a can be increased. Consequently, the working liquid 102b that has been condensed can be retained in the vapor passage 152a by the capillary force. In this case, as illustrated in FIG. 77, the wall LW of the condensed working liquid 102b may be formed in the vapor passage 152a. Consequently, in the bend part BP, the vapor passage 152a may decrease in cross-sectional area, which may lead to an increased channel resistance for the working vapor 2a. As a result, heat transfer via the bend part BP can be further reduced.

Even if the vapor chamber 101 is bent in an L-shape such that the first region RR1 and the second region RR2 are orthogonal to each other as illustrated in FIG. 78, the vapor chamber 101 may have a configuration similar to that according to the modification illustrated in FIG. 76. That is, in the bend part BP, the first sheet 110 may be recessed toward the vapor passage 152a, and the second sheet 120 may be recessed toward the vapor passage 152a. The height hh2a of the vapor passage 152a in the bend part BP may be less than the height hh2a of the liquid-channel main flow groove 161 in each of the first region RR1 and the second region RR2. Within the bend part BP, the height hh2a of each vapor passage 152a may decrease with increasing distance from the first bend end portion BE1 toward the bend middle portion BM, and may increase with increasing distance from the bend middle portion BM toward the second bend end portion BE2. In this case as well, an effect similar to that of the modification illustrated in FIG. 76 can be provided.

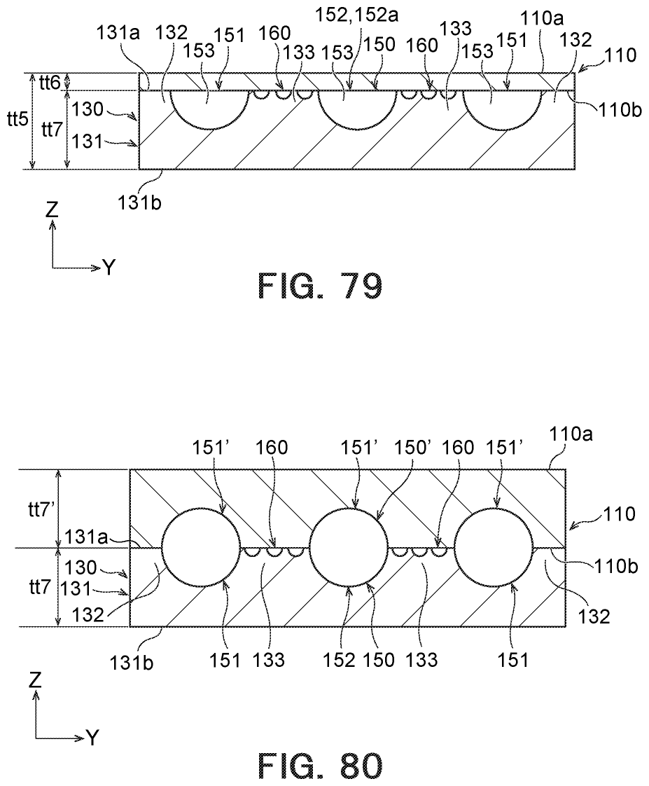

The foregoing description of the fourth embodiment is directed to the example in which the vapor chamber 101 includes the first sheet 110, the second sheet 120, and the body sheet 130 (see FIG. 41). This, however, is not intended to be limiting. Alternatively, as illustrated in FIG. 79, the vapor chamber 101 may include the first sheet 110, and the body sheet 130.

In the example illustrated in FIG. 79, the vapor chamber 101 includes the first sheet 110 and the body sheet 130, but does not include the second sheet 120. In the example illustrated in FIG. 79, the body sheet 130 and the first sheet 110 are stacked in this order. The device D may be mounted to the first-sheet outer face 110a of the first sheet 110. The housing component Ha may be mounted to the second body face 131b of the body sheet 130. The heat of the working vapor 102a is transferred from the body sheet 130 to the housing component Ha.

In the example illustrated in FIG. 79, although the vapor channel part 150 is disposed in the first body face 131a, the vapor channel part 150 does not extend to reach the second body face 131b. The vapor channel part 150 thus does not extend through the sheet body 131 of the body sheet 130. That is, the first vapor passage 151 and the second vapor passage 152 of the vapor channel part 150 are each defined by the first vapor channel recess 153, with no second vapor channel recess 154 provided in the body sheet 130.

The vapor chamber 101 illustrated in FIG. 79 may have a thickness tt5 of, for example, 100 μm to 1000 μm. The first sheet 110 illustrated in FIG. 79 may have a thickness tt6 of, for example, 6 μm to 200 μm. The body sheet 130 illustrated in FIG. 79 may have a thickness tt7 of, for example, 50 μm to 800 μm.

The example illustrated in FIG. 79 is not intended to be limiting. Alternatively, as illustrated in FIG. 80, a vapor channel part 150′ may be disposed in the first-sheet inner face 110b of the first sheet 110. As illustrated in FIG. 80, the vapor channel part 150′ of the first sheet 110 may be positioned to face the vapor channel part 150 of the body sheet 130. That is, the vapor channel part 150′ of the first sheet 110 may include a first vapor passage 151′ facing the first vapor passage 151 of the body sheet 130, and a second vapor passage 152′ facing the second vapor passage 152 of the body sheet 130. The vapor channel part 150′ of the first sheet 110 may have dimensions substantially equal to the dimensions of the vapor channel part 150 of the body sheet 130. The first sheet 110 illustrated in FIG. 80 may have a thickness tt7′ substantially equal to the thickness tt7 of the body sheet 130. In the example illustrated in FIG. 80, the first sheet 110 is not provided with the liquid channel part 160. This, however, is not intended to be limiting. The first sheet 110 may be provided with the liquid channel part 160.

According to the modifications illustrated in FIGS. 79 and 80, the vapor chamber 101 includes the first sheet 110, and the body sheet 130. In this case as well, the vapor chamber 101 is bent in a direction parallel to the first direction. This makes it possible to reduce back-and-forth movement of the working vapor 102a between the first region RR1 and the second region RR2 in the bend part BP. As a result, for the vapor chamber 101 in its bent state, heat transfer via the bend part BP can be reduced. According to the modifications illustrated in FIGS. 79 and 80, the vapor chamber 101 includes the first sheet 110, and the body sheet 130 as described above. This allows for further reduction in the thickness of the vapor chamber 101.

The foregoing embodiments allow the vapor chamber to exhibit improved performance even in its bent state.

The present invention is not limited to the foregoing embodiments and modifications as specifically described. Rather, the present invention can in practice be implemented with modifications or changes to its constituent elements without departing from the scope and sprit of the invention. Variations of the invention can be made by suitable combinations of a plurality of constituent elements disclosed in the foregoing embodiments and modifications. Of all the constituent elements described in the foregoing embodiments and modifications, some constituent elements may be omitted.

1-21. (canceled)

22. A vapor chamber in which a working fluid is sealed, the vapor chamber comprising:
a body sheet including a first body face and a second body face, the second body face being located opposite from the first body face;
a first sheet located on the first body face of the body sheet; and
a space part disposed in the body sheet and covered by the first sheet,
wherein the body sheet includes a plurality of first land parts located within the space part and extending in a first direction, the plurality of first land parts being spaced apart from each other in a second direction orthogonal to the first direction,
wherein the first sheet includes a first-sheet outer face located opposite from the body sheet,
wherein the first-sheet outer face includes a first bond region and a first space region, the first bond region overlapping each of the plurality of first land parts, the first space region overlapping the space part,
wherein the vapor chamber includes a bend region where the vapor chamber is bent along a bend line, the bend line extending in a direction crossing the first direction in plan view,
wherein a maximum dimension defined between the first bond region and the first space region in a thickness direction of the first sheet is defined as a first maximum dimension, and
wherein when viewed in a direction parallel to the bend line, the first maximum dimension in the bend region is greater than the first maximum dimension in a region other than the bend region.

23. The vapor chamber according to claim 22, wherein the first space region has a recessed shape.

24. The vapor chamber according to claim 22,
wherein the first space region has a recessed shape in the bend region, and
wherein the first space region has, in the region other than the bend region, a flat shape in a direction aligned with the bend line.

25. The vapor chamber according to claim 22, wherein in the bend region, a portion of the first space region has a recessed shape, and an other portion of the first space region has a flat shape in a direction aligned with the bend line.

26. The vapor chamber according to claim 22, wherein the first sheet includes a plurality of first-sheet recesses, the plurality of first-sheet recesses overlapping the first space region in plan view and extending into the space part.

27. The vapor chamber according to claim 22, wherein in the bend region, the vapor chamber is bent along a bend line extending in the second direction.

28. The vapor chamber according to claim 22, wherein in the bend region, the vapor chamber is bent along a bend line inclined with respect to the first direction.

29. The vapor chamber according to claim 22, wherein in the bend region, the first sheet is located outward relative to the body sheet.

30. The vapor chamber according to claim 22, wherein in the bend region, the first sheet is located inward relative to the body sheet.

31. The vapor chamber according to claim 22, comprising
a second sheet located on the second body face of the body sheet,
wherein the space part extends from the first body face to the second body face, and is covered at the second body face by the second sheet,
wherein the second sheet includes a second-sheet outer face located opposite from the body sheet,
wherein the second sheet includes a second bond region and a second space region, the second bond region overlapping each of the plurality of first land parts, the second space region overlapping the space part,
wherein a maximum dimension defined between the second bond region and the second space region in a thickness direction of the second sheet is defined as a second maximum dimension, and
wherein when viewed in the direction parallel to the bend line, the second maximum dimension in the bend region is greater than the second maximum dimension in the region other than the bend region.

32. The vapor chamber according to claim 31, wherein in the bend region, the second sheet is located inward relative to the body sheet.

33. The vapor chamber according to claim 22,
wherein the body sheet includes a plurality of second land parts extending in the second direction,
wherein each of the plurality of second land parts is located in the region other than the bend region,
wherein each of the plurality of first land parts is located in the bend region, and
wherein each of the plurality of first land parts is connected to a corresponding one of the plurality of second land parts.

34. An electronic apparatus comprising:
a housing;
a device contained in the housing; and
the vapor chamber according to claim 22, the vapor chamber being in thermal contact with the device.

35. A method for manufacturing a vapor chamber in which a working fluid is sealed, the method comprising:
a preparing step of preparing a body sheet and a first sheet, the body sheet including a first body face and a second body face located opposite from the first body face;
a bonding step of placing the first sheet on the first body face of the body sheet, and bonding the first sheet and the body sheet to each other, the bonding causing a space part to be formed in the body sheet, the space part being covered by the first sheet; and
a bending step of bending the body sheet and the first sheet to form a bend region where the body sheet and the first sheet are bent,
wherein the body sheet includes a plurality of first land parts located within the space part and extending in a first direction, the plurality of first land parts being spaced apart from each other in a second direction orthogonal to the first direction,
wherein the first sheet includes a first-sheet outer face located opposite from the body sheet,
wherein the first-sheet outer face includes a first bond region and a first space region, the first bond region overlapping each of the plurality of first land parts, the first space region overlapping the space part,
wherein in the bend region, the vapor chamber is bent along a bend line, the bend line extending in a direction crossing the first direction in plan view,
